(19) United States
(12) Patent Application Publication
(10) Pub. No.: US 2024/0213124 A1
(43) Pub. Date: Jun. 27, 2024

(54) POWER ELECTRONICS PACKAGE LAYOUTS, STRUCTURES, AND/OR CONFIGURATIONS FOR ONE OR MORE POWER DEVICES AND PROCESSES IMPLEMENTING THE SAME

(71) Applicant: WOLFSPEED, INC., Durham, NC (US)

(72) Inventors: Brice MCPHERSON, Fayetteville, AR (US); Shashwat SINGH, Fayetteville, AR (US); Brandon PASSMORE, Fayetteville, AR (US); Roberto Marcelo SCHUPBACH, Fayetteville, AR (US); Mohammed Hazzaz MAHMUD, Fayetteville, AR (US)

(21) Appl. No.: 18/145,502

(22) Filed: Dec. 22, 2022

(51) Int. Cl. H01L 23/495; H01L 23/00; H01L 23/31; H01L 23/36; H01L 23/544

(52) U.S. Cl. CPC H01L 23/49562; H01L 23/3107; H01L 23/36; H01L 23/544; H01L 24/40; H01L 24/48; H01L 2223/54426; H01L 2224/40175; H01L 2224/48137; H01L 2224/48175

(57) ABSTRACT

A power package includes a power substrate; one or more power devices arranged on the power substrate; and a lead frame power interconnection having a lead frame first portion and a lead frame second portion.

### BACKGROUND OF THE DISCLOSURE

### 1. Field of the Disclosure

This disclosure is directed to power electronics package layouts, structures, and/or configurations for one or more power devices. Moreover, the disclosure is directed to processes implementing power electronics package layouts, structures, and/or configurations for one or more power devices.

### 2. Related Art

Power electronics packages typically implement one or more power devices, such as Silicon Carbide (SiC) power devices, which offer a high level of performance benefits, including high voltage blocking, low on-resistance, high current, fast switching, low switching losses, high junction temperatures, and high thermal conductivity. Ultimately, these power device characteristics result in a notable increase in potential power density, which is power processed per area or volume.

However, typical power electronics packages fail to provide the necessary functionality to achieve the potential of power devices. In this regard, the typical power electronics packages suffer from significant challenges at the package and system level. The higher voltages, currents, and switching speeds manifest into significantly higher physical stresses applied onto smaller and more constrained areas. Accordingly, the typical power electronics packages fall short from achieving a performance commensurate with the power devices.

Accordingly, what is needed is power electronics packages implementing layouts, structures, and/or configurations that can operate commensurate with the high level performance of the power devices implemented by the power electronics packages.

### SUMMARY OF THE DISCLOSURE

In one general aspect, the power package includes a power substrate. The power package in addition includes one or more power devices arranged on the power substrate. The power package moreover includes a lead frame power interconnection having a lead frame first portion and a lead frame second portion. The power package also includes a connector configured to reduce transconductance mismatches between paralleled implementations of the one or more power devices.

In one general aspect, the power package includes a power substrate. The power package in addition includes one or more power devices arranged on the power substrate. The power package moreover includes a lead frame power interconnection having a lead frame first portion and a lead frame second portion. The power package also includes a molded assembly configured to provide electrical isolation, voltage safety distances, and/or mechanical support to an internal layout and the one or more power devices. The power package further includes where the molded assembly may include creepage extenders.

In one general aspect, the power package includes a power substrate. The power package in addition includes one or more power devices arranged on the power substrate. The power package moreover includes a lead frame power interconnection having a lead frame first portion and a lead frame second portion. The power package also includes a thermal pad configured as an exposed metal surface configured to thermally and mechanically attach to another component. The power package further includes where components of the power package are configured for one, two, three, or four implementations of the one or more power devices within a same structure of the power package.

Additional features, advantages, and aspects of the disclosure may be set forth or apparent from consideration of the following detailed description, drawings, and claims. Moreover, it is to be understood that both the foregoing summary of the disclosure and the following detailed description are exemplary and intended to provide further explanation without limiting the scope of the disclosure as claimed.

### BRIEF DESCRIPTION OF THE DRAWINGS

The accompanying drawings, which are included to provide a further understanding of the disclosure, are incorporated in and constitute a part of this specification, illustrate aspects of the disclosure and together with the detailed description serve to explain the principles of the disclosure. No attempt is made to show structural details of the disclosure in more detail than may be necessary for a fundamental understanding of the disclosure and the various ways in which it may be practiced. In the drawings:

FIG. 1 illustrates a top side perspective view of an external configuration a power package according to aspects of the disclosure.

FIG. 2 illustrates a bottom side perspective view of the external configuration of the power package according to FIG. 1.

FIG. 3 illustrates a front side view of the external configuration of the power package according to FIG. 1.

FIG. 4 illustrates a top side view of the external configuration of the power package according to FIG. 1.

FIG. 5 illustrates a side view of the external configuration of the power package according to FIG. 1.

FIG. 6 illustrates a bottom side view of the external configuration of the power package according to FIG. 1.

FIG. 7A illustrates a terminal arrangement of the power package 100 according to aspects of the disclosure; and FIG. 7B further illustrates a single switch topology of the power package 100 according to aspects of the disclosure.

FIG. 8 illustrates an exemplary arrangement of one or more implementations of the power package to form circuit topology ‘building blocks’ according to aspects of the disclosure.

FIG. 9 illustrates an exemplary arrangement of one or more implementations of the power package to form circuit topology ‘building blocks’ according to aspects of the disclosure.

FIG. 10 illustrates an exemplary arrangement of one or more implementations of the power package to form circuit topology ‘building blocks’ according to aspects of the disclosure.

FIG. 11 illustrates an exemplary arrangement of one or more implementations of the power package to form circuit topology ‘building blocks’ according to aspects of the disclosure.

FIG. 12 illustrates an exploded view of the power package with exemplary components according to aspects of the disclosure.

FIG. 13 illustrates an exemplary power loop implemented by configurations of the power package according to aspects of the disclosure.

FIG. 14 an exemplary signal loop implemented by a configuration of the power package according to aspects of the disclosure.

FIG. 15 illustrates an exemplary implementation of the power package implementing a pseudo source Kelvin configuration according to aspects of the disclosure.

FIG. 16 illustrates an exemplary implementation of the power package implementing a true source Kelvin configuration according to aspects of the disclosure.

FIG. 17 illustrates another aspect of the power package implementing a connector according to aspects of the disclosure.

FIG. 18 illustrates another aspect of the power package implementing another aspect of a connector according to aspects of the disclosure.

FIG. 19 illustrates another aspect of the power package implementing hold down configurations according to aspects of the disclosure.

FIG. 20 illustrates another aspect of the power package implementing fiducial configurations according to aspects of the disclosure.

FIG. 21 illustrates another aspect of the power package implementing configurations of the power substrate according to aspects of the disclosure.

FIG. 22 illustrates another aspect of the power package implementing configurations of the power substrate according to aspects of the disclosure.

FIG. 23 illustrates another aspect of the power package implementing configurations of the power substrate according to aspects of the disclosure.

FIG. 24 illustrates another aspect of the power package implementing configurations of the power substrate according to aspects of the disclosure.

FIG. 25 illustrates another aspect of the power package implementing configurations of the power substrate according to aspects of the disclosure.

FIG. 26 illustrates aspects of the power package according to aspects of the disclosure.

FIG. 27 illustrates aspects of the power package according to aspects of the disclosure.

FIG. 28 illustrates aspects of the power package according to aspects of the disclosure.

FIG. 29 illustrates aspects of the power package according to aspects of the disclosure.

FIG. 30 illustrates aspects of the power package according to aspects of the disclosure.

FIG. 31 illustrates aspects of the power package according to aspects of the disclosure.

FIG. 32 illustrates aspects of the power package according to aspects of the disclosure.

FIG. 34 illustrates aspects of the power package according to aspects of the disclosure.

FIG. 35 illustrates aspects of the power package according to aspects of the disclosure.

FIG. 36 illustrates aspects of the power package according to aspects of the disclosure.

FIG. 37 illustrates aspects of the power package according to aspects of the disclosure.

FIG. 38 illustrates aspects of the power package according to aspects of the disclosure.

FIG. 39 illustrates aspects of the power package according to aspects of the disclosure.

FIG. 40 illustrates aspects of the power package according to aspects of the disclosure.

FIG. 41 illustrates aspects of the power package according to aspects of the disclosure.

FIG. 42 illustrates aspects of the power package according to aspects of the disclosure.

FIG. 43 illustrates aspects of the power package according to aspects of the disclosure.

FIG. 44 illustrates aspects of the power package according to aspects of the disclosure.

FIG. 45 illustrates aspects of the power package according to aspects of the disclosure.

FIG. 46 illustrates aspects of the power package according to aspects of the disclosure.

FIG. 47 illustrates aspects of the power package according to aspects of the disclosure.

FIG. 48 illustrates aspects of the power package according to aspects of the disclosure.

FIG. 49 illustrates aspects of the power package according to aspects of the disclosure.

FIG. 50 illustrates aspects of the power package according to aspects of the disclosure.

FIG. 51 illustrates aspects of the power package according to aspects of the disclosure.

FIG. 52 illustrates aspects of the power package according to aspects of the disclosure.

FIG. 53 illustrates aspects of the power package according to aspects of the disclosure.

FIG. 54 illustrates aspects of the power package according to aspects of the disclosure.

FIG. 55 illustrates aspects of the power package according to aspects of the disclosure.

FIG. 56 illustrates aspects of the power package according to aspects of the disclosure.

FIG. 57 illustrates aspects of the power package according to aspects of the disclosure.

FIG. 58 illustrates aspects of the power package according to aspects of the disclosure.

FIG. 59 illustrates aspects of the power package according to aspects of the disclosure.

FIG. 60 illustrates aspects of the power package according to aspects of the disclosure.

FIG. 61 illustrates aspects of the power package according to aspects of the disclosure.

FIG. 62 illustrates aspects of the power package according to aspects of the disclosure.

FIG. 63 illustrates aspects of the power package according to aspects of the disclosure.

FIG. 64 illustrates aspects of the power package according to aspects of the disclosure.

FIG. 65 illustrates aspects of the power package according to aspects of the disclosure.

FIG. 66 illustrates aspects of the power package according to aspects of the disclosure.

### DETAILED DESCRIPTION OF THE DISCLOSURE

The aspects of the disclosure and the various features and advantageous details thereof are explained more fully with reference to the non-limiting aspects and examples that are described and/or illustrated in the accompanying drawings and detailed in the following description. It should be noted that the features illustrated in the drawings are not necessarily drawn to scale, and features of one aspect may be employed with other aspects as the skilled artisan would recognize, even if not explicitly stated herein. Descriptions of well-known components and processing techniques may be omitted so as to not unnecessarily obscure the aspects of the disclosure. The examples used herein are intended merely to facilitate an understanding of ways in which the disclosure may be practiced and to further enable those of skill in the art to practice the aspects of the disclosure. Accordingly, the examples and aspects herein should not be construed as limiting the scope of the disclosure, which is defined solely by the appended claims and applicable law. Moreover, it is noted that like reference numerals represent similar parts throughout the several views of the drawings.

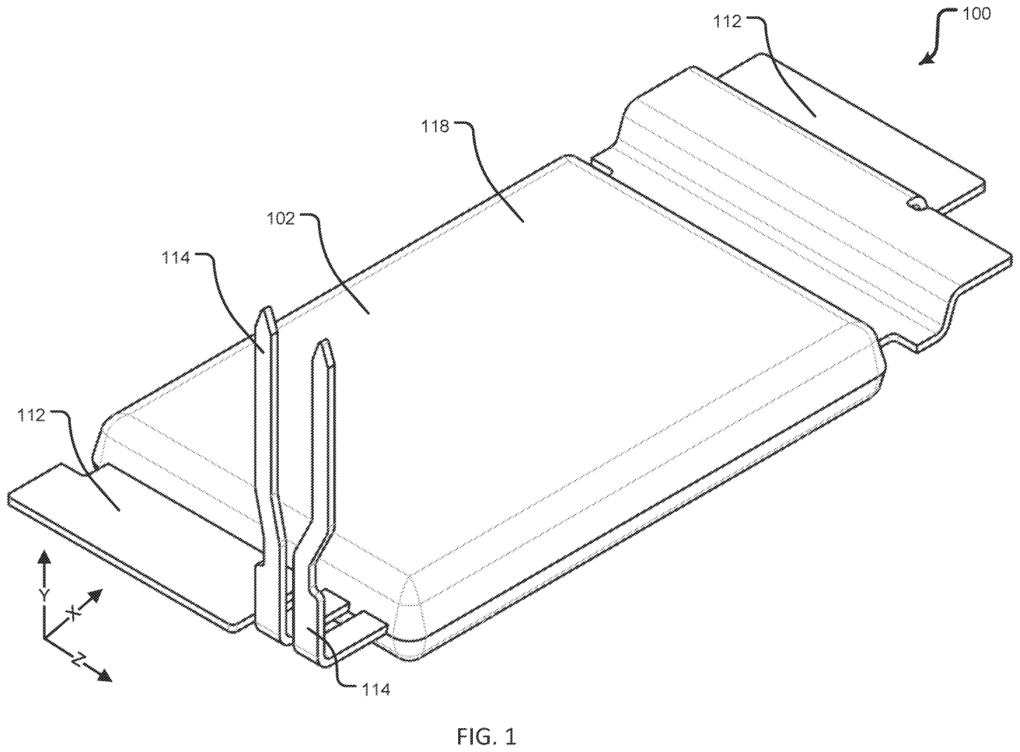

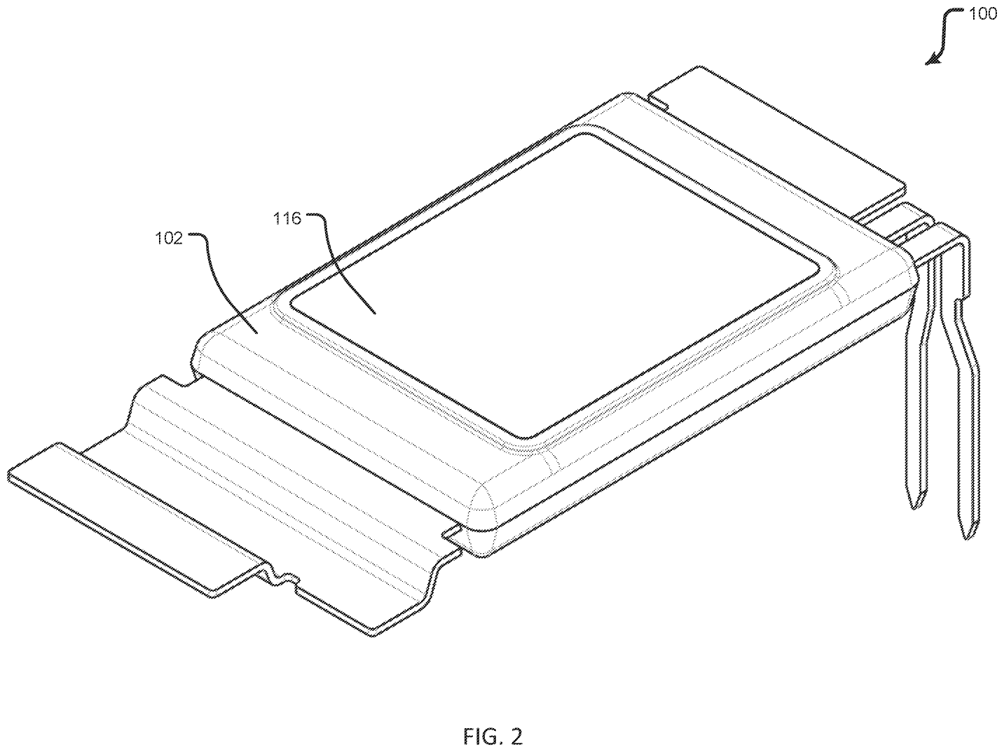

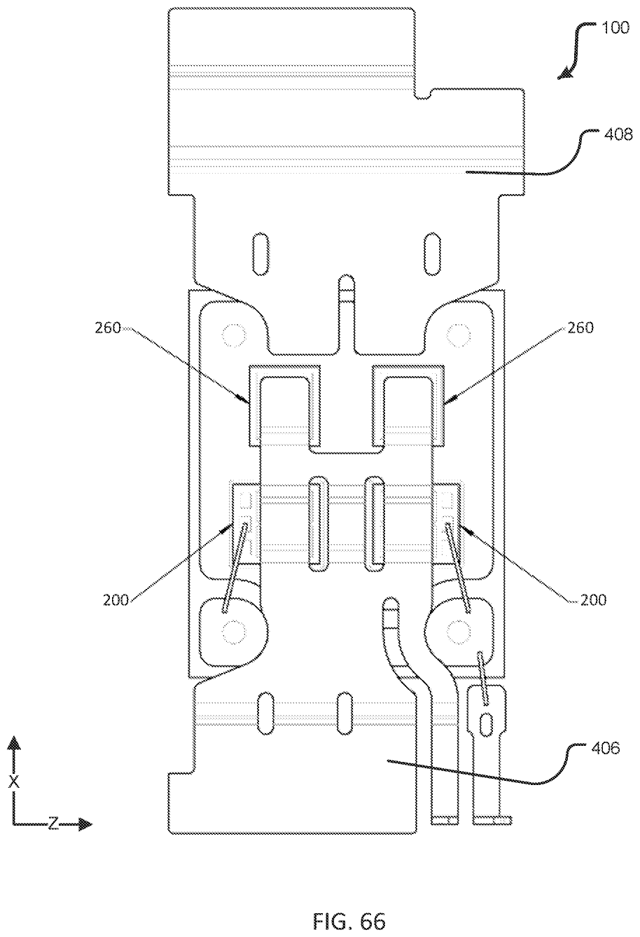

As illustrated in FIGS. 1-66, the disclosure is directed to a power package 100. The power package 100 of the disclosure includes a series of internal layout arrangements for a single switch position high voltage power package containing one or multiple power devices in parallel. These arrangements all fit within the external geometry, electrical terminals, and thermal pad of an industry standard product outline specification. Each embodiment is optimized around different design constraints, including topside interconnection geometry, topside interconnection material(s), thermal performance, manufacturing considerations, and the implementation of a true source kelvin signal connection.

As each configuration of the power package 100 may meet an industry standard product outline specification, they could be commonly used in many systems which have or will adopt the standard, while also taking advantages of the specific benefits and optimizations of the given approach.

In general, output current scales with device area, with more device area able to process more current and dissipate more waste heat from conduction, switching, and package resistance losses. Scalability is achieved with each layout able to accommodate devices of different sizes. Device positions are also modular, such that they also be fully or partially populated with power switches and diodes for even more adaptability. Using both of these techniques, total active device area can be modulated to allow for a range of performance and cost targets depending on the needs of a system.

Aspects of the power package 100 may include: Multiple internal configurations and layouts for power electronic devices in an industry standard external product outline; Layout implementations for true source kelvin and pseudo source kelvin implementations; Interconnect implementations for direct source attach, aluminum power wire bonding, copper wire bonding, aluminum power ribbon bonding, and copper power ribbon bonding; Interconnect implementations to reduce package resistances and increase maximum package current; Physical arrangement of power devices to optimize heat spreading for minimal thermal overlap; Physical arrangement of hold down pin locations for edge and center locations for minimizing stress during product manufacturing; Layout implementations of mechanical linkages from the lead frame to the power substrate for handling support during product manufacturing; Molded-in voltage creepage extenders on the bottom side of the package to improve voltage safety requirements; Scalable device positions allowing for devices to scale up or down in length and/or width to increase output current (more device area) or reduce cost (less device area); Modular device positions allowing for full or partial population of the up to four possible device locations; Modular device positions allowing for the inclusion of antiparallel diodes; Semi-modular lead frame with clip insert for modular switch position optimization; Lead frame implementations for solder, sinter, or direct welding attaches; Surface enhancements of the backside thermal pad for optimal heat transfer.

Aspects of the power package 100 may implement Silicon Carbide (SiC) power devices that offer a high level of performance benefits, including high voltage blocking, low on-resistance, high current, fast switching, low switching losses, high junction temperatures, and high thermal conductivity. Ultimately, these characteristics result in a notable increase in potential power density, which is power processed per area or volume.

Achieving this potential, however, requires addressing significant challenges at the package and system level. The higher voltages, currents, and switching speeds manifest into significantly higher physical stresses applied onto smaller and more constrained areas. To fully take advantage of what SiC technology has to offer, the disclosed implementation of the power package 100 addresses these challenges including: Capability to form common circuit topologies both within (internal layout) and without (interconnection) the package; Waste heat removal including conduction and switching losses from the devices; Effective electrical isolation between high voltage potentials; Low power loop inductance for minimal high voltage overshoot during high speed switching; Low signal loop inductance for minimal gate voltage overshoot and oscillations; Internal layout optimized for paralleling of devices for dynamic and steady state current sharing; Low power loop resistance for high current carrying without overheating; External terminal arrangement well suited for paralleling modules and featuring straightforward arrangement into circuit topologies; and/or Balanced arrangement of devices.

Aspects of the power package 100 may implement the internal layout, or physical arrangement of package components, has a prominent influence on each of these factors. It becomes increasingly more difficult to realize an optimal layout as the number of devices inside of the package increases. Paralleling is a technique for SiC devices to increase the current capability of a package. With more devices in parallel, the tradeoffs between heat spreading, power loop inductance, signal loop inductance, and package size become progressively more difficult to balance.

Aspects of the power package 100 may be implemented in power electronic systems with many topologies, or electrical arrangements of the power devices, are used. These may include but are not limited to the following: Single Switch, Half Bridge, Full Bridge, Three Phase Bridge (also called a Six Pack), Buck, Boost, Buck-Boost, Ćuk, and/or the like

Aspects of the power package 100 may house and interconnect the full topology itself, others are intended as building blocks from which many topologies can be formed. Often, packages housing a single switch position of one or more power devices per switch position are used. Another arrangement is a bridge leg, or half-bridge, of two switch positions of one or more devices per switch position connected in series.

In addition to layout, topology, and performance, to appeal to a broad range of markets and applications, aspects of the power package 100 may be configured to keep cost kept low. A few techniques to optimize the Bill of Materials (BOM) and production costs of the power package 100 include: Limit use of individual components by serving multiple functions out of the same component; Optimize functionality and performance out of each component through design, Limit the requirement of secondary or finishing operations, Use conventional or well-established manufacturing methods known for high yield, Utilize batch or continuous processing when possible, using panels, strips, arrays, magazines, etc., Optimize package size and form based on manufacturing methods of the sub-components (such as sizing the parts that are fabricated on a strip or a panel to maximize utilization of that raw material).

Aspects of the power package 100 may be implemented with, but are not limited to, a combination of one or more of the following components, each providing multiple functions: Power Device(s)—Controllable switches MOSFET, IGBT, and the like and Diodes; a Power Substrate having Layered metal and ceramic for high current electrical interconnection, high voltage isolation, high thermal conductivity, coefficient of thermal expansion (CTE) matching, and external thermal interface; a Signal Substrate having Layered Printed Circuit Board (PCB), layered metal and ceramic, thick film, and the like for high frequency electrical interconnection and high voltage isolation; a Power Terminal having Metal contact for high current external connection and internal interconnection; a Signal Terminal having a Metal contact or connector for high frequency external connection and internal interconnection; a Lead Frame Metal contact strip for high current external connection and internal interconnection; Contacts are joined together on a single sheet, often with multiple products per sheet, and are processed as an array and then formed and singulated; a Base Plate having a Metal or composite material for mechanical structure, high thermal conductivity, coefficient of thermal expansion (CTE) matching, and external thermal interface; a Device Attach having Solder, adhesive, or sintered metal, and the like for mechanical structure, high current interconnection, and high thermal conductivity; a Terminal Attach having Solder, adhesive, sintered metal, laser weld, ultrasonic weld, and the like for mechanical structure, high current interconnection, and high thermal conductivity; a Substrate Attach having Solder, adhesive, or sintered metal, and the like for mechanical structure and high thermal conductivity; Power Wire Bonds having Ultrasonically or thermosonically bonded large diameter wire for high current electrical interconnection; Signal Wire Bonds having Ultrasonically or thermosonically bonded small diameter wire for low current electrical interconnection; a Case/Housing including an Injection molded case and lid, providing mechanical structure, high voltage isolation, and acting as a well for the encapsulation material; a Mold Compound having a Transfer or compression molded epoxy molding compound (EMC) for mechanical structure, high voltage isolation, coefficient of thermal expansion (CTE) matching, and low humidity absorption; an Encapsulation having Soft, flexible silicone or similar encapsulation material for high voltage isolation, and low humidity absorption; a Temperature Sensor implementing a Passive or active element that can be used to monitor internal temperatures; Signal Circuitry that may include Resistors, capacitors, surface mount components, sensors, and the like for stabilization of the dynamic switching performance of the devices or for other internal circuit requirements, such as active miller clamping, etc.

The power package 100 may include the one or more power devices 200 implemented as power semiconductor devices, including MOSFETs, IGBTs, diodes, and/or the like, arranged into a variety of circuit topologies. The power package 100 may include multiple devices in parallel and arranged into multiple switch positions. Aspects of the power package 100 may serve many functions including: Electrical interconnection, Electrical isolation, Heat transfer, Mechanical structure, Protection of the devices from environmental contamination and moisture, External electrical and thermal connection interfaces, Compliance with safety standards such as voltage creepage and clearance distances, and/or the like.

Aspects of the power package 100 may include numerous implementations that may vary significantly based on the specific applications for and intended usage of the products. In particular, aspects of the power package 100 may be configured and implemented to include: High power density (small package size), High current, High voltage, High temperature operation, Low thermal resistance, Low stray inductance, Fast and clean switching, High efficiency through low on-resistance, High efficiency through high speed switching, Thoughtful external terminal layout for effective interconnection, Compliance with creepage and clearance standards, Moisture Sensitivity Level (MSL) compliance, Low cost, and/or the like.

FIG. 1 illustrates a top side perspective view of an external configuration a power package according to aspects of the disclosure.

FIG. 2 illustrates a bottom side perspective view of the external configuration of the power package according to FIG. 1.

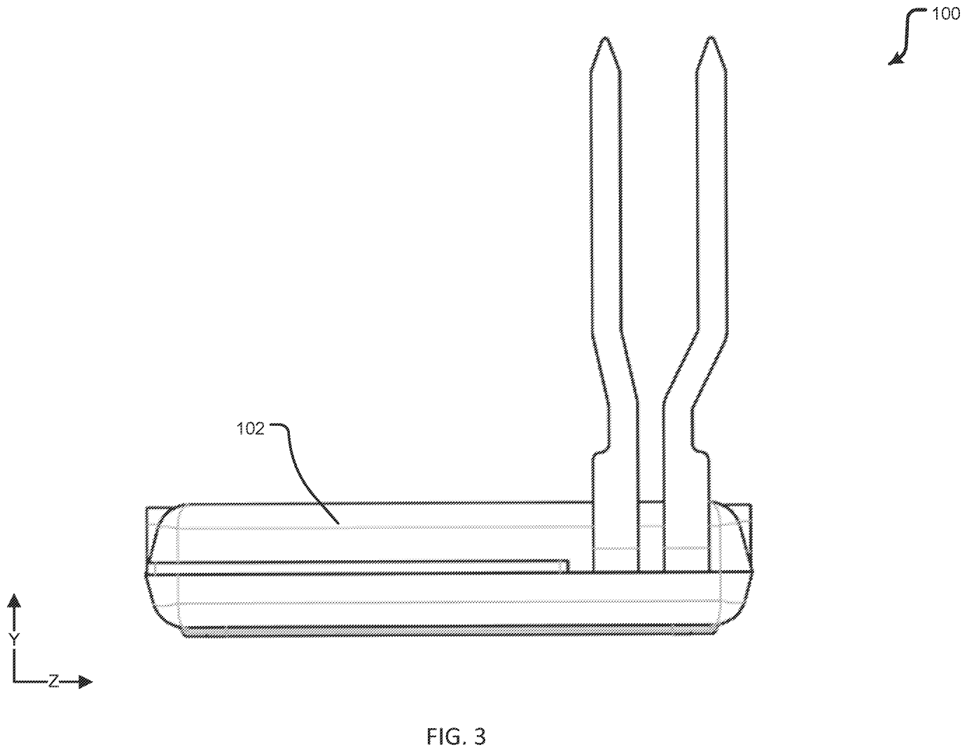

FIG. 3 illustrates a front side view of the external configuration of the power package according to FIG. 1.

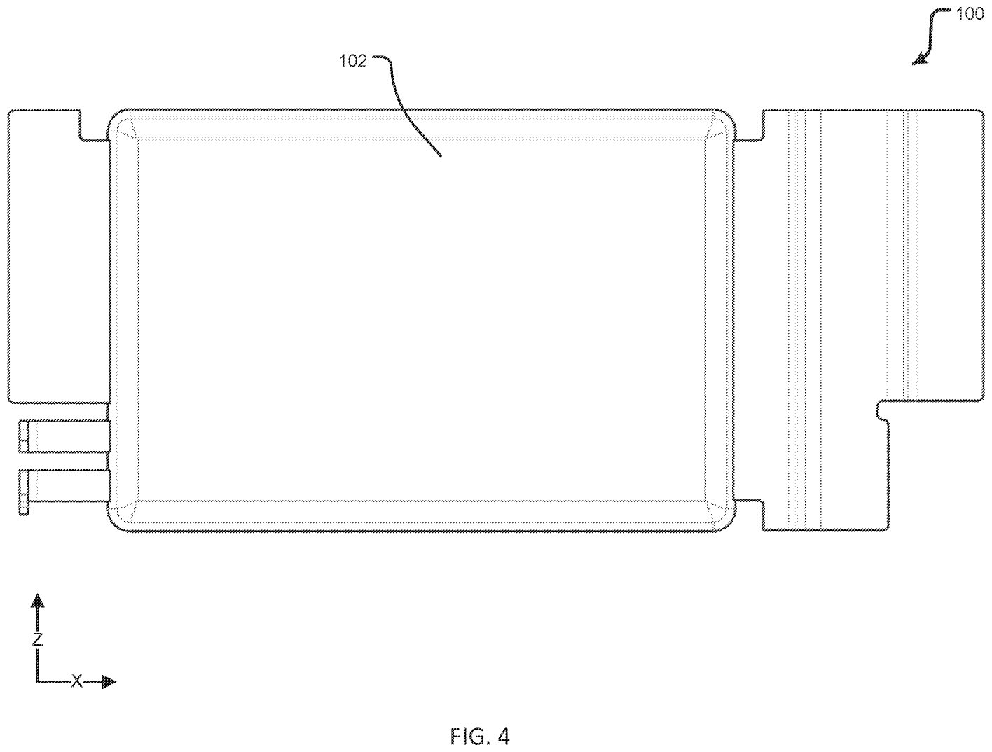

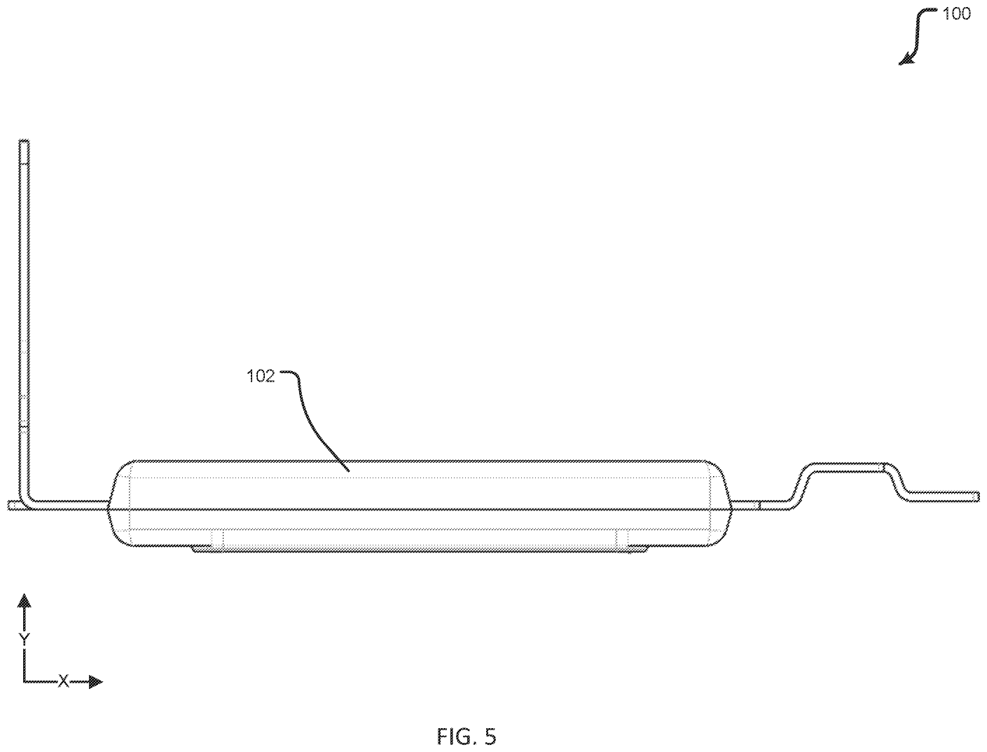

FIG. 4 illustrates a top side view of the external configuration of the power package according to FIG. 1.

FIG. 5 illustrates a side view of the external configuration of the power package according to FIG. 1.

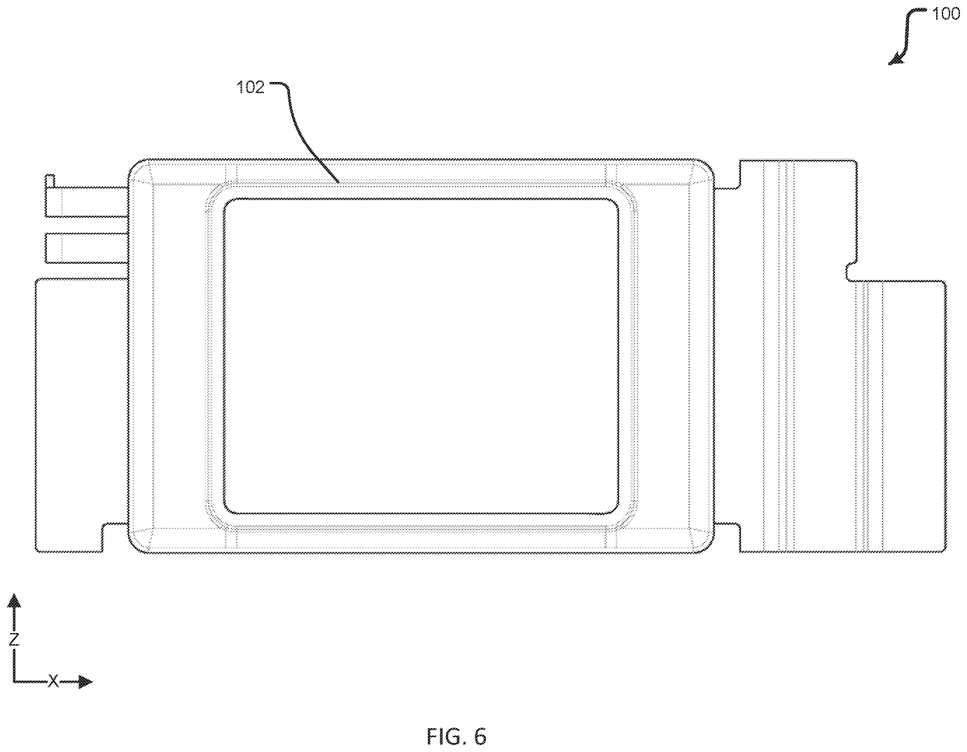

FIG. 6 illustrates a bottom side view of the external configuration of the power package according to FIG. 1.

In particular, FIGS. 1-6 illustrate various views of an external configuration 102 of a power package 100 according to aspects of the disclosure. The aspects of the power package 100 illustrated in FIGS. 1-6 may be implemented in any other aspects described herein. Moreover, other aspects described herein may be implemented in the power package 100 of FIGS. 1-6.

Additionally, the external configuration 102 of the power package 100 illustrated in FIGS. 1-6 is merely exemplary and the power package 100 may be implemented with any external configuration. Aspects of the power package 100 may be configured for implementation with the external configuration 102 of the power package 100 illustrated in FIGS. 1-6. However, further aspects of the power package 100 described herein provide additional implementations to an interior arrangement, layout, geometries, composition, and/or the like of multiple configurations, and/or the like of the power package 100.

In aspects, the external configuration 102 of the power package 100 may be configured to be well optimized for next generation power electronics. The external configuration 102 of the power package 100 may be configured to provide a number of benefits including low cost, easy to parallel, high thermal performance, reliable and high current laser welded power contacts, option for high thermal conductive package attaches to a system cold plate, and/or the like.

With reference to FIG. 1, the power package 100 may include power contacts 112 and signal contacts 114. The power contacts 112 of the power package 100 may be configured to be wide, flat tabs on opposing sides of the power package 100.

In particular, a width of the power contacts 112 may extend along the z-axis illustrated in FIG. 1. In aspects, the width of the power contacts 112 may be 60%-100% of a width of the power package 100, 60%-70% of a width of the power package 100, 70%-80% of a width of the power package 100, 80%-90% of a width of the power package 100, or 90%-100% of a width of the power package 100. In aspects, the power contacts 112 may be structured and arranged to have at least in part a flat portion in a plane of the x-axis and z-axis. The flat portion of the power contacts 112 may form a contact to other components, external components, and/or the like. In aspects, the power contacts 112 may be configured to be electrically and mechanically connect to another implementation of the power package 100, a bus bar, and/or the like. In aspects, the power contacts 112 of the power package 100 may be configured to be electrically and mechanically connected to another component, such as a system, an application component, an application device, a wire, a clipped connection, and/or the like. The electrical and mechanical connections between the power contacts 112 and the another component may be implemented through a number of structures, methods, and/or the like. In aspects, the electrical and mechanical connections between the power contacts 112 and the another component may include welded portions, welding, soldered portions, soldering, conductive epoxy, clips, spring contacts, mechanical fasteners, and/or the like. The welded portions may include laser welded portions, ultrasonic welding portions, and/or the like. The welding may include laser welding, ultrasonic welding, and/or the like.

In aspects of the power package 100, the signal contacts 114 may be grouped as illustrated in FIG. 1. In aspects, the signal contacts 114 may be grouped on one end of the power package 100 with one implementation of the power contacts 112 of a closest electrical potential. In aspects, the signal contacts 114 may be bent at ninety degrees. In particular, the signal contacts 114 may extend from the power package 100 a set distance in a plane of the x-axis and z-axis and thereafter extend along the y-axis. In this regard, the signal contacts 114 may have a bent portion. In particular, the signal contacts 114 may extend from the power package 100 in a plane of the y-axis and z-axis as illustrated in FIG. 1.

In aspects, the signal contacts 114 of the power package 100 may be configured to be electrically and mechanically connected to another component, such as a gate driver, a gate driver printed circuit board (PCB), a wire, a clipped connection, and/or the like. The electrical and mechanical connections between the signal contacts 114 and the another component may be implemented through a number of structures, methods, and/or the like. In aspects, the electrical and mechanical connections between the signal contacts 114 and the another component may include welded portions, welding, soldered portions, soldering, conductive epoxy, clips, spring contacts, mechanical fasteners, and/or the like. The welded portions may include laser welded portions, ultrasonic welding portions, and/or the like. The welding may include laser welding, ultrasonic welding, and/or the like.

As illustrated in FIG. 2, the power package 100 may be configured on a backside thereof with a thermal pad 116. The thermal pad 116 may be configured as an exposed metal thermal pad. Further, the thermal pad 116 may be configured with a large surface to thermally and mechanically attach to another component. The surface of the thermal pad 116 may be configured to facilitate the removal of waste heat from conduction, switching, package resistive losses, and/or the like from the power package 100. An area of the thermal pad 116 may comprise 50% to 95% of an area of the power package 100, 50% to 65% of an area of the power package 100, 65% to 75% of an area of the power package 100, 75% to 85% of an area of the power package 100, or 85% to 95% of an area of the power package 100.

Additionally, the thermal pad 116 may be configured to be attached via a connection to another component. The connection of the thermal pad 116 to another component may be implemented by sintering, soldering, conductive epoxy, thermal paste, and/or the like. In this regard, the thermal pad 116 may be configured to form the connection to another component utilizing one or more of these processes.

With reference back to FIG. 1, the power package 100 may include a molded assembly 118. The molded assembly 118 of the power package 100 may comprise a dielectric compound, a dielectric mold compound, a mold compound, and/or the like. The molded assembly 118 may surround one or more components of the power package 100, a majority the components of the power package 100, all of the components of the power package 100 with the exception of portions of the power contacts 112, the signal contacts 114, the thermal pad 116, and/or the like. The molded assembly 118 may be configured, structured, and/or arranged with the power package 100 to provide electrical isolation, voltage safety distances, mechanical support to the internal layout and power semiconductor devices, and/or the like.

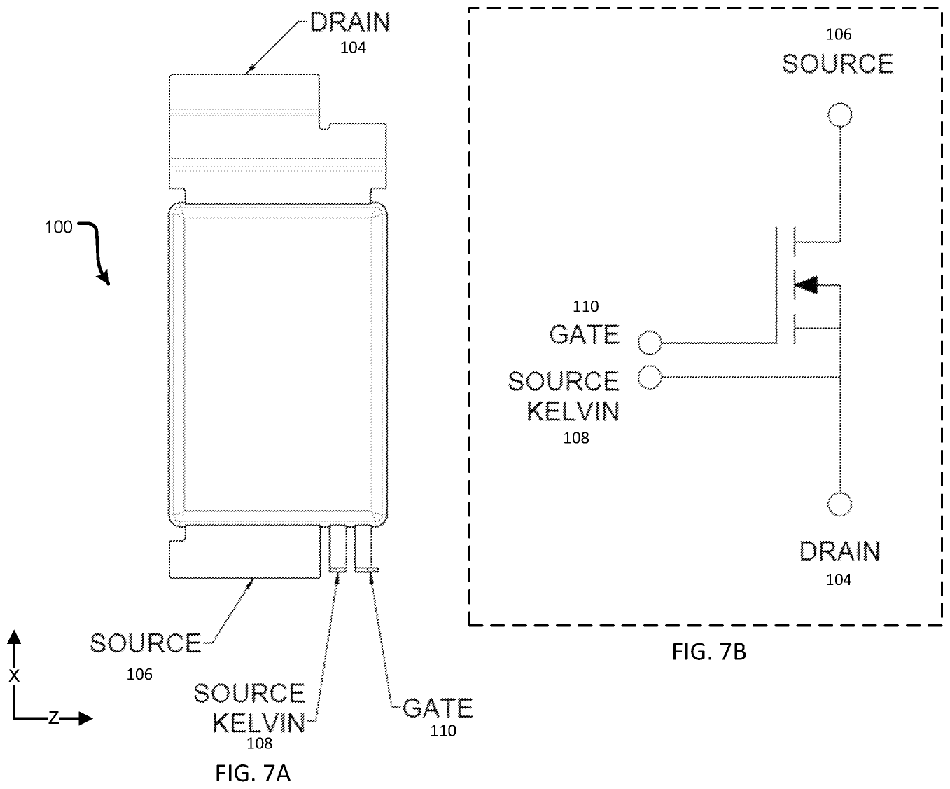

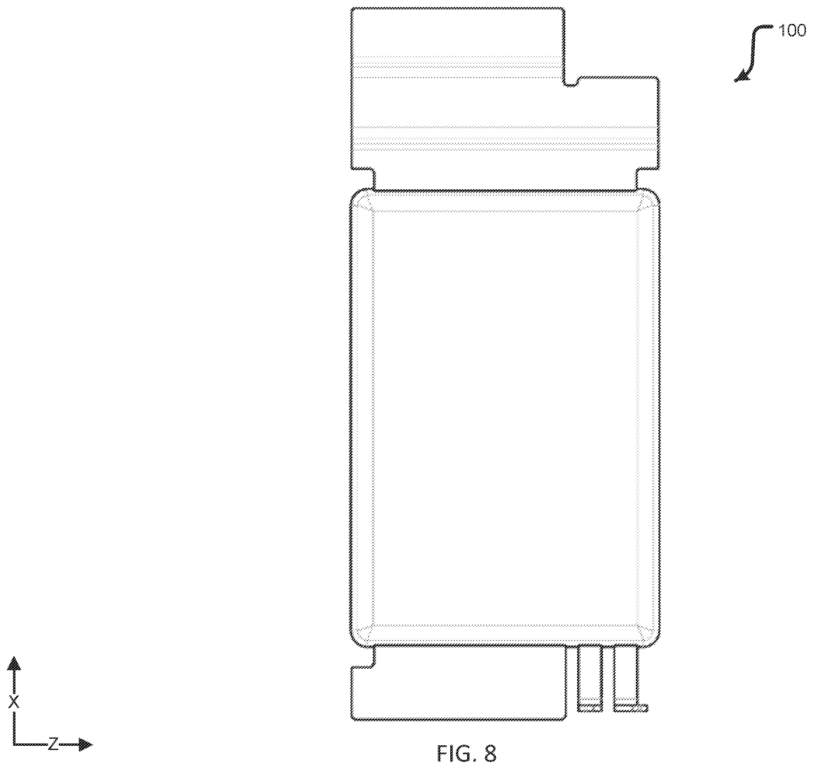

FIG. 7A illustrates a terminal arrangement of the power package 100 according to aspects of the disclosure; and FIG. 7B further illustrates a single switch topology of the power package 100 according to aspects of the disclosure.

In aspects, the power package 100 may be implemented with any number of terminals. In this regard, the FIG. 7A aspects of the power package 100 is implemented with a four terminal, single switch position configuration, which can house one or multiple power electronic switching devices. More specifically, the power package 100 may implement a drain terminal 104, a source terminal 106, a source Kelvin terminal 108, and a gate terminal 110.

It should be further noted that a physical implementation internally of the source Kelvin terminal 108 of the power package 100 may include a number of configurations as described herein. In aspects, the source Kelvin terminal 108 of the power package 100 may be implemented and configured as a true source kelvin, which configuration of the source Kelvin terminal 108 may be implemented with no overlapping path of power and signal loops. In aspects, the source Kelvin terminal 108 of the power package 100 may be implemented and configured as a pseudo source kelvin, which configuration of the source Kelvin terminal 108 may be implemented with some overlap of the power and signal loop.

Additionally, it should be appreciated that the implementation of the power package 100 illustrated in FIG. 7A with the terminals and circuit schematic shown in FIG. 7B are for a MOSFET implementation of the power package 100. In other aspects, the power package 100 may be implemented with other terminal configurations and other power device types, such as IGBT, JFET, and/or the like power device types. In this regard, the connections in these implementations of the power package 100 may be similar; however, the terminal names and circuit symbols for these implementations of the power package 100 would be specific to those power device types.

FIG. 8 illustrates an exemplary arrangement of one or more implementations of the power package to form circuit topology ‘building blocks’ according to aspects of the disclosure.

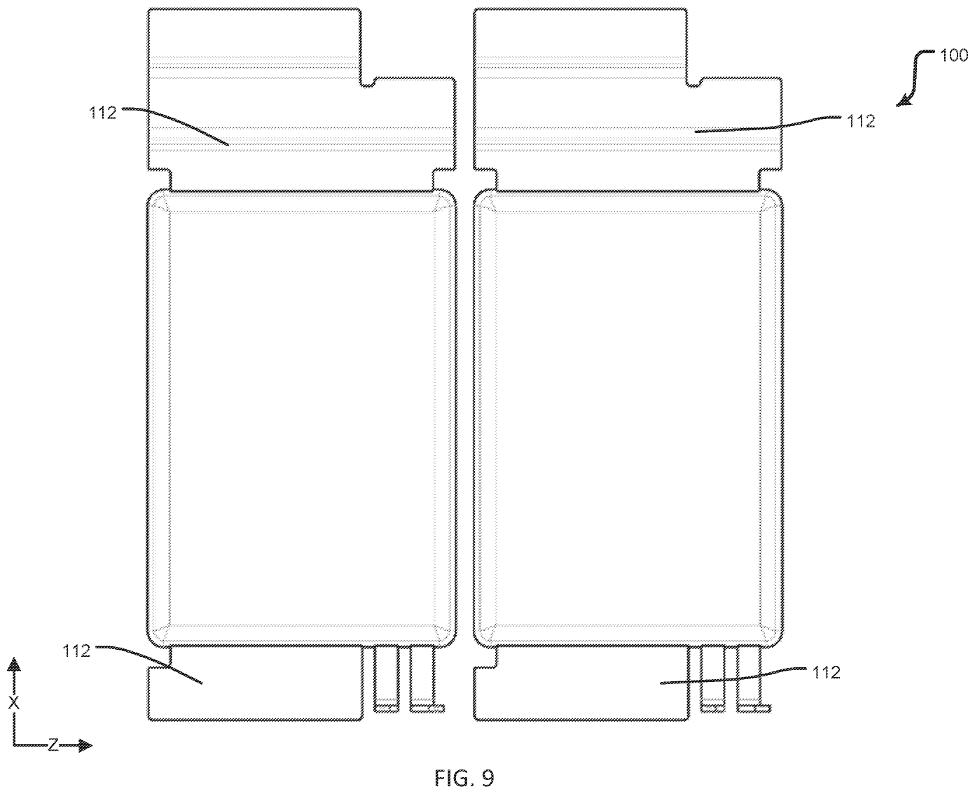

FIG. 9 illustrates an exemplary arrangement of one or more implementations of the power package to form circuit topology ‘building blocks’ according to aspects of the disclosure.

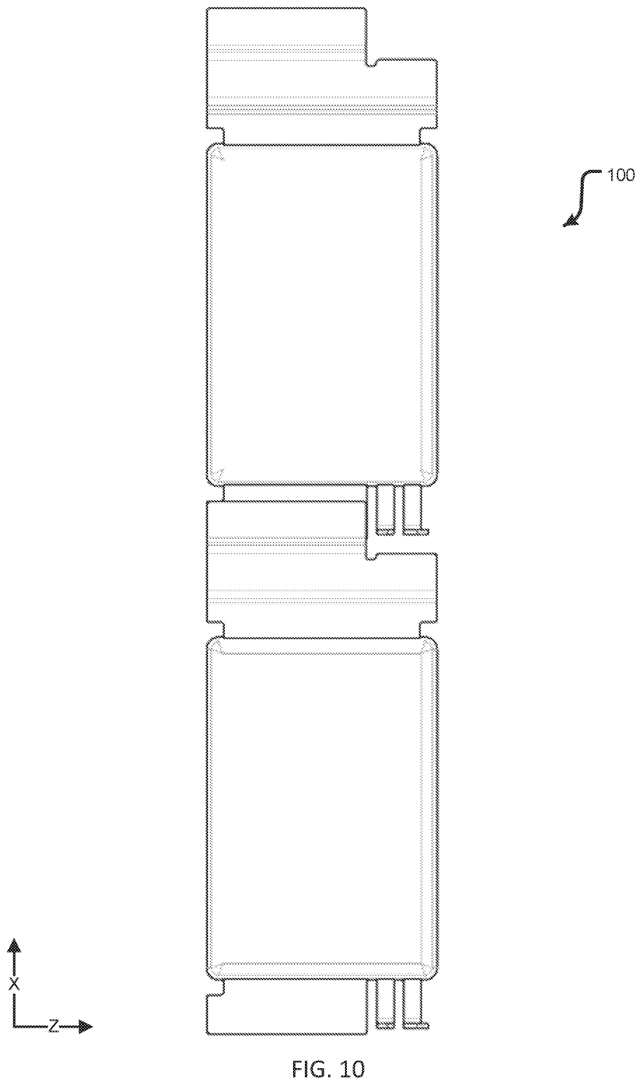

FIG. 10 illustrates an exemplary arrangement of one or more implementations of the power package to form circuit topology ‘building blocks’ according to aspects of the disclosure.

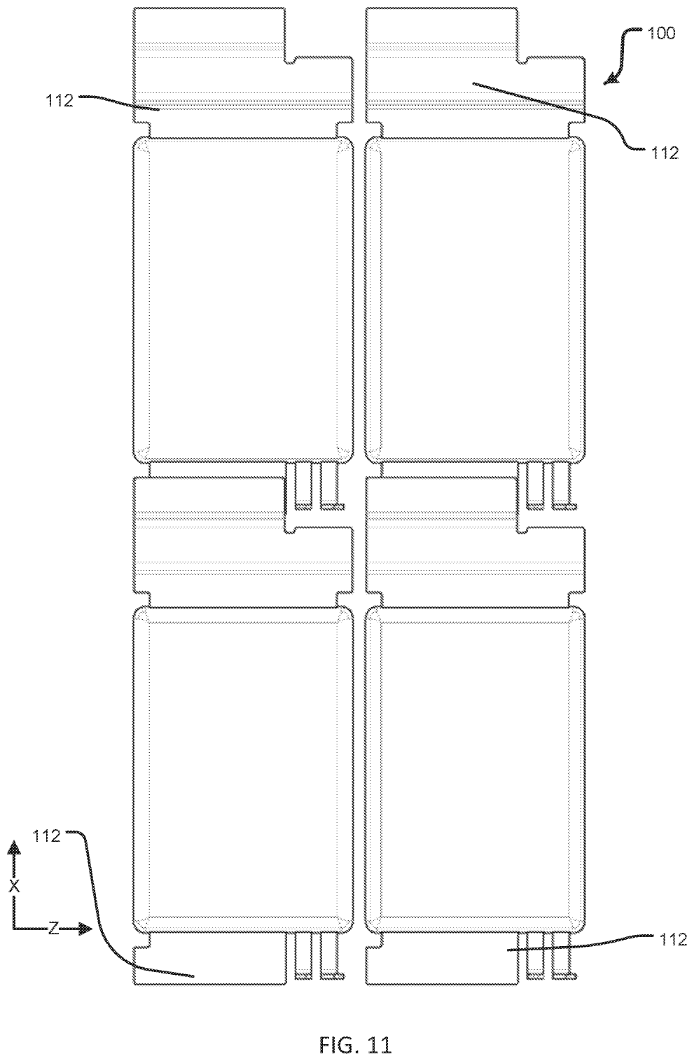

FIG. 11 illustrates an exemplary arrangement of one or more implementations of the power package to form circuit topology ‘building blocks’ according to aspects of the disclosure.

In particular, the aspects of the power package 100 illustrated in FIGS. 8-11 may include any other aspects as described herein. In this regard, FIGS. 8-11 illustrate exemplary arrangements of one or more implementations of the power package 100 to form circuit topology ‘building blocks’ according to aspects of the disclosure. More specifically, FIGS. 8-11 illustrate circuit topologies implementing one or more implementations of the power package 100. In this regard, arrangements of one or more implementations of the power package 100 may be configured as single positions and bridge legs, by themselves or with many in parallel, can achieve any of the circuit topologies described herein at any number of various scalable output power levels.

More specifically, FIG. 8 illustrates a single package implementation of the power package 100. FIG. 9 illustrates implementations of the power package 100 with parallel implementations of the power package 100 along the z-axis. In aspects, the parallel implementations of the power package 100 may be electrically connected at corresponding implementations of the power contacts 112 (not shown). In this regard, there may be any number of parallel implementations of the power package 100 along the x-axis.

FIG. 10 illustrates implementations of the power package 100 with a single bridge leg; and FIG. 11 illustrates implementations of the power package 100 with paralleled bridge legs. In aspects, the parallel implementations of the power package 100 may be electrically connected at corresponding implementations of the power contacts 112 (not shown). In this regard, there may be any number of paralleled bridge leg implementations of the power package 100 along the z-axis.

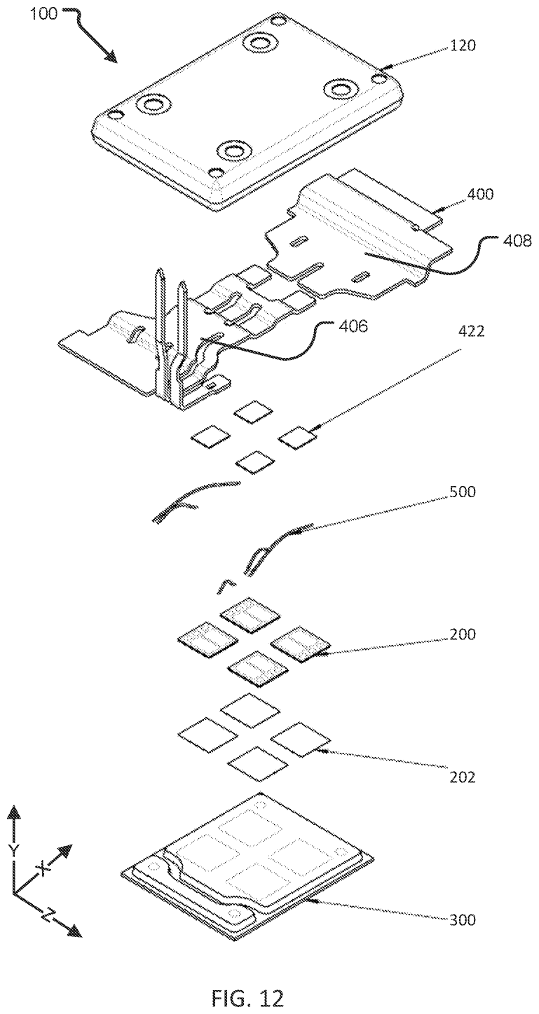

FIG. 12 illustrates an exploded view of the power package with exemplary components according to aspects of the disclosure.

In particular, the aspects of the power package 100 illustrated in FIG. 12 may include any other aspects as described herein. In this regard, FIG. 12 illustrates an exploded view of the power package 100 with exemplary components according to aspects of the disclosure. In aspects, the power package 100 may include one or more power devices 200, one or more device attaches 202, a power substrate 300, a lead frame power interconnection 400, power interconnection attach 422, a signal interconnection 500, a mold compound 120, and/or the like.

In aspects of the disclosure, the power package 100 may be configured as a type of package that may be referred to as an ‘over-molded power module.’ In aspects, during manufacture multiple implementations of the power package 100 may be assembled on a patterned lead frame array, encapsulated with a mold compound or similar composite dielectric material, singulated from the lead frame array, and finally the electrical contacts are formed into shape. Often, multiple parts of the power package 100 may be fabricated on a single lead frame to maximize throughput. The processes of manufacturing the power package 100 and the various configurations of the power package 100 described herein may be highly compatible with serial processing in an automated manufacturing line.

The following functional elements of the power package 100 may be used in the different layout configurations of the power package 100 as disclosed herein. However, the power package 100 may include fewer elements and/or additional elements within the scope of the disclosure.

In aspects, the one or more power devices 200 implemented by the power package 100 may be configured as power devices that may be configured and/or implemented as power semiconductor switches. In aspects, the power semiconductor switches implemented by the power package 100 may be sized to minimize a device area for a given power requirement.

In aspects, the one or more device attaches 202 implemented by the power package 100 may comprise a material for attaching the one or more power devices 200 to the power substrate 300. The material of the one or more device attaches 202 may be selected and/or implemented to (1) maximize thermal performance, (2) minimize cost, and/or the like.

In aspects, the power substrate 300 implemented by the power package 100 may comprise a material. The material of the power substrate 300 may be selected and/or implemented to (1) maximize thermal performance, (2) maximize reliability, (3) minimize cost, and/or the like.

In aspects, the lead frame power interconnection 400 may be initially formed as part of a lead frame. The material of the lead frame may be selected and/or implemented to be compatible with the attach method to the power substrate 300 and the lead frame power interconnection 400.

In aspects, the lead frame power interconnection 400 may include a lead frame first portion 406 and a lead frame second portion 408. The lead frame first portion 406 may be part of the source terminal 106 and/or may be connected to the source terminal 106; and the lead frame second portion 408 may be part of the drain terminal 104 and/or may be connected to the drain terminal 104.

In aspects, the power interconnection attach 422 may be configured as and/or implemented as a lead frame attach and/or a lead frame attach process. In aspects, the lead frame attach may include welded portions, solder portions, sintered portions, preformed portions, and/or the like. In aspects, the lead frame attach processes may include welding processes, solder paste processes, sintering processes, preform processes, and/or the like.

The lead frame power interconnection 400 of the power package 100 may be configured as a power interconnection. In aspects, the power connection of the lead frame power interconnection 400 may be configured such that a high current electrical connection may be formed through a direct welded connection, a soldered connection, a sintered connection, and/or the like connection to the lead frame that forms the lead frame power interconnection 400. In aspects, the power connection of the lead frame first portion 406 may be configured such that a topside high current electrical connection may be formed through: (1) a direct welded connection, a soldered connection, a sintered connection, and/or the like connection to the lead frame that forms the lead frame first portion 406; (2) power wire bonds from topside bond pads to the lead frame that forms the lead frame first portion 406; (3) power ribbon bonds from the topside bond pads to the lead frame that forms the lead frame first portion 406; and/or the like.

The signal interconnection 500 of the power package 100 may form a signal interconnection. In aspects, the signal interconnection may be configured as a topside electrical connection of the signal pads of the one or more power devices 200 to the signal contacts 114 of the power package 100. In aspects, the signal interconnection 500 may be configured as signal wire bonds.

In aspects, mold compound 120 of the power package 100 may be configured, structured, and arranged to form the molded assembly 118. The mold compound 120 may be implemented with a material and the material may be implemented and selected to (1) maximize reliability, (2) minimize stresses, (3) maximize dielectric performance, and/or the like.

These functional elements illustrated in FIG. 12 are merely exemplary. Further aspects and implementations of the various elements of the power package 100 may vary based off of the specific product configuration detailed in the proceeding descriptions disclosure.

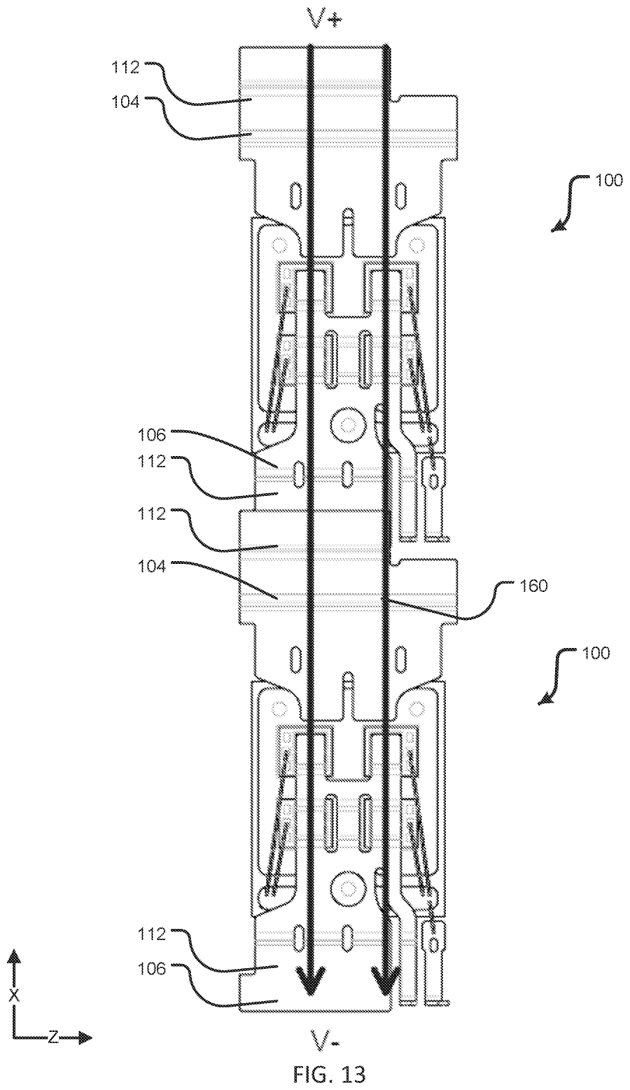

FIG. 13 illustrates an exemplary power loop implemented by configurations of the power package according to aspects of the disclosure.

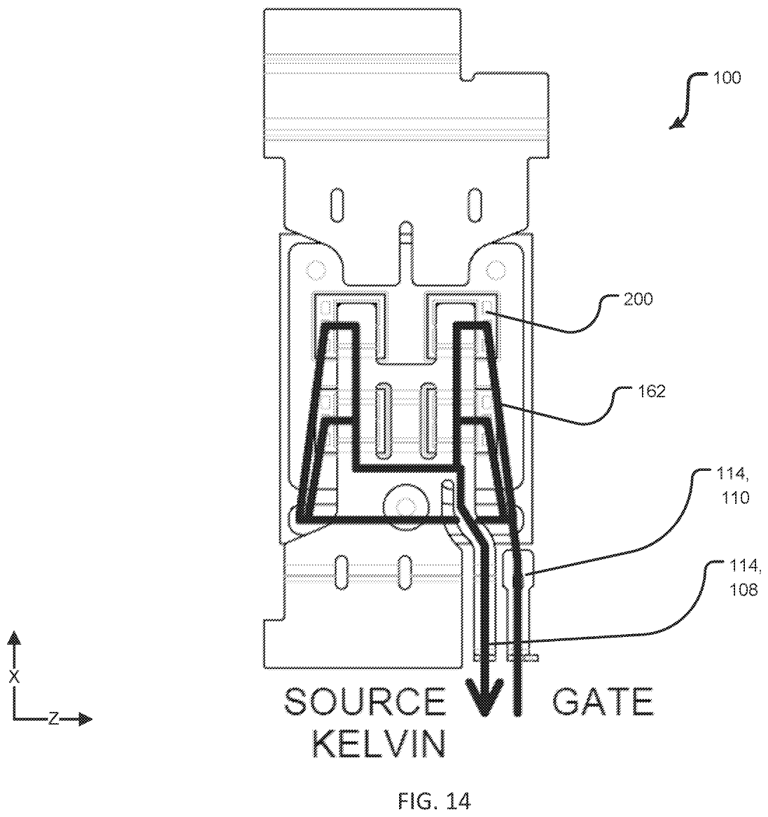

FIG. 14 an exemplary signal loop implemented by a configuration of the power package according to aspects of the disclosure.

In general, there may be at least two categories of electrical loops in the power package 100 of the disclosure. In particular, FIG. 13 illustrates an exemplary power loop 160 implemented by configurations of the power package 100; and FIG. 14 and an exemplary signal loop 162 implemented by a configuration of the power package 100.

In aspects illustrated in FIG. 13, the exemplary power loop 160 that may operate through implementations of the power package 100 may be a high voltage, high current path through the switch(es) that delivers power to the load through the drain (or collector) and source (or emitter) of the semiconductor device(s). In aspects, the exemplary power loop 160 may flow from the upper implementation of the power contacts 112 of the high side implementation of the power package 100 to the lower implementation of the power contacts 112 of the lower implementation of the power package 100. In aspects, the exemplary power loop 160 may flow from the drain terminal 104 of the high side implementation of the power package 100 to the source terminal 106 of the lower implementation of the power package 100.

In aspects illustrated in FIG. 14, the exemplary signal loop 162 may be implemented as a low voltage, low current path through the gate (or base) and the source (or emitter) of the semiconductor device(s). The gate-source (or base-emitter) signal path actuates the devices to turn-on or turn-off.

In aspects, the exemplary signal loop 162 may be implemented as a low voltage, low current path through the gate and the source of the semiconductor device(s). The gate-source signal path actuates the devices to turn-on or turn-off. In aspects, the exemplary signal loop 162 may be implemented as a low voltage, low current path through the gate and the source of the one or more power devices 200. The gate-source signal path actuates the one or more power devices 200 to turn-on or turn-off.

In aspects, the exemplary signal loop 162 may be implemented as a low voltage, low current path through the base and the emitter of the semiconductor device(s). The base-emitter signal path actuates the devices to turn-on or turn-off. In aspects, the exemplary signal loop 162 may be implemented as a low voltage, low current path through the base and the emitter of the one or more power devices 200. The base-emitter signal path actuates the one or more power devices 200 to turn-on or turn-off.

In aspects as illustrated in FIG. 13, the exemplary power loop 160 implemented by the power package 100 may operate such that the exemplary power loop 160 flows from a V+ terminal, which may be the drain terminal 104 of the high side implementation of the power package 100, to a V− terminal, which may be the source terminal 106 on the low side implementation of the power package 100.

In aspects as illustrated in FIG. 14, the exemplary signal loop 162 may be configured as a signal loop that flows from the gate terminal 110 to the source Kelvin terminal 108 (gate terminal to source terminal).

It should be noted that while there can be multiple such loops in implementations the power package 100 as disclosed, there are two that are particularly important for performance and reliability of the power package 100. For a number of applications, one or more implementations of the power package 100 be arranged in a half-bridge configuration and driving an inductive load. Accordingly, it is best to consider the power loop inductance as a bridge-leg of switch positions in series. These loops are illustrated in FIG. 13 and FIG. 14 for an exemplary product configuration implementing one or more implementations of the power package 100.

With further reference to FIG. 13, the exemplary power loop 160 or V+ terminal to V− terminal loop through one or more implementations of the power package 100 may be connected to a DC input. In aspects, this DC input may be a battery with a DC-link capacitor. Stored energy in a magnetic field existing in part in the one or more implementations of the power package 100, due to inductance, can result in high voltage overshoot during switching events. Minimizing inductance within one or more implementations the power package 100 will lessen those spikes. Depending on the system, a lower inductance can manifest in reliability improvements of implementations of the power package 100 due to less voltage stress, and/or allow for more aggressive, faster switching.

The exemplary signal loop 162 or the gate and source connection, for each switch position of the power package 100 may also require a low impedance to minimize voltage stresses on the gates of the one or more power devices 200 during switching. While these can be buffered or reduced by adding resistors within the power package 100, this is often at the cost of higher package complexity, higher cost, and slower switching speeds. Most importantly, for optimal switching performance, the power package 100 may be configured such that the exemplary power loop 160 and the exemplary signal loop 162 are configured to be more independent of each other to enable low switching loss with fast, well controlled dynamics.

The drain-source (or collector-emitter) and gate-source (or gate-emitter) loops of the exemplary signal loop 162 of the power package 100 may be configured to share the same connection at the source (or emitter) of the one or more power devices 200. If the power path couples into the signal paths of the power package 100, extra dynamics are introduced through either positive or negative feedback. Typically, negative feedback introduces extra losses as the power path coupling fights the control signal. For example, the power path coupling tries to turn the devices OFF when the control signal is trying to turn the devices ON. Positive feedback typically causes instability as the power path coupling amplifies the control signal until the devices are destroyed. Ultimately, the coupling of power and signal paths result in a reduction in switching quality, slower switching speeds, increased losses, and possible destruction.

Accordingly, to improve switching quality and to ensure independent loops within the power package 100, the power package 100 may be configured such that the power source connection has a separate path from the signal source (referred to as a source Kelvin) such that one does not overlap or interfere with the other. The closer the separate connections are made to the one or more power devices 200, the better the switching performance.

Implementing a true source kelvin is a tradeoff, as it requires extra signal interconnections and area on the power substrate for the layout. An alternative method and configuration disclosed herein uses a pseudo source kelvin, in which some of the paths overlap but not all of them. This can be implemented by the power package 100 by ‘branching off’ the source kelvin connection at some mid-point in the source path.

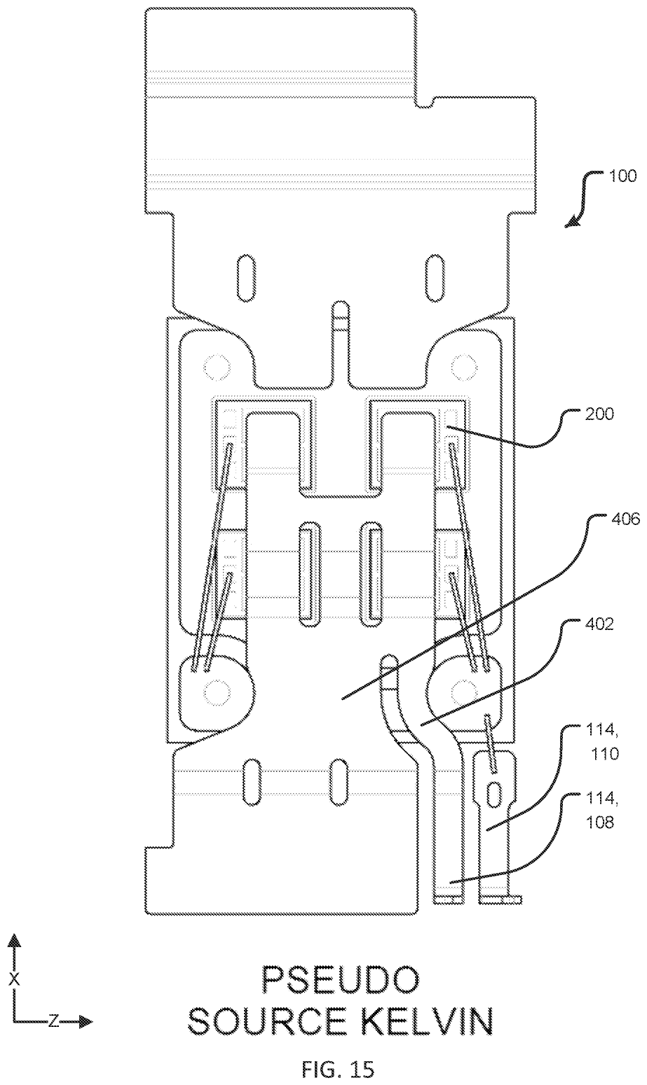

FIG. 15 illustrates an exemplary implementation of the power package implementing a pseudo source Kelvin configuration according to aspects of the disclosure.

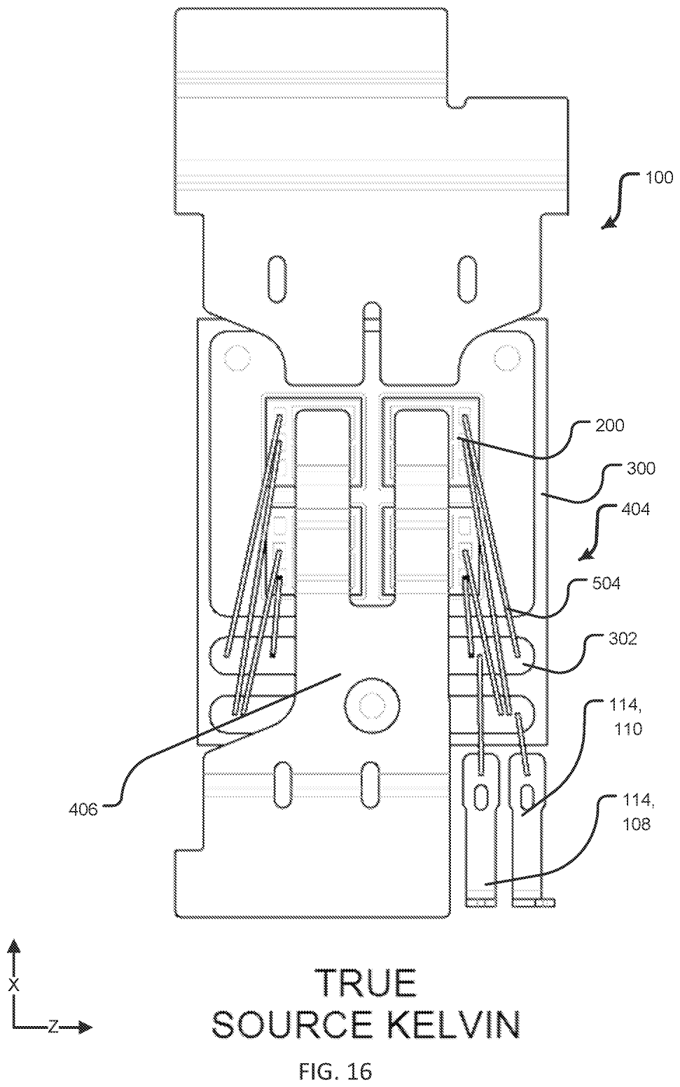

FIG. 16 illustrates an exemplary implementation of the power package implementing a true source Kelvin configuration according to aspects of the disclosure.

In particular, FIG. 15 illustrates an exemplary implementation of the power package 100 implementing a pseudo Kelvin connection 402; and FIG. 16 illustrates an exemplary implementation of the power package 100 implementing a true source Kelvin connection 404. The aspects of the power package 100 illustrated in FIGS. 15 and 16 may be implemented in any other aspects described herein. Moreover, other aspects described herein may be implemented in the power package 100 of FIGS. 15 and 16. The need for a true source kelvin implementation vs. pseudo source kelvin implementation depends on how the power package 100 may be used. In particular, the switching frequency, switching rates, and loss distribution (conduction vs. switching).

FIG. 15 illustrates an implementation of the power package 100 with a pseudo kelvin connection 402. The pseudo kelvin connection 402 may be connected to the lead frame first portion 406. However, the pseudo kelvin connection 402 may extend up close to the one or more power devices 200 to decouple the path overlap as much as possible from the lead frame first portion 406. In particular, the pseudo kelvin connection 402 may extend into the power package 100 before connecting to the lead frame first portion 406 and connecting to the one or more power devices 200 to decouple the path overlap as much as possible.

As illustrated in FIG. 16, the power package 100 may implement a true source kelvin connection 404. In aspects, the true source kelvin connection 404 may be separate from the lead frame first portion 406. In aspects, the true source kelvin connection 404 may have a dedicated trace 302 on the power substrate 300 and dedicated kelvin bonds 504 to the source pad on the one or more power devices 200.

In aspects, a spacing of the one or more power devices 200 may be closer and a drain pad on the power substrate 300 may be smaller for implementation of the true source kelvin connection 404. Accordingly, improved switching quality of the power package 100 may be at the expense of other performance characteristics of the power package 100.

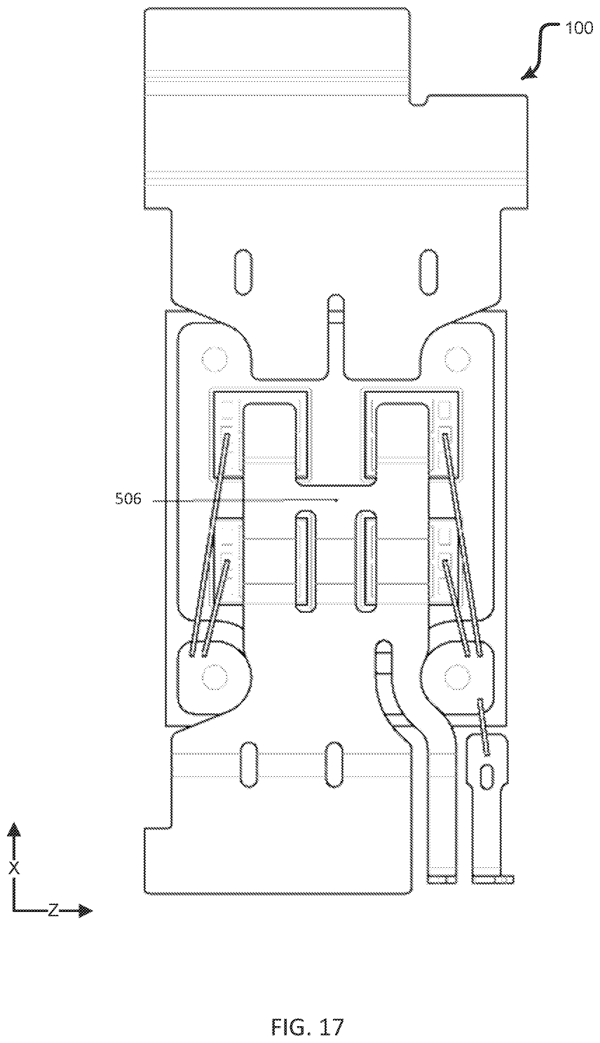

FIG. 17 illustrates another aspect of the power package implementing a connector according to aspects of the disclosure.

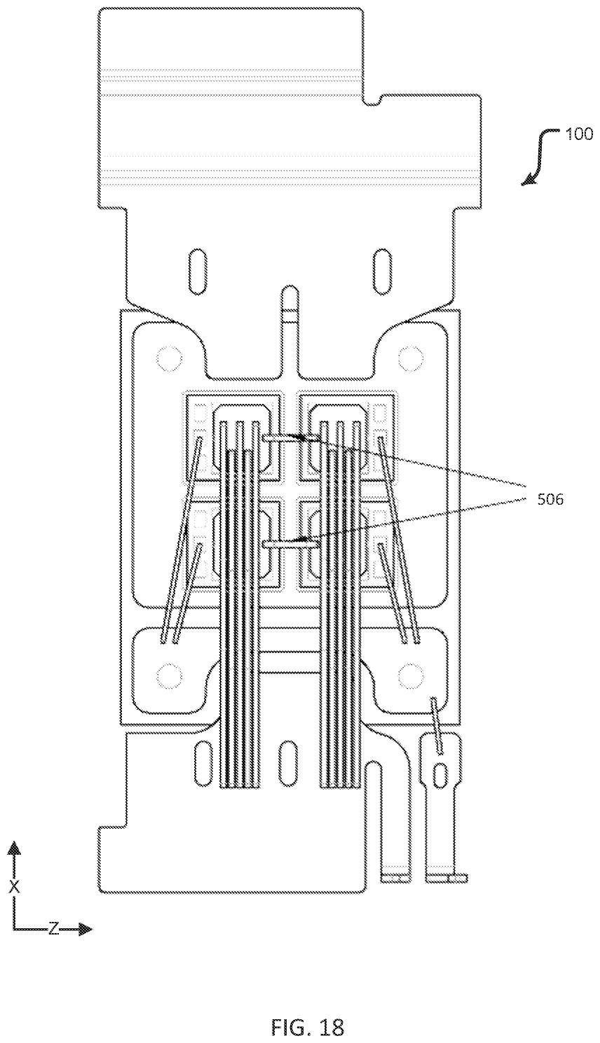

FIG. 18 illustrates another aspect of the power package implementing another aspect of a connector according to aspects of the disclosure.

In particular, FIG. 17 illustrates another aspect of the power package 100 implementing a connector 506; and FIG. 18 illustrates another aspect of the power package 100 implementing another aspect of the connector 506 according to aspects of the disclosure. The aspects of the power package 100 illustrated in FIGS. 17 and 18 may be implemented in any other aspects described herein. Moreover, other aspects described herein may be implemented in the power package 100 of FIGS. 17 and 18. In this regard, a further issue in implementations of the power package 100 may arise in transconductance mismatches between paralleled implementations of the one or more power devices 200. Transconductance may be effectively the current gain of the one or more power devices 200—the relationship between the output current to the input voltage. During switching of the one or more power devices 200, the input voltage rises and results in an associated rise in the output current of the one or more power devices 200. If there is a transconductance difference between paralleled implementations of the one or more power devices 200, which may be common in Silicon Carbide implementations of the one or more power devices 200, the one or more power devices 200 may each have slightly different turn on characteristics. With different currents running through each implementation of the one or more power devices 200, the one or more power devices 200 may have slightly different voltages across themselves. This voltage mismatch will result in a ‘balancing current’ that flows between the one or more power devices 200 during switching.

This balancing current will prefer the path of least impedance, which could be through the signal loop instead of the power loop of the power package 100. Like the issues of interference with the coupled power and signal loops, this balancing current can affect switching quality of the power package 100. Introducing this high, uncontrolled current through the signal loop of the power package 100 can also introduce a reliability concern as the signal loops are not intended to carry high currents.

In aspects of the power package 100, a balancing return path can be achieved through the connector 506. As illustrated in FIG. 17, the connector 506 may be configured as a centralized connecting bar in the lead frame first portion 406; and as illustrated in FIG. 18, the connector 506 may be implemented as jumper wire bonds between the one or more power devices 200. It should be noted that in many cases this balance path is not necessary and is not needed. Its implementation may be considered optional and the bonding region that would be utilized by the connector 506 could be used for more power bonds on the one or more power devices 200 instead. However, in aspects of the power package 100, a transconductance difference between paralleled implementations of the one or more power devices 200 may not be an issue and accordingly in such aspects, implementation of the connector 506 may be avoided.

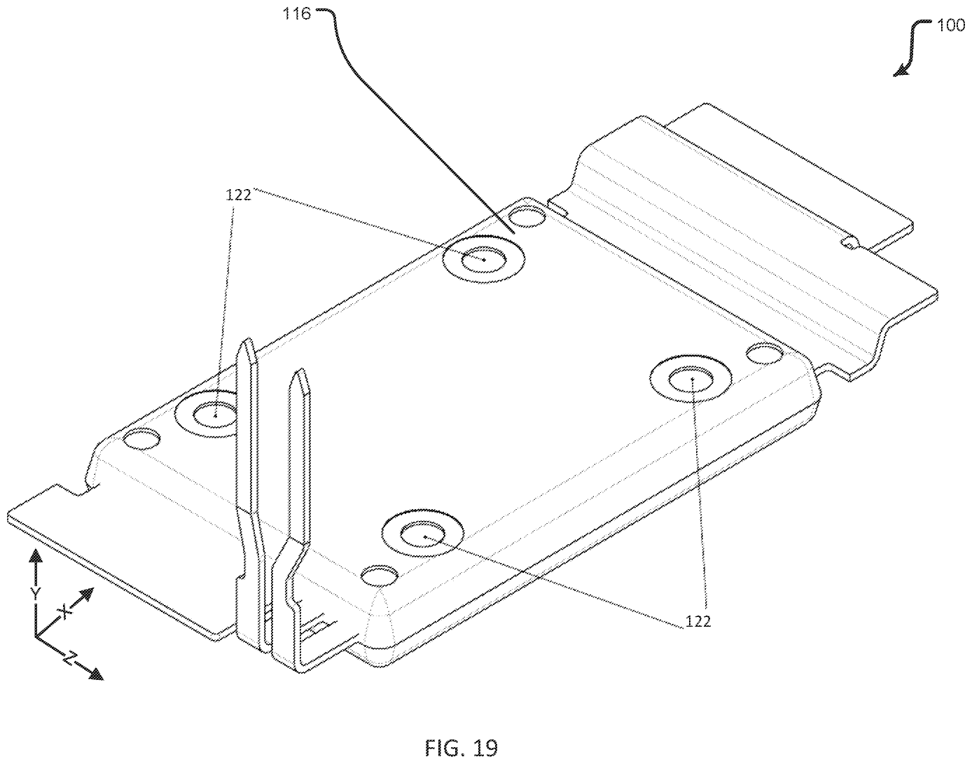

FIG. 19 illustrates another aspect of the power package implementing hold down configurations according to aspects of the disclosure.

In particular, FIG. 19 illustrates another aspect of the power package implementing hold down configurations 122 The aspects of the power package 100 illustrated in FIG. 19 may be implemented in any other aspects described herein. Moreover, other aspects described herein may be implemented in the power package 100 of FIG. 19.

In aspects of the disclosure, it may be beneficial that the thermal pad 116 of the power package 100 be free of mold compound after the over-molding process to form of the mold compound 120. Due to process and part variation of the power package 100, there is a chance that some mold flow or resin bleed may creep onto the thermal pad 116. To limit this, the power substrate 300 may be clamped down onto a mold tooling such that much of this flow is shut off. Accordingly, in aspects of the manufacturer the power package 100, cylindrical, tapered pins are used to accomplish this. The location and pattern of these pins is layout driven based on various design parameters of the power package 100. The hold down pins will leave a corresponding tapered holes or vestiges in the finished implementation of the power package 100.

FIG. 19 illustrates the thermal pad 116 and hold down pin vestiges in the mold compound 120 for an exemplary configuration of the power package 100. Accordingly, the thermal pad 116 may include implementations of the hold down configurations 122 arranged thereon. The location and diameter of the hold down pins may vary based on internal layout. Accordingly, implementations of the hold down configurations 122 may vary as well.

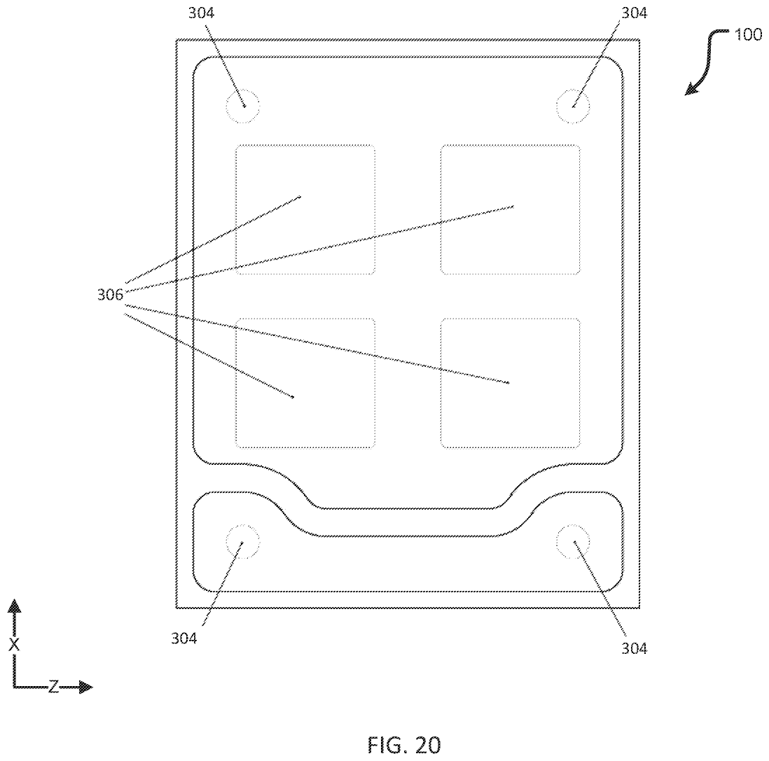

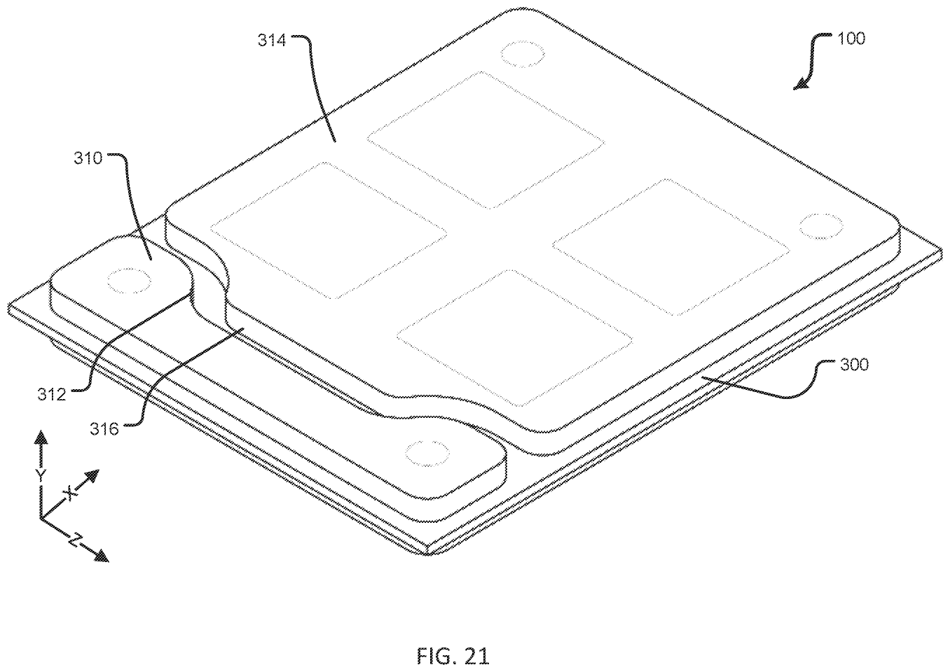

FIG. 20 illustrates another aspect of the power package implementing fiducial configurations according to aspects of the disclosure.

In particular, FIG. 20 illustrates another aspect of the power package 100 implementing fiducial configurations 304. The aspects of the power package 100 illustrated in FIG. 20 may be implemented in any other aspects described herein. Moreover, other aspects described herein may be implemented in the power package 100 of FIG. 20.

In many cases, a fiducial or alignment mark or feature may be used on the power substrate 300 for pattern recognition systems of manufacturing equipment. These markings need to be visually recognizable when viewing the power package 100 from above through multiple assembly steps. Since the hold down pins need vertical access to move up and down during transfer molding, their locations, a location of the hold down configurations 122 may also be compatible to also be used for fiducial markings implemented as the fiducial configurations 304.

The fiducial configurations 304 may be configured as markings and may be formed with selective plating, laser marking, etching, solder masking, inking, and/or similar marking method. For many attach methods, a fully or selectively plated metal in device regions 306 may be beneficial. Accordingly, forming the power substrate 300 for as a fiducial pattern with selective plating in the same location as the hold down configurations 122 for the hold down pins combines functionality without adding additional process steps.

FIG. 20 illustrates the power substrate 300 as well as exemplary implementations of the fiducial configurations 304 configured to implement a fiducial and the device regions 306 implemented as a device region pattern of an example configuration. Note that the shape of the fiducials does not have to be circular and may vary based on marking method and process. Also note that some device attaches do not need selective plating and in these cases the regions may be left un-plated.

FIG. 21 illustrates another aspect of the power package implementing configurations of the power substrate according to aspects of the disclosure.

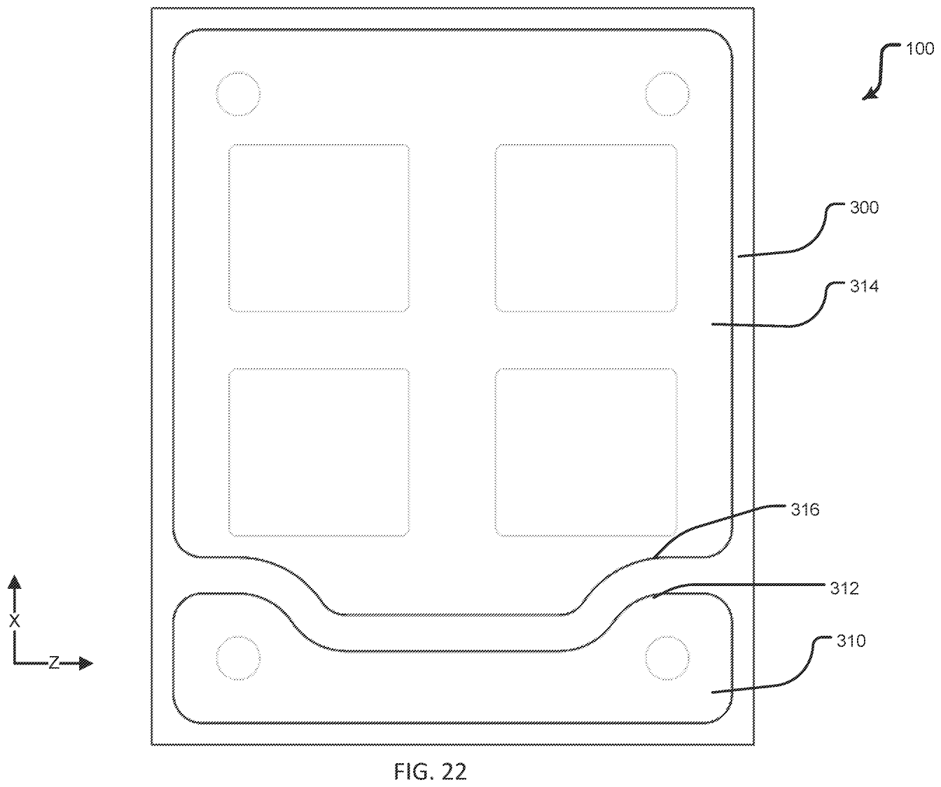

FIG. 22 illustrates another aspect of the power package implementing configurations of the power substrate according to aspects of the disclosure.

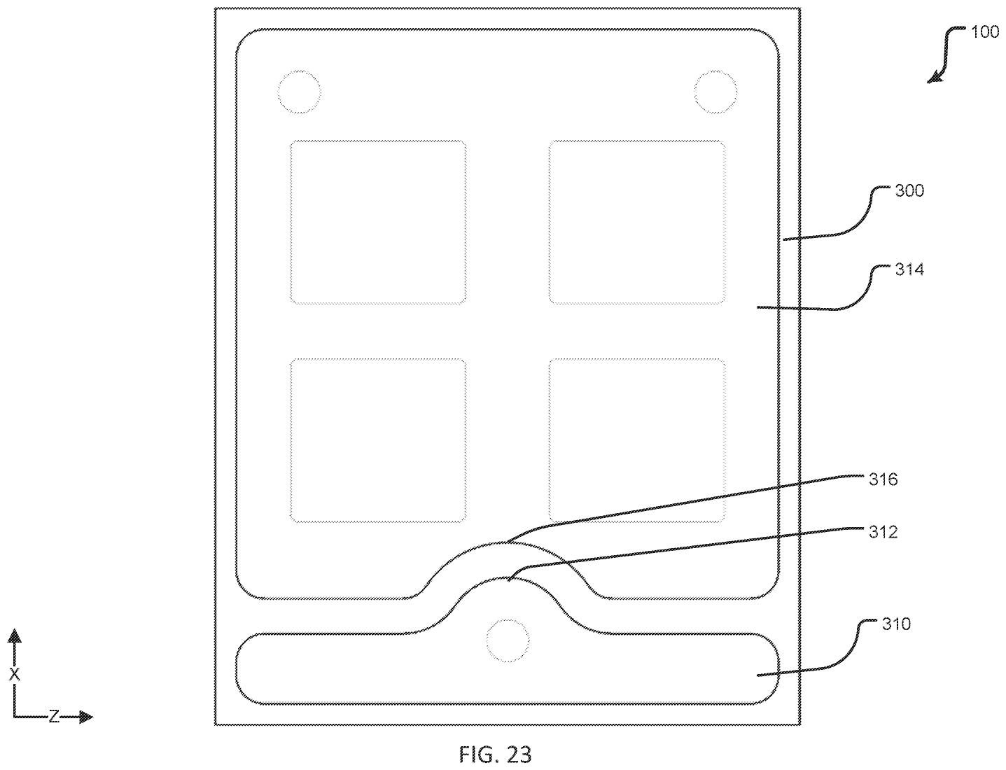

FIG. 23 illustrates another aspect of the power package implementing configurations of the power substrate according to aspects of the disclosure.

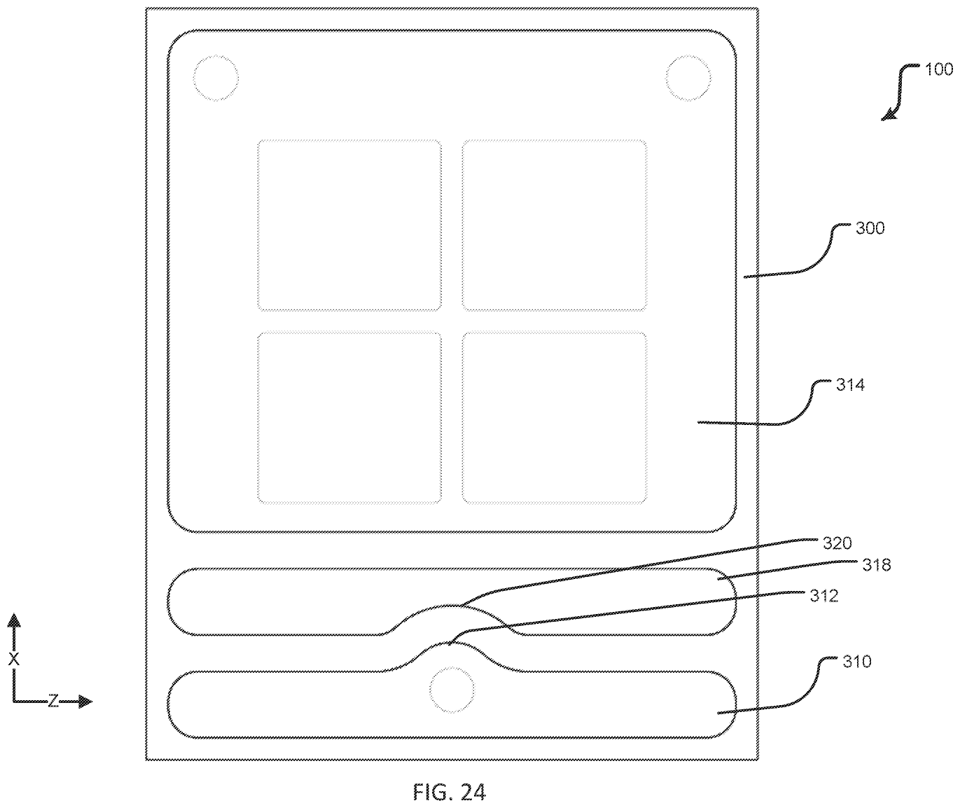

FIG. 24 illustrates another aspect of the power package implementing configurations of the power substrate according to aspects of the disclosure.

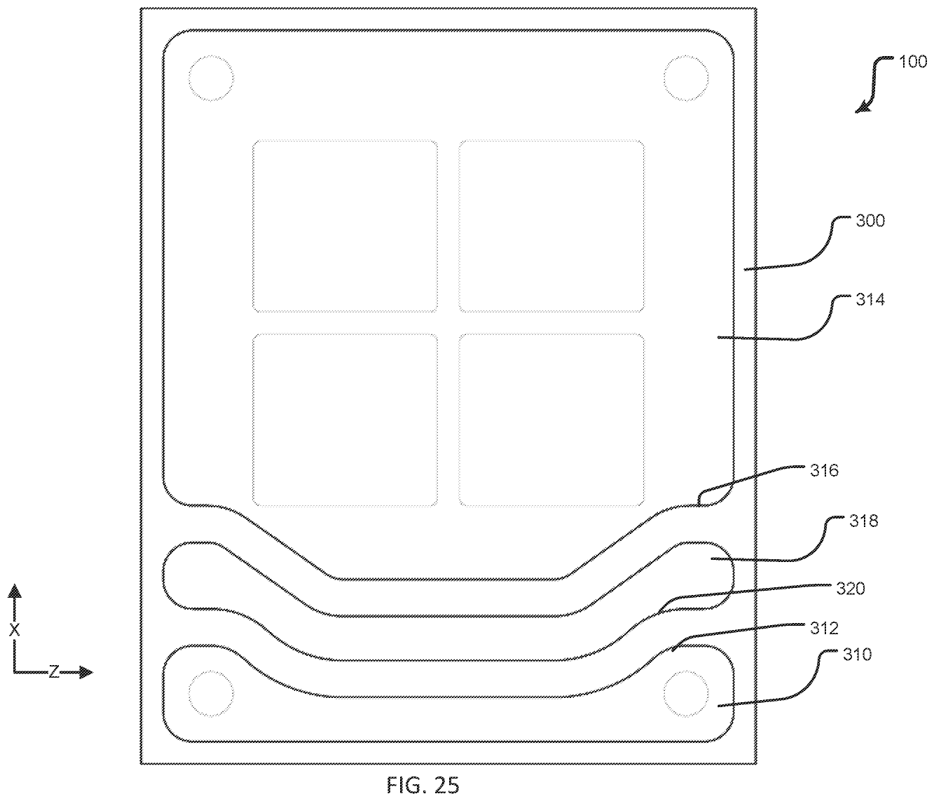

FIG. 25 illustrates another aspect of the power package implementing configurations of the power substrate according to aspects of the disclosure.

In particular, FIGS. 21-25 illustrate further aspects of the power package 100 implementing configurations of the power substrate 300. The aspects of the power package 100 illustrated in FIGS. 21-24 may be implemented in any other aspects described herein. Moreover, other aspects described herein may be implemented in the power package 100 of FIGS. 21-25.

As illustrated in FIG. 21 and FIG. 22, the power substrate 300 of the power package 100 may be configured with layout contouring. In this regard, the clamping pressure from the hold down pins can run the risk of damaging the power substrate 300, which may be ceramic or a similar insulating layer. In this regard, if the clamping pressure is too high or unevenly distributed, the power substrate 300 may be damaged. Further, pressure distributions can also be detrimental if the pin head is too small or the metal region of the power substrate 300 being pressed on is too narrow.

Accordingly, the power substrate 300 may implement a substrate layout that can contour around the hold down pins to add material to the power substrate 300 where it is needed and allow for more metal on a drain trace of the power substrate 300 for heat spreading of the one or more power devices 200. This is illustrated in FIGS. 21-25 for layouts with various hold down pin locations (indicated by the circles) and source kelvin implementation (one or two signal traces).

In particular aspects illustrated in FIG. 21, the power substrate 300 may include a first metal 310 having a first contoured portion 312. The power substrate 300 may have a second metal portion 314 and the second metal portion 314 may have a second contoured portion 316. In aspects, the first contoured portion 312 and the second contoured portion 316 may have corresponding shapes such that a distance between the second metal portion 314 and the first metal 310 remain generally the same.

FIG. 23 illustrates an implementation of the power substrate 300 where there is a single hold down pin location arranged on the first metal 310. In this regard, the first contoured portion 312 is located strategically at this single hold down pin location.

FIG. 24 illustrates an implementation of the power substrate 300 having a third metal portion 318 implementing a third contoured portion 320 adjacent the first contoured portion 312 of the first metal 310. In this regard, the first contoured portion 312 is located strategically at this single hold down pin location.

FIG. 25 illustrates an implementation of the power substrate 300 implementing the first metal 310 having the first contoured portion 312, the second metal portion 314 having the second contoured portion 316, and the third metal portion 318 having the third contoured portion 320. In this regard, the first contoured portion 312 is located strategically at hold down pin locations.

In aspects, the first contoured portion 312, the second contoured portion 316, and/or the third metal portion 318 may have non-rectangular shapes that smoothly contour about a periphery of a respective metal portion. In aspects, the first contoured portion 312, the second contoured portion 316, and/or the third metal portion 318 may have shapes that smoothly contour about one or more hold down pin locations. Moreover, the first contoured portion 312, the second contoured portion 316, and/or the third metal portion 318 may provide increased strength at pin locations as well as a greater area for heat spreading.

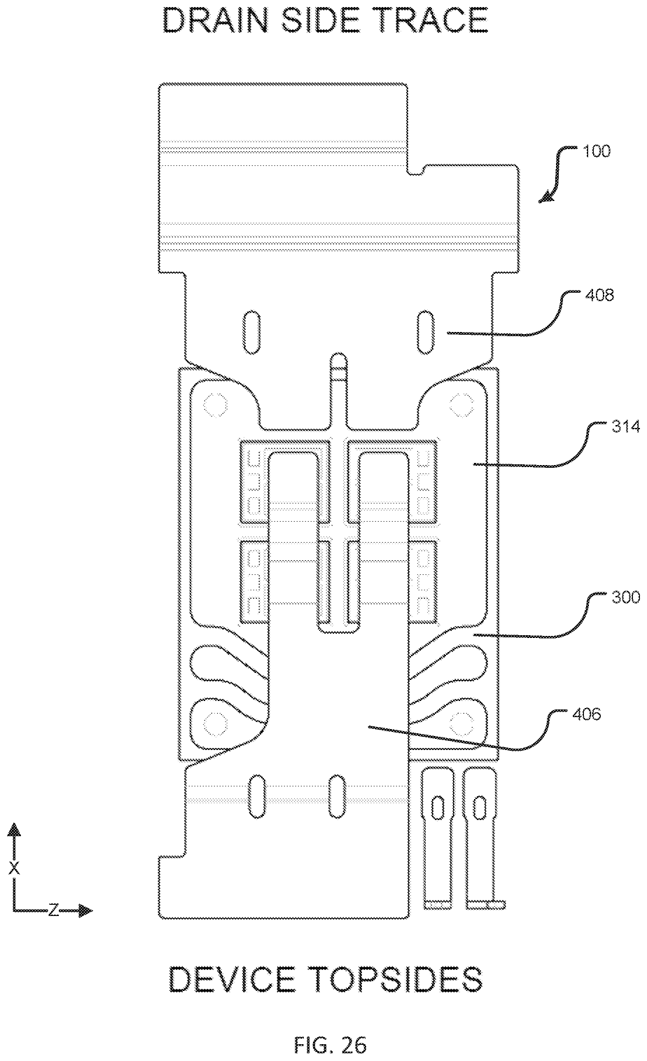

FIG. 26 illustrates aspects of the power package according to aspects of the disclosure.

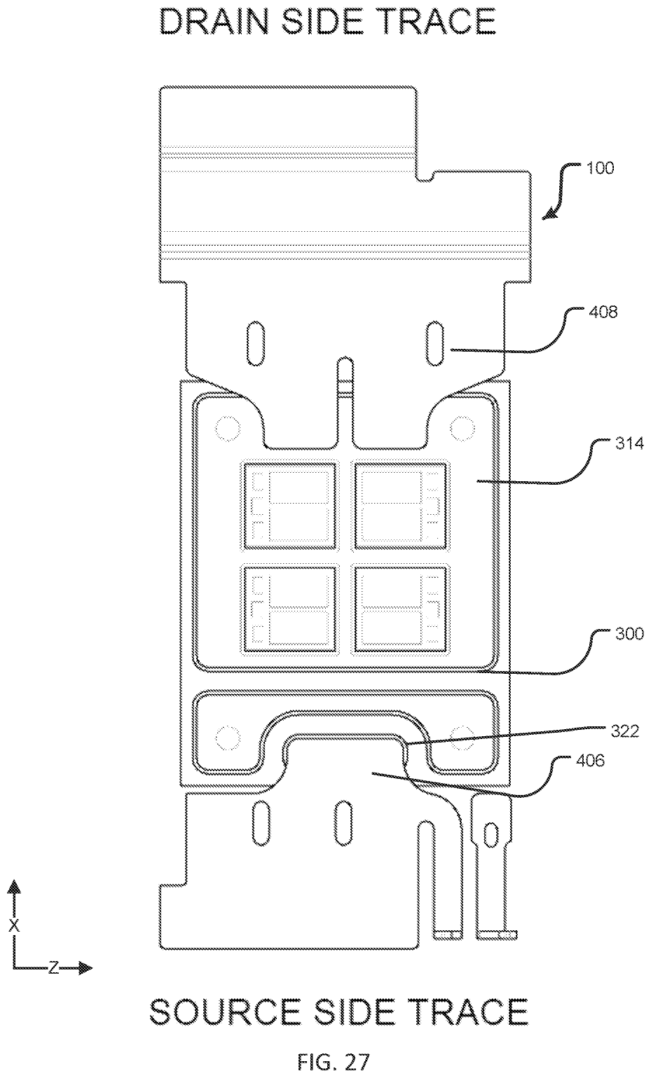

FIG. 27 illustrates aspects of the power package according to aspects of the disclosure.

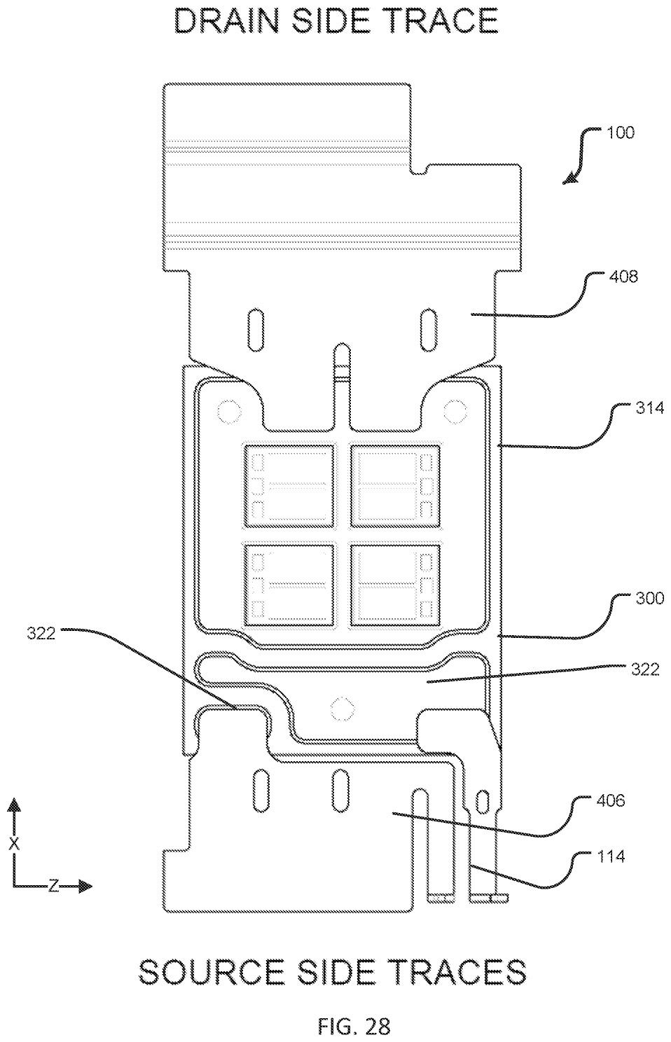

FIG. 28 illustrates aspects of the power package according to aspects of the disclosure.

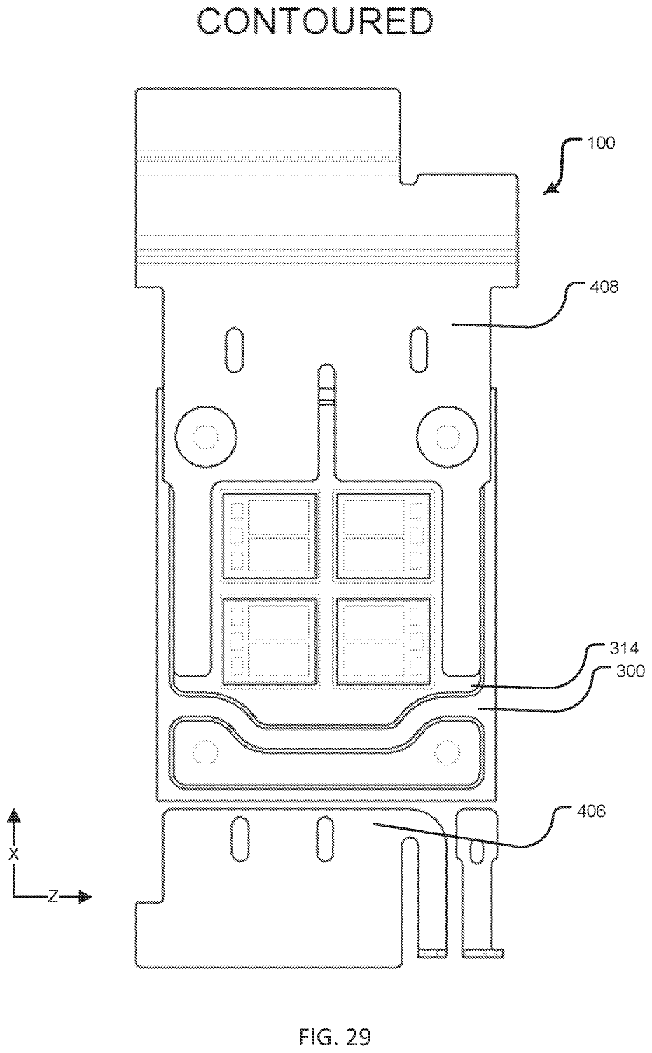

FIG. 29 illustrates aspects of the power package according to aspects of the disclosure.

In particular, FIGS. 26-29 illustrate further aspects of the power package 100. The aspects of the power package 100 illustrated in FIGS. 26-29 may be implemented in any other aspects described herein. Moreover, other aspects described herein may be implemented in the power package 100 of FIGS. 26-29.

In particular, FIGS. 26-29 illustrate aspects of a mechanical linkage of the lead frame power interconnection 400. In this regard, implementations of the power package 100 may be configured in view of a fact that a stable mechanical connection of the lead frame or the lead frame power interconnection 400 to the power substrate 300 may be beneficial to provide support during handling and manufacturing processes of the power package 100 prior to over-molding. In many cases, this also may be used for an electrical connection to the power substrate 300 and the one or more power devices 200 of the power package 100.

FIGS. 26-29 illustrate various linkage variations implemented by the lead frame power interconnection 400. As previously noted, the lead frame power interconnection 400 may include the lead frame first portion 406 and the lead frame second portion 408. In aspects, the lead frame first portion 406 may be implemented as a drain linkage and the lead frame second portion 408 may be implemented as a source linkage.

In some aspects of the power package 100, the drain linkage implemented by the lead frame second portion 408 is readily formed by bonding to the edge of the drain trace. In aspects, the drain trace may be implemented by the second metal portion 314 of the power substrate 300. For configurations where attachment from the source side is not possible, the drain linkage implemented by the lead frame second portion 408 can be contoured around the one or more power devices 200 to increase the linkage strength and support the power substrate 300 from its center of mass as illustrated in FIG. 29. In this regard, the lead frame second portion 408 may extend substantially over the second metal portion 314 and past one or more implementations of the one or more power devices 200. In aspects, the lead frame second portion 408 have portions that may extend substantially over the second metal portion 314 and extend past and along one or more implementations of the one or more power devices 200.

In aspects, the lead frame first portion 406 may be implemented as clip attach. For a clip attach implementation the power package 100, the source side linkage or the lead frame first portion 406 may be formed through a topside clip attach implementation as illustrated in FIG. 26. In this regard, between the lead frame first portion 406 and the one or more power devices 200 may be arranged the power interconnection attach 422, which are illustrated in FIG. 12.

For wire and ribbon bonded approaches, a sacrificial trace on the power substrate 300 can be added for the sole function of providing support. For example, a trace 322 on the power substrate 300 may be used to form the mechanical and electrical connection with the lead frame first portion 406 as illustrated in FIG. 27 and FIG. 28. This may be formed on one side of the power substrate 300, both sides of the power substrate 300, or the center of the trace of the power substrate 300, depending on specific variation of the power package 100. Likewise, another implementation of the trace 322 may be utilized to support an implementation of the signal contacts 114 as illustrated in FIG. 28.

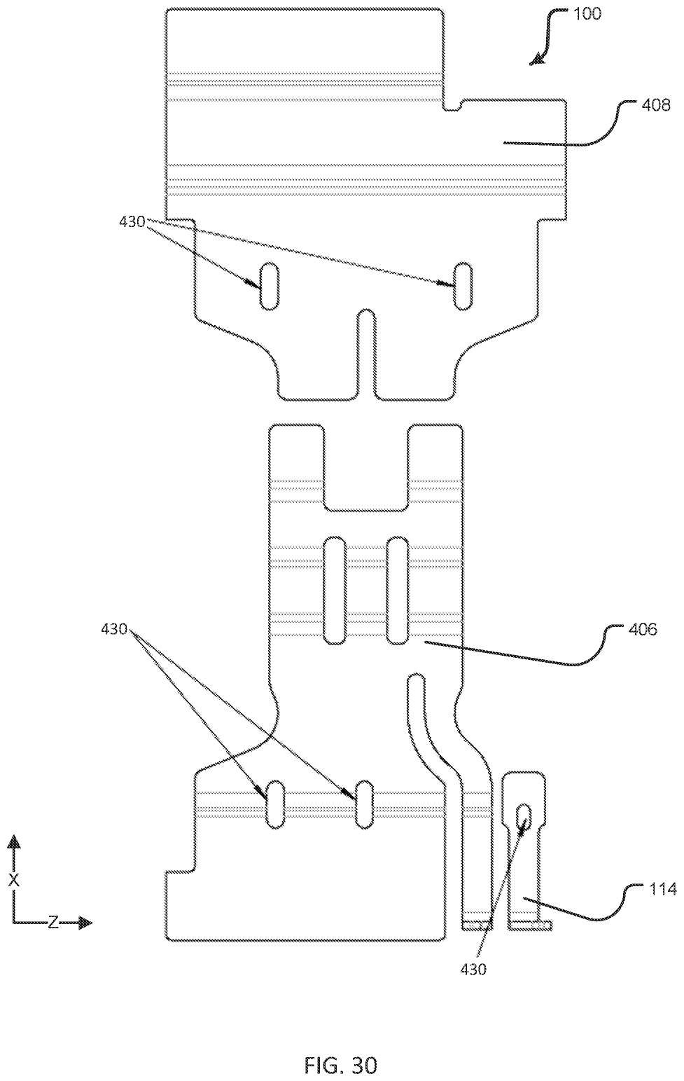

FIG. 30 illustrates aspects of the power package according to aspects of the disclosure.

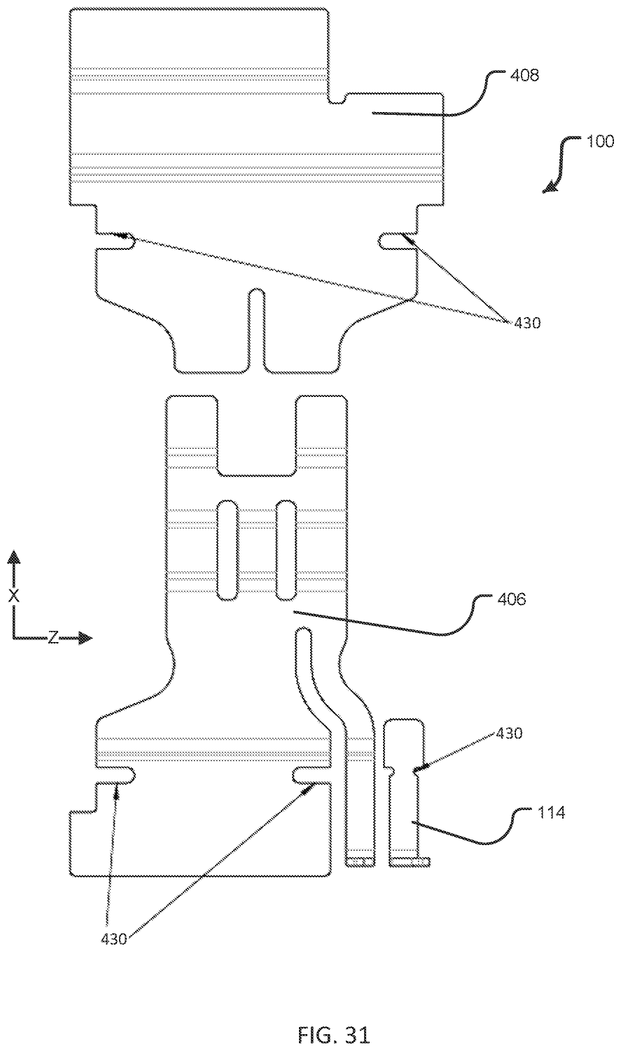

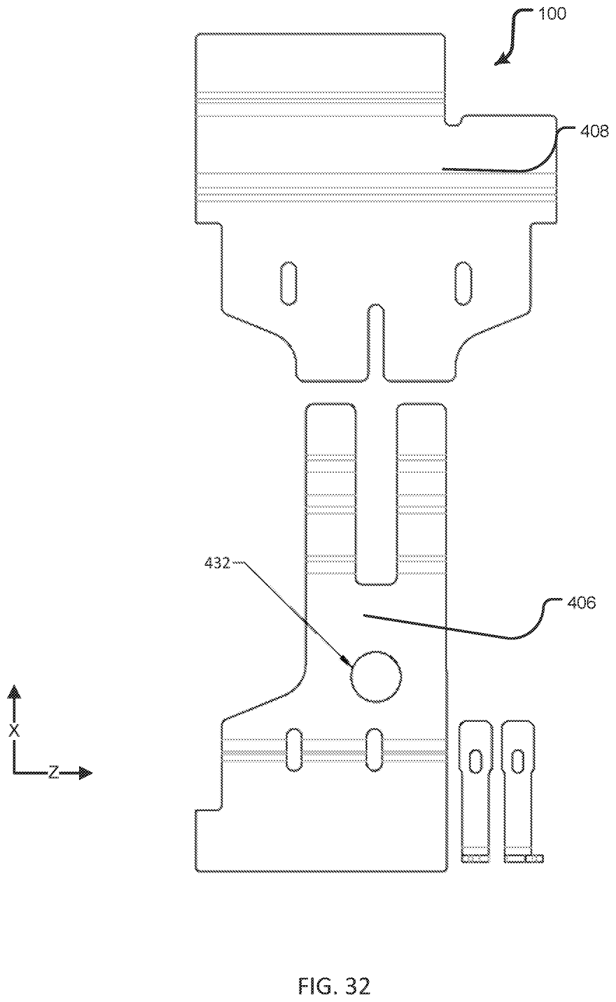

FIG. 31 illustrates aspects of the power package according to aspects of the disclosure.

In particular, FIGS. 30 and 31 illustrate further aspects of the power package 100. The aspects of the power package 100 illustrated in FIGS. 30 and 31 may be implemented in any other aspects described herein. Moreover, other aspects described herein may be implemented in the power package 100 of FIGS. 30 and 31.

In aspects, the lead frame power interconnection 400 of the power package 100 may be configured to utilize strain relief. In this regard, the power contacts 112 and the signal contacts 114 may be electrically and mechanically connected to other packages, wires, printed circuit boards, bus bars, and/or the like. Further, it is not desired for external mechanical stresses due to vibration, mechanical shock, thermal expansion, and/or the like to be transferred to the components of the power package 100, such as the power interconnection attach 422 of the lead frame power interconnection 400, internal to the power package 100.

To account for this, strain relieving features 430 may be included in the lead frame to anchor and transfer these external strains to noncritical areas. For example, the lead frame second portion 408 or the lead frame first portion 406 may include one or more implementations of the strain relieving features 430. Similarly, one or more implementations of the signal contacts 114 may include one or more implementations of the strain relieving features 430. In aspects, the strain relieving features 430 may be implemented as through holes, slots, shoulders, other openings, and/or the like in the lead frame to ensure the strain is located at these interfaces with the mold compound 120 and not the attach layers. In this regard, FIG. 30 illustrates an elongated hole implementations of the strain relieving features 430; and FIG. 31 illustrates slot implementations of the strain relieving features 430.

In particular, the completed implementation of the power package 100 that includes the mold compound 120 may further include the mold compound 120 having portions that extend through the strain relieving features 430. Accordingly, the mold compound 120 may absorb any strain on the lead frame first portion 406, the lead frame second portion 408, and/or the signal contacts 114 by the material extending through the strain relieving features 430.

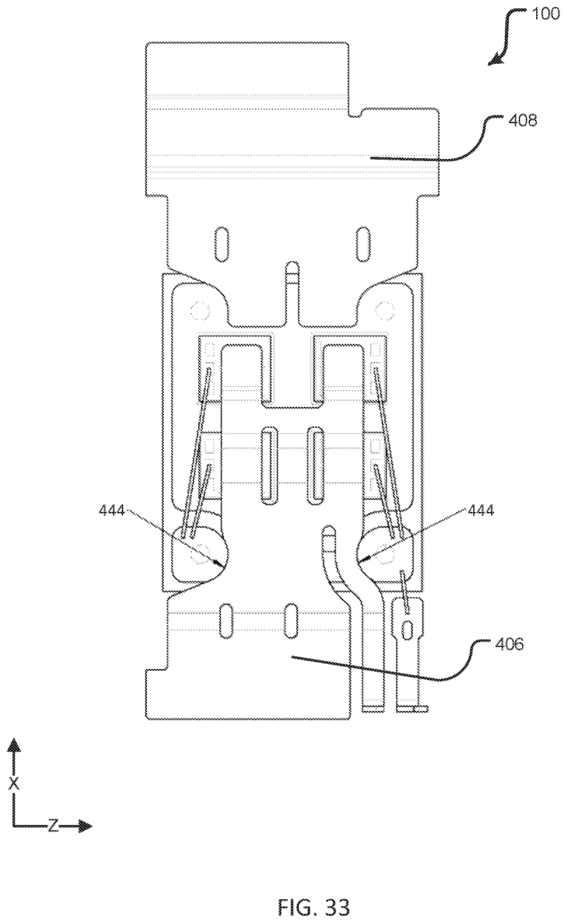

FIG. 32 illustrates aspects of the power package according to aspects of the disclosure.

In particular, FIG. 32 illustrates further aspects of the power package 100. The aspects of the power package 100 illustrated in FIG. 32 may be implemented in any other aspects described herein. Moreover, other aspects described herein may be implemented in the power package 100 of FIG. 32.

In aspects, the power package 100 may be configured to provide mold flow enhancement. In aspects, the power package 100 may implement a mold assembly feature 432 configured to provide mold flow enhancement, hold down access, and/or strengthen leads. In aspects, the mold assembly feature 432 may be configured as one or more holes or slots and may be added to the lead frame or the lead frame power interconnection 400 to improve mold flow. In aspects, the mold assembly feature 432 may be implemented by the lead frame first portion 406 as illustrated in FIG. 32.

In this regard, a removal of material of the lead frame power interconnection 400, such as the lead frame first portion 406 can help equalize pressure and speed of the mold compound as it flows over the surfaces of the components of the power package 100. The mold assembly feature 432 may also be beneficial to create access for the hold down pins as previously described. In aspects, this may be utilized clip attach configurations of the lead frame power interconnection 400 with the hold down pin located in the center of one of the power substrate 300 edges. In this case, the mold assembly feature 432 serves multiple purposes as it also acts to provide strain relief for the lead frame power interconnection 400, such as the lead frame first portion 406.

FIG. 33 illustrates aspects of the power package according to aspects of the disclosure.

In particular, FIG. 33 illustrates further aspects of the power package 100. The aspects of the power package 100 illustrated in FIG. 33 may be implemented in any other aspects described herein. Moreover, other aspects described herein may be implemented in the power package 100 of FIG. 33.

In aspects, the power package 100 may be configured with multiple openings 444 in the source lead frame or the lead frame first portion 406 of the lead frame power interconnection 400. In aspects, the multiple openings 444 may be configured for manufacturing tooling access.

In aspects of the power package 100, for the signal wire bonds and, in some embodiments, power wire bonds, considerations must be taken to accommodate the wire bonding manufacturing process of the power package 100. All bond sites and the power substrate 300 and lead frame or the lead frame power interconnection 400 need room for a clamp to mechanically support the parts of the power package 100 during the bonding formation process. Clearance from the wire bonder equipment itself must be considered, as the bond head comes in close contact and proximity to many surfaces of the power package 100. In some cases, wire bonds can be angled to facilitate this. In other cases, features can be combined such that removed material from the lead frame, such as the lead frame first portion 406 and/or the lead frame second portion 408, for other purposes also acts to introduce clearance distance from the wire bond head. An example of this is shown in FIG. 33 in which the hold down pin clearance can be combined with wire bond head clearance by implementation of the multiple openings 444.

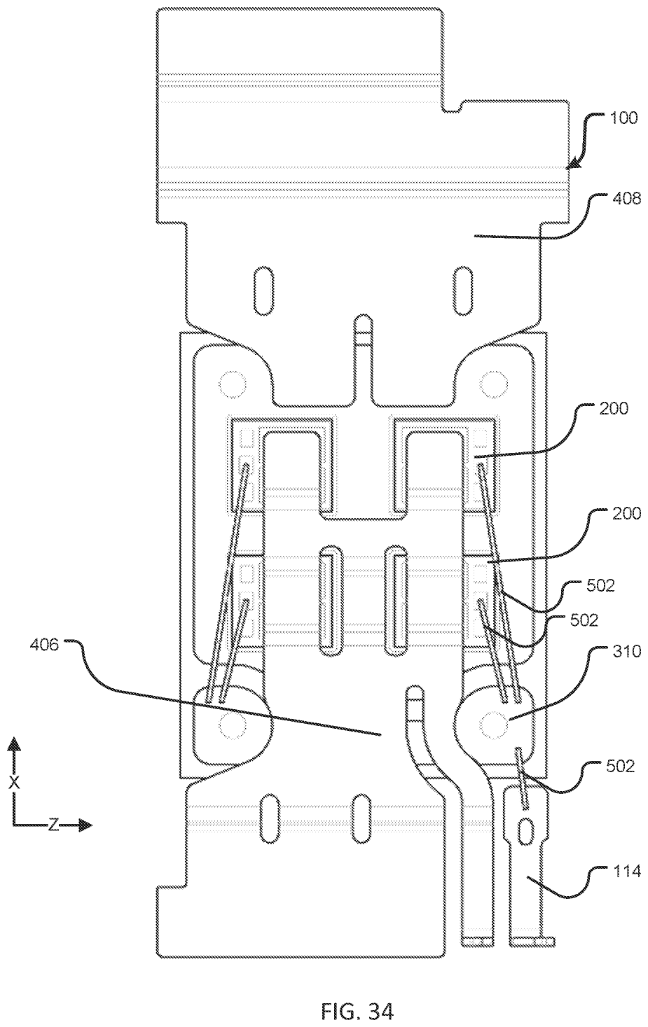

FIG. 34 illustrates aspects of the power package according to aspects of the disclosure.

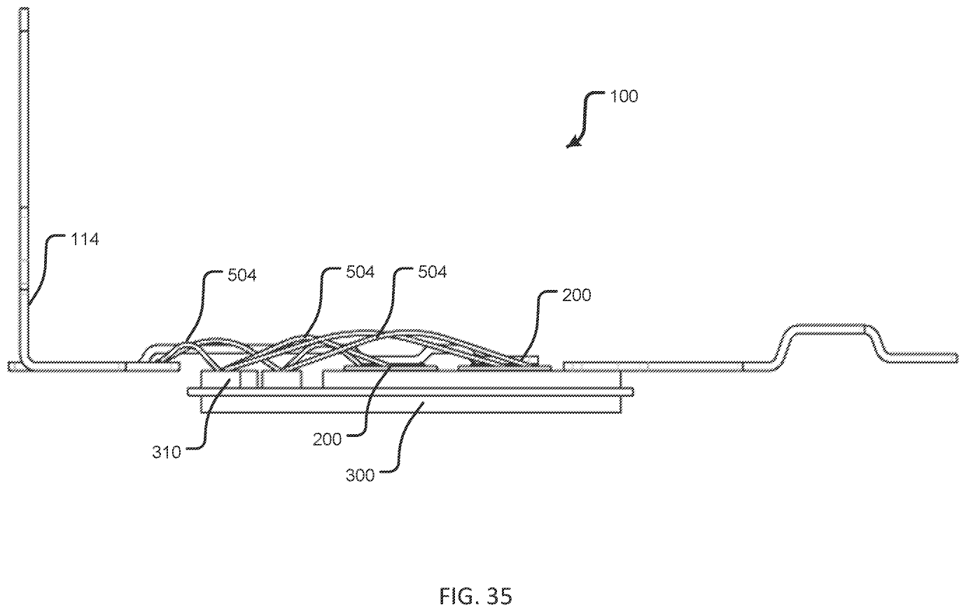

FIG. 35 illustrates aspects of the power package according to aspects of the disclosure.

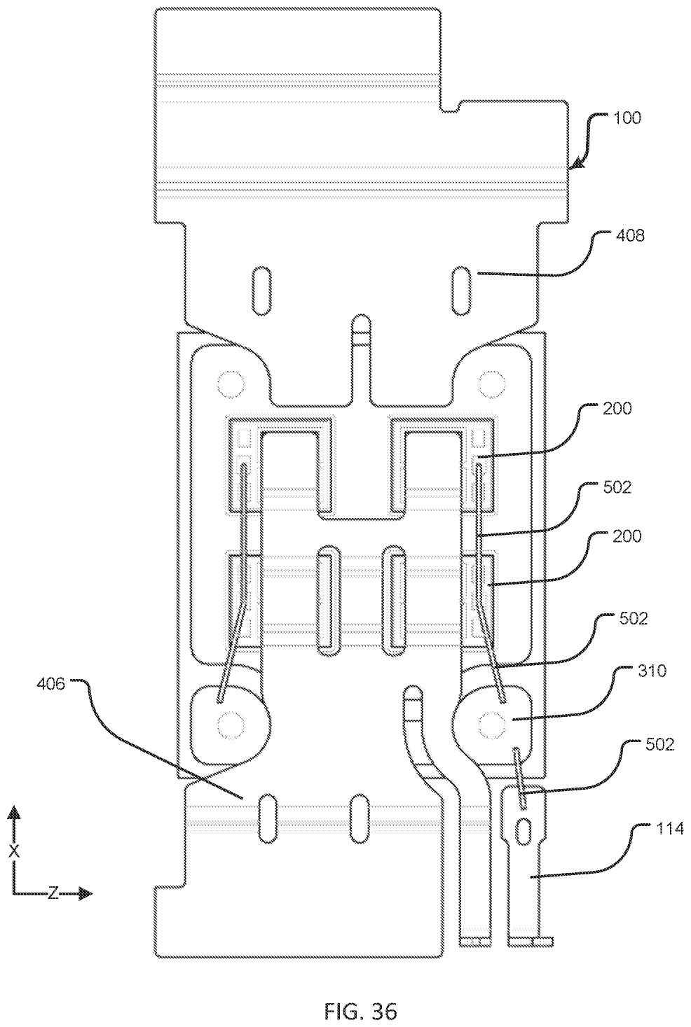

FIG. 36 illustrates aspects of the power package according to aspects of the disclosure.

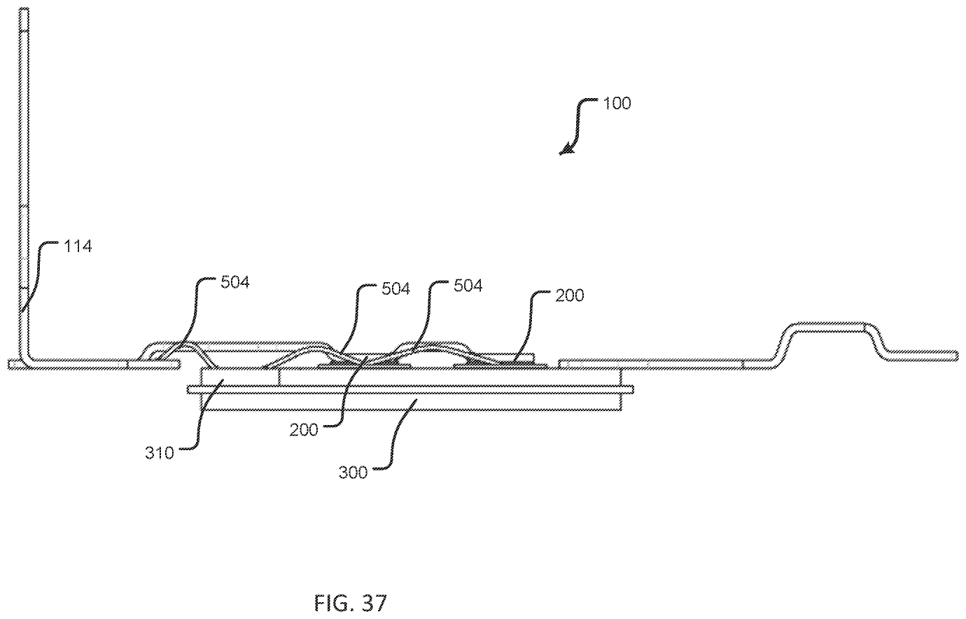

FIG. 37 illustrates aspects of the power package according to aspects of the disclosure.

In particular, FIGS. 34-37 illustrate further aspects of the power package 100. The aspects of the power package 100 illustrated in FIGS. 34-37 may be implemented in any other aspects described herein. Moreover, other aspects described herein may be implemented in the power package 100 of FIGS. 34-37.

In aspects, the power package 100 may be configured with signal bonds. In particular aspects of the power package 100, the signal bonds may be formed for each individual device, giving each an independent loop to the signal terminals and system gate driver. The wire bonds may be relatively longer for the back two implementations of the one or more power devices 200. In some cases, particularly for smaller diameter wires, longer bonds may be susceptible to wire sweep during the transfer molding process. Wire sweep occurs when the flowing mold compound deforms the wire and moves them out of place. Preventing wire sweep can be achieved by using a larger diameter wire or reducing the bond length.

However, larger diameter wire requires larger bond pads. In general, gate bond pads are desired to be small on the one or more power devices 200 to maximize active area. In some embodiments, the signal bonds may be ‘stitched’ or bonded to each gate and/or source pad of the one or more power devices 200 with the same bond at multiple locations. The bond jumps from one gate pad, to the next gate pad, and then to the power substrate 300 or the signal contacts 114. This technique may also help reduce wire crowding for configurations that have source kelvin bonding.

FIGS. 34-37 illustrate these two signal bonding approaches for one layout embodiment of the power package 100. As illustrated in FIGS. 34 and 35, the power package 100 is configured for individual implementations of the bonds 502. In particular, the bonds 502 extend from the signal contacts 114 to the first metal 310; and the bonds 502 extend from the first metal 310 individually to the one or more power devices 200.

As illustrated in FIGS. 36 and 37, the bonds 502 extend from the signal contacts 114 to the first metal 310; the bonds 502 extend from the first metal 310 to a lower implementation of the one or more power devices 200; and the bonds 502 extend from the lower implementation of the one or more power devices 200 to an upper implementation of the one or more power devices 200. The implementation of the bonds 502 in the power package 100 may be referred to as stitched bonds. The disclosed layouts of the power package 100 may use either approach depending on specific product configuration and manufacturing processes.

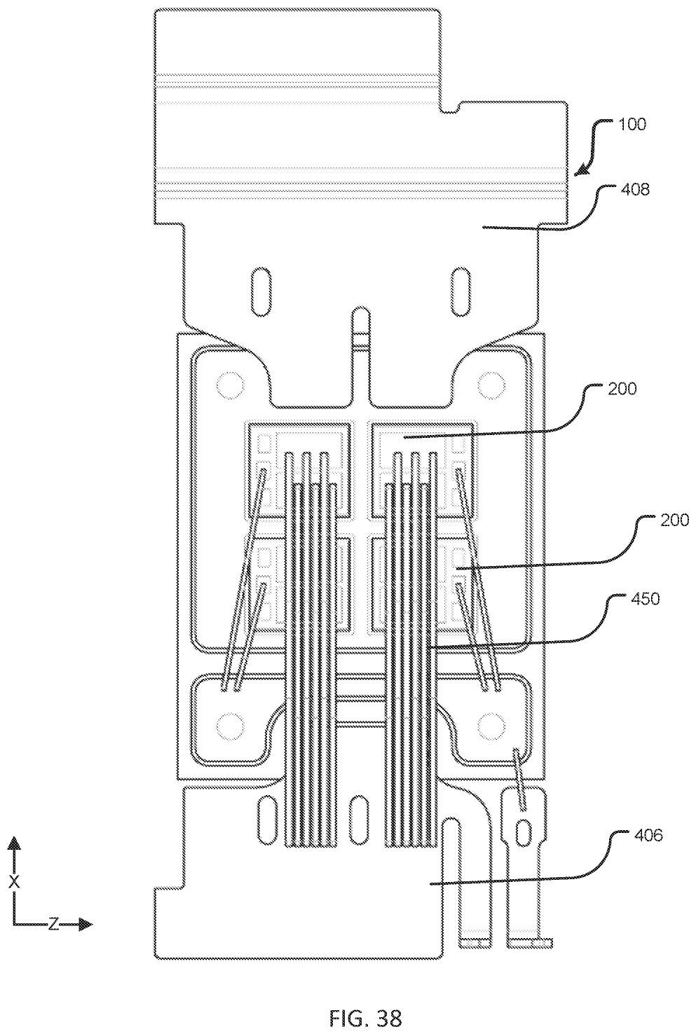

FIG. 38 illustrates aspects of the power package according to aspects of the disclosure.

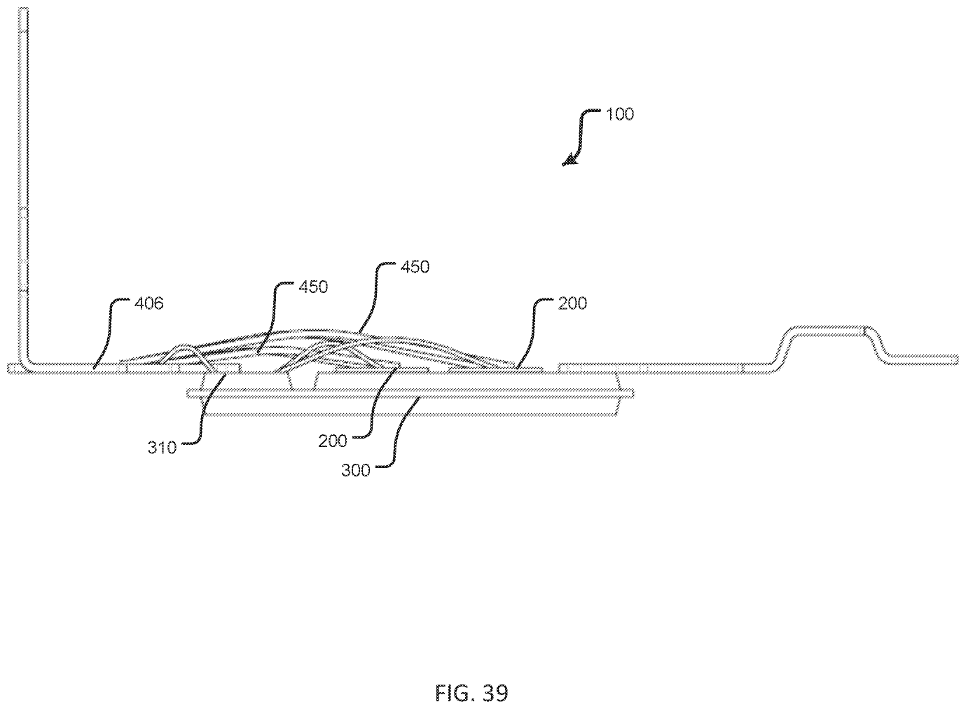

FIG. 39 illustrates aspects of the power package according to aspects of the disclosure.

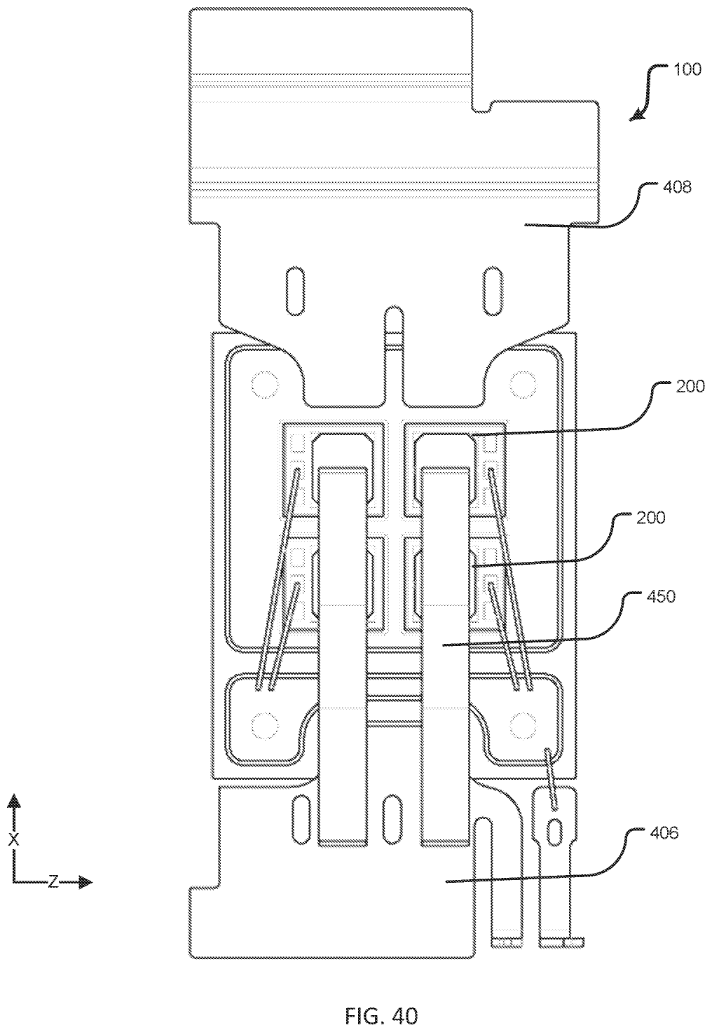

FIG. 40 illustrates aspects of the power package according to aspects of the disclosure.

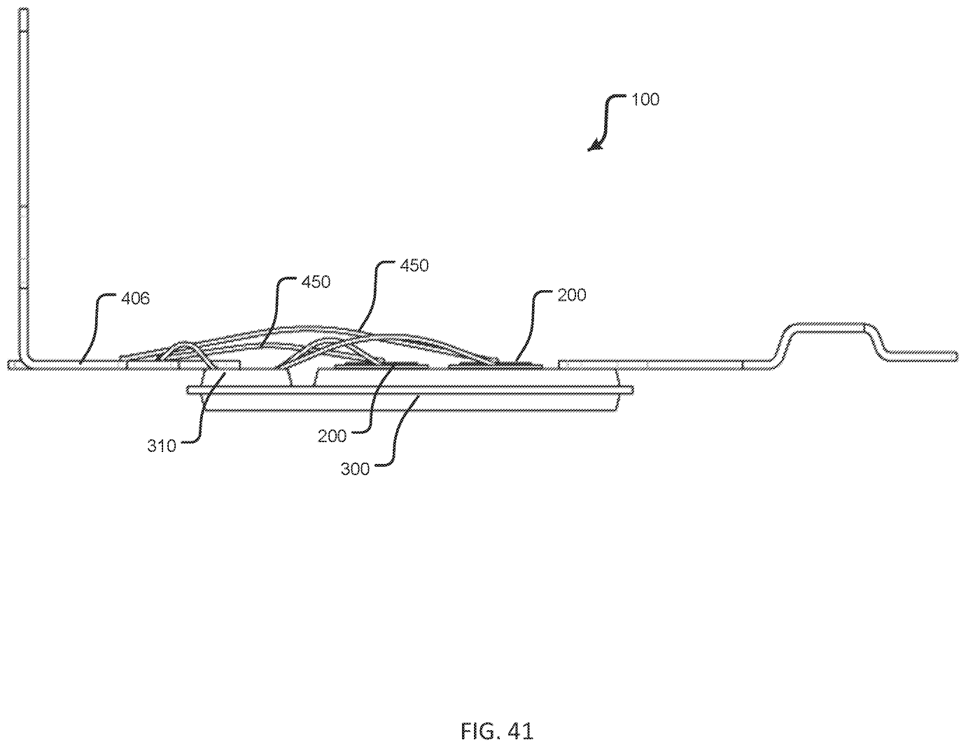

FIG. 41 illustrates aspects of the power package according to aspects of the disclosure.

In particular, FIGS. 38-41 illustrate further aspects of the power package 100. The aspects of the power package 100 illustrated in FIGS. 38-41 may be implemented in any other aspects described herein. Moreover, other aspects described herein may be implemented in the power package 100 of FIGS. 38-41.

In aspects, the power package 100 may be configured with power connections 450 as illustrated in FIGS. 38 and 39. In this regard, the power connections 450 illustrated in FIGS. 38 and 39 are wire bonds. In aspects of the power package 100, configurations that use large diameter power bonds for the device topside interconnection of the power loop may use a variety of bond patterns depending on the pad layout of the one or more power devices 200 and the ampacity needs of the product specification of the power package 100. In this regard, as disclosed herein, large diameter power bonds may comprise a diameter of 0.20 mm to 0.80 mm, a diameter greater than 0.20 mm, a diameter greater than 0.40 mm, or a diameter greater than 0.60 mm. The power connections 450 may be paralleled, stitched, stacked, interleaved, and/or fanned out to increase the effective cross sectional area of the high current loop.

Alternatively, as illustrated in FIGS. 40 and 41 the power connections 450 may be implemented as ribbon bonds in implementations of the power package 100 that require optimal ampacity while retaining the flexibility of a bonded approach. Ribbon bonds increase the cross sectional area of the interconnect and use more of the bondable area of the one or more power devices 200.

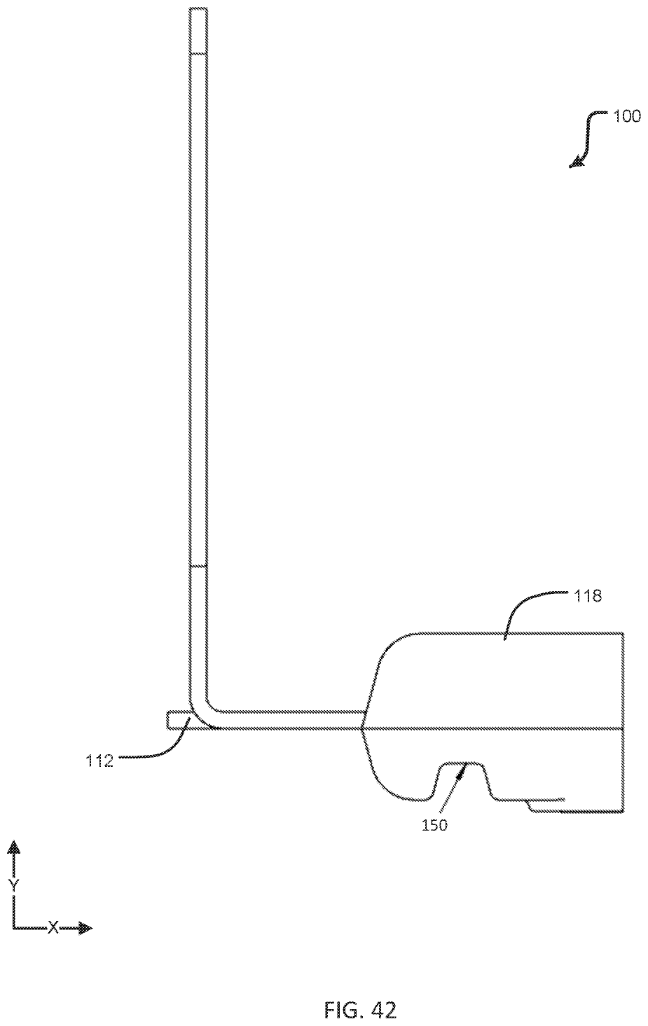

FIG. 42 illustrates aspects of the power package according to aspects of the disclosure.

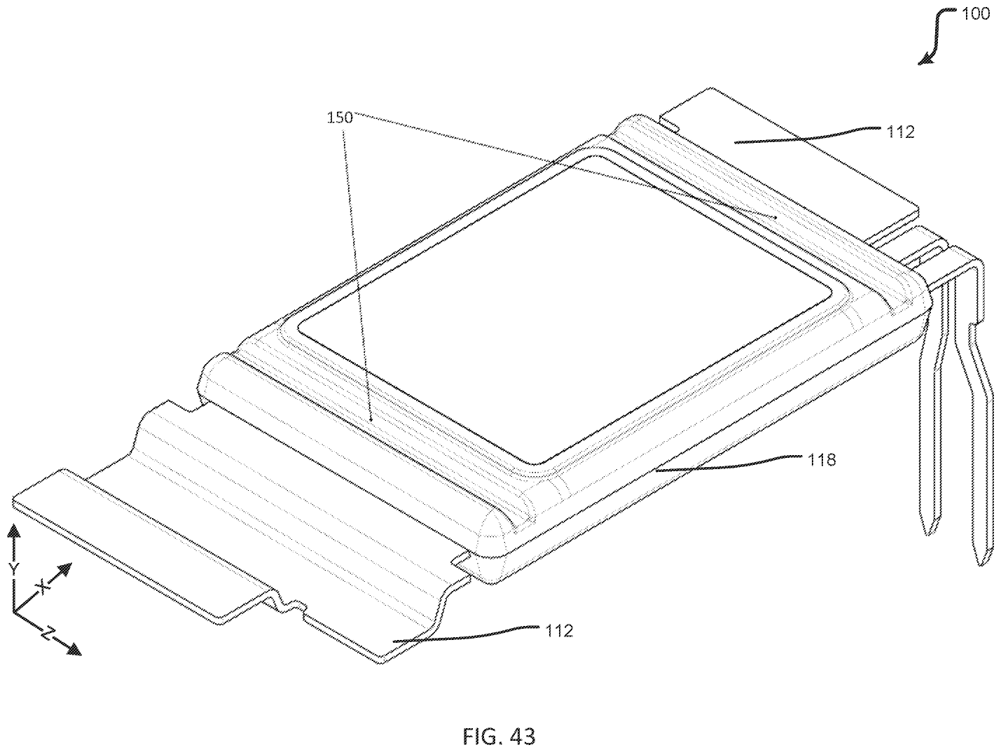

FIG. 43 illustrates aspects of the power package according to aspects of the disclosure.

In particular, FIGS. 42 and 43 illustrate further aspects of the power package 100. The aspects of the power package 100 illustrated in FIGS. 42 and 43 may be implemented in any other aspects described herein. Moreover, other aspects described herein may be implemented in the power package 100 of FIGS. 42 and 43.

In particular, the power package 100 may be configured with creepage extenders 150. In some aspects of the power package 100, clearance and creepage may be an issue for a high voltage product. Between conductors at different voltage potentials, clearance is the shortest direct path in air between them. Creepage is the shortest direct path along a surface between them. Meeting safety standards is a challenge and is often at odds with a manufacturing method (tooling, epoxy flow, etc.) and product size (footprint and power density). For small transfer molded packages, particularly low profile and high voltage SiC based products, reaching a suitable balance is difficult.

To increase the creepage distance of the external product specification to accommodate higher voltages, the creepage extenders 150 may be implemented in the power package 100. In aspects, the creepage extenders 150 may be configured as grooves, ripples, or other surface enhancements that extend the surface distance between conductors at different potentials. In aspects, the creepage extenders 150 may be included as part of the plastic or epoxy housing of the power package 100, providing extra functionality without adding cost. As illustrated in FIGS. 42 and 43, the creepage extenders 150 may be configured as trenches acting as creepage distance extension on the power package 100 and/or the molded assembly 118. In aspects, the creepage extenders 150 may be arranged on either end of the power package 100 and/or the molded assembly 118. In aspects, the creepage extenders 150 may be arranged on both ends of the power package 100 and/or the molded assembly 118. In aspects, the creepage extenders 150 may be arranged on either end of the power package 100 and/or the molded assembly 118 adjacent the power contacts 112. In aspects, the creepage extenders 150 may be arranged on both ends of the power package 100 and/or the molded assembly 118 adjacent the power contacts 112.

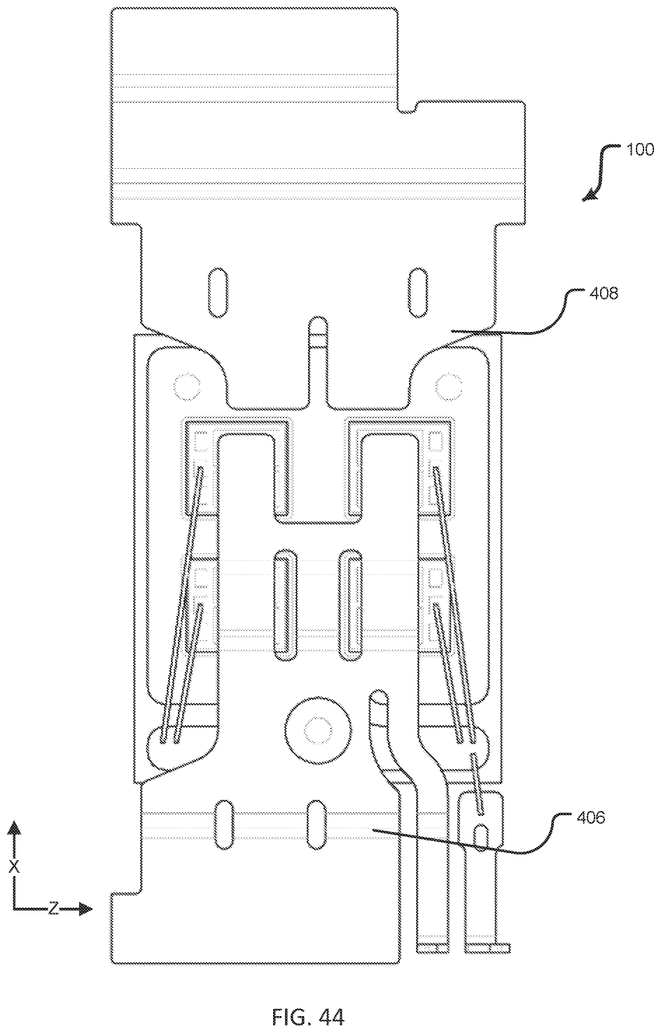

FIG. 44 illustrates aspects of the power package according to aspects of the disclosure.

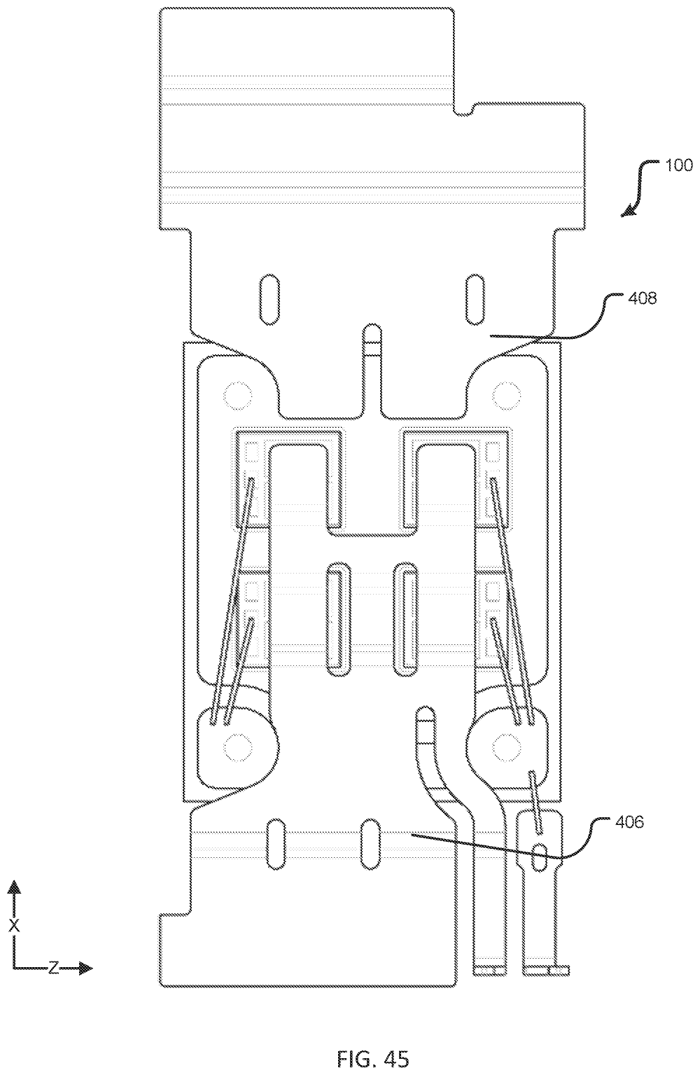

FIG. 45 illustrates aspects of the power package according to aspects of the disclosure.

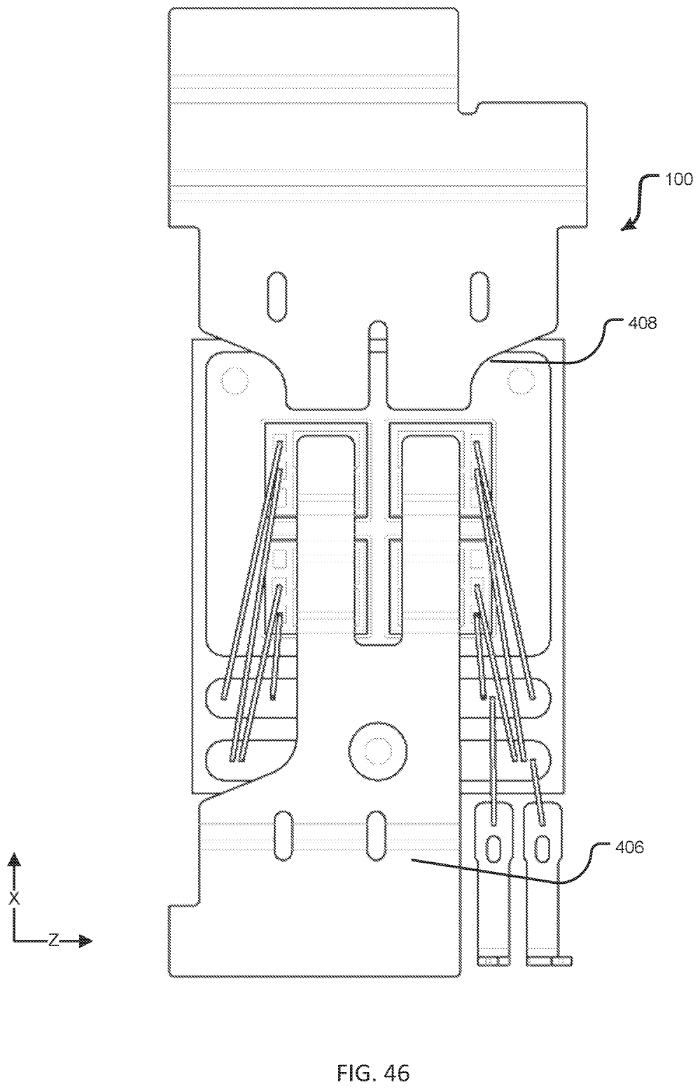

FIG. 46 illustrates aspects of the power package according to aspects of the disclosure.

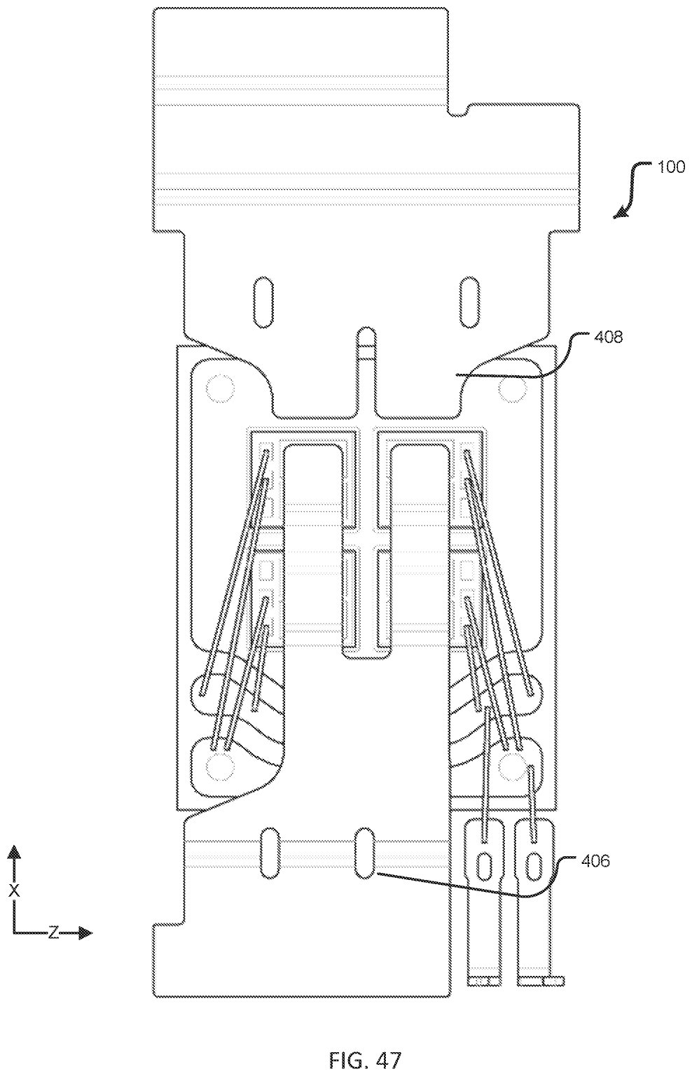

FIG. 47 illustrates aspects of the power package according to aspects of the disclosure.

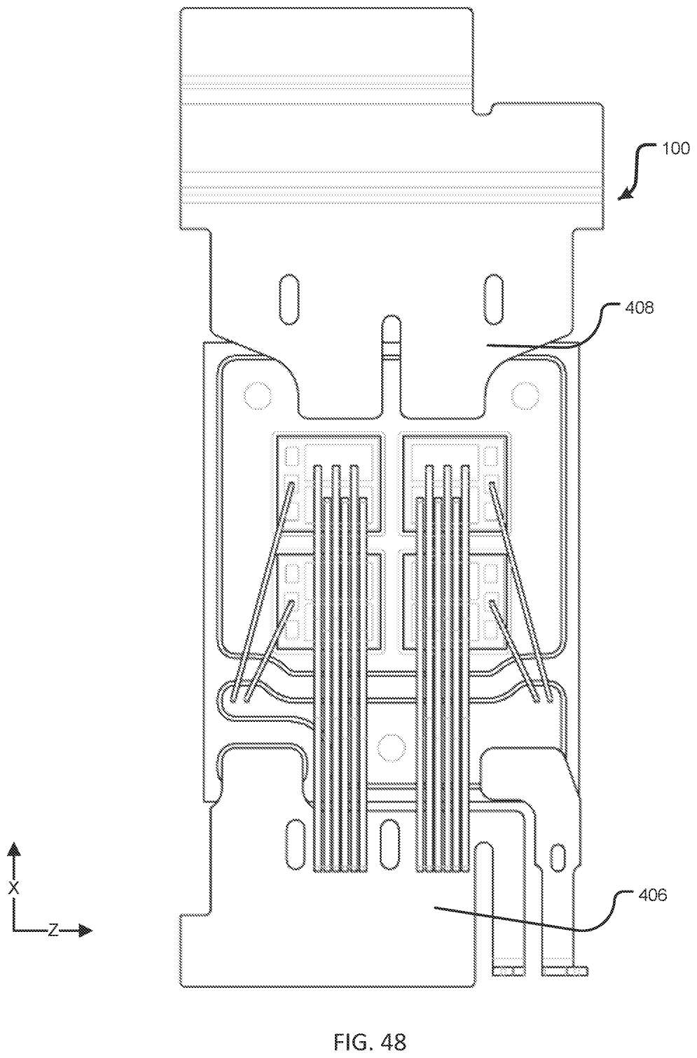

FIG. 48 illustrates aspects of the power package according to aspects of the disclosure.

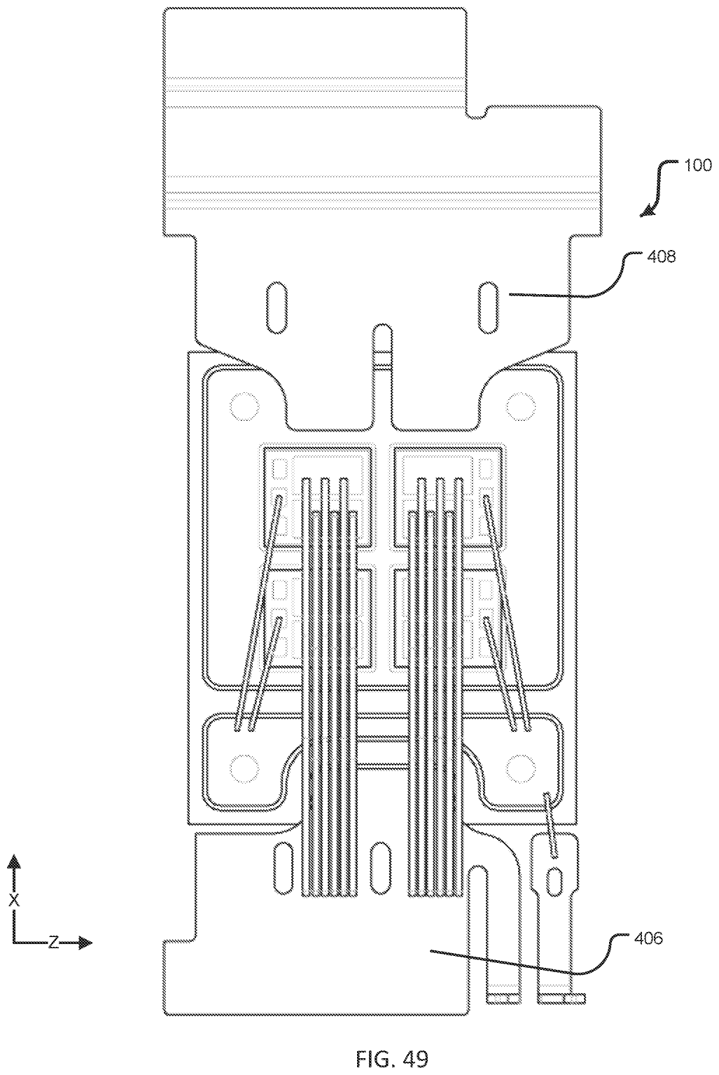

FIG. 49 illustrates aspects of the power package according to aspects of the disclosure.

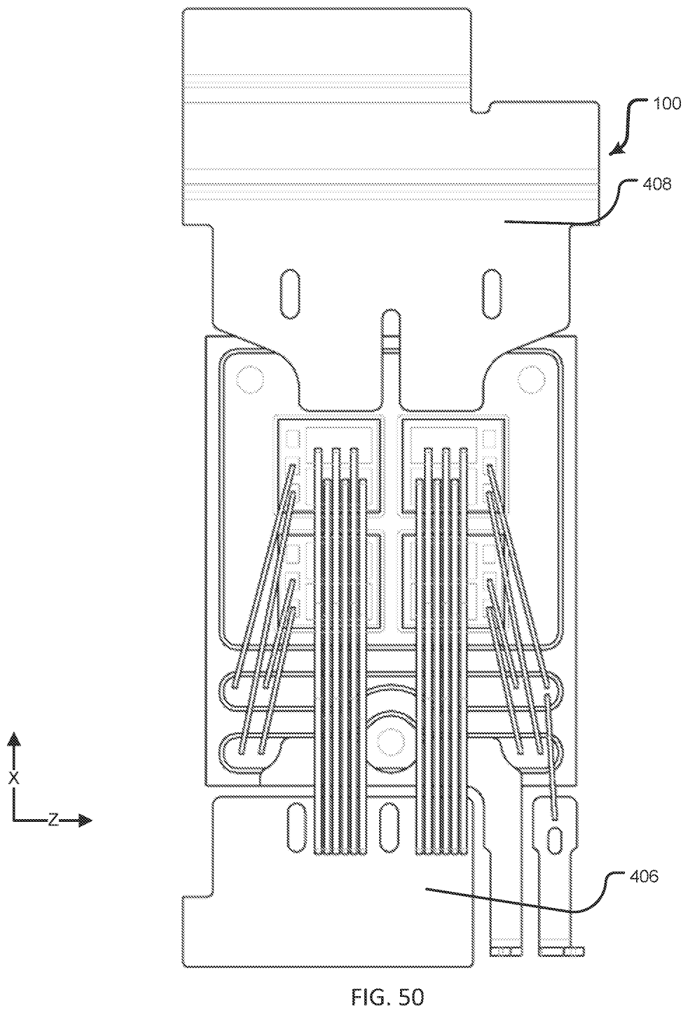

FIG. 50 illustrates aspects of the power package according to aspects of the disclosure.

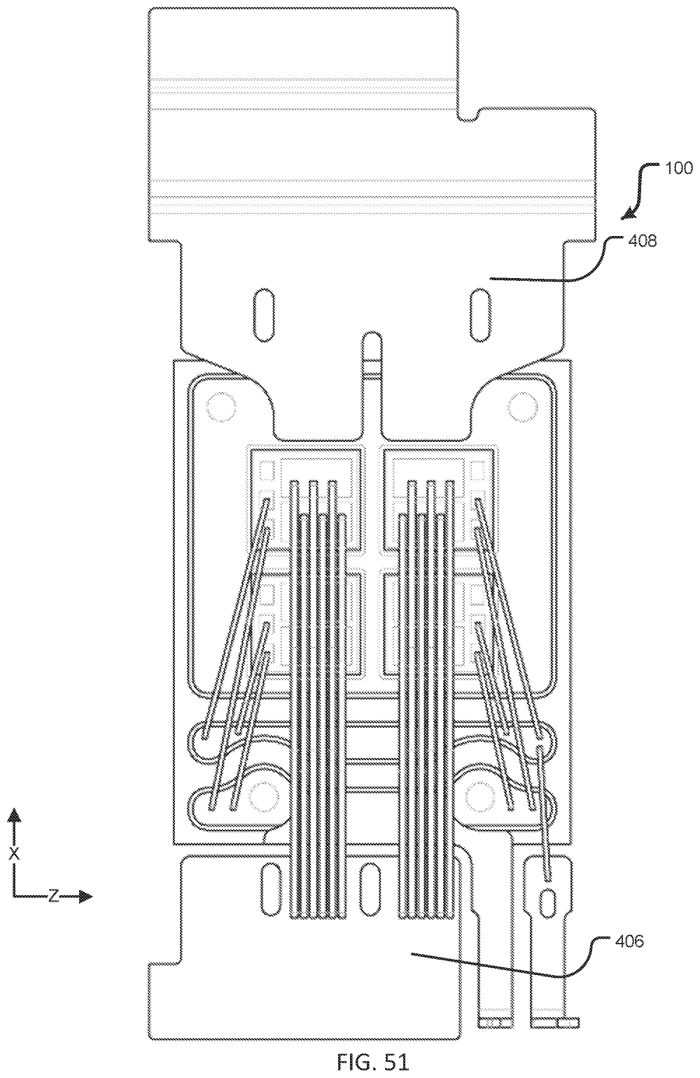

FIG. 51 illustrates aspects of the power package according to aspects of the disclosure.

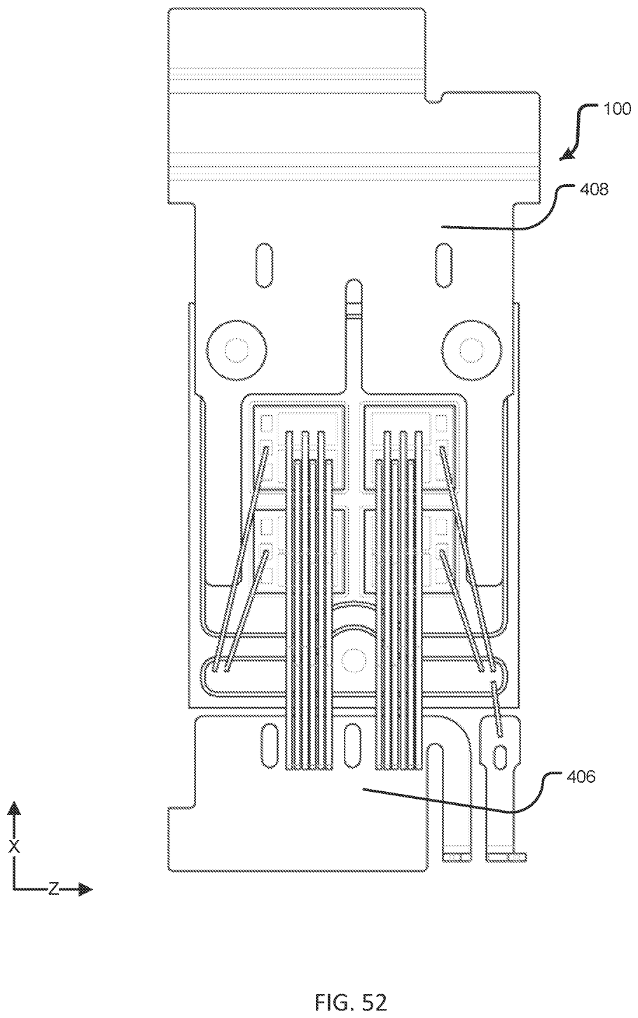

FIG. 52 illustrates aspects of the power package according to aspects of the disclosure.

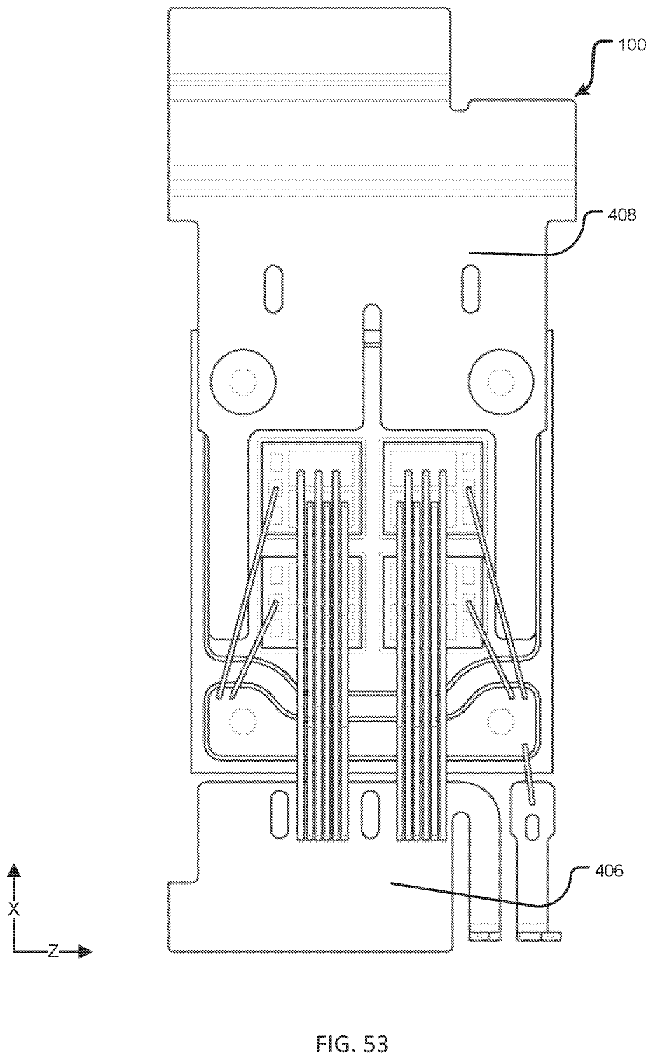

FIG. 53 illustrates aspects of the power package according to aspects of the disclosure.

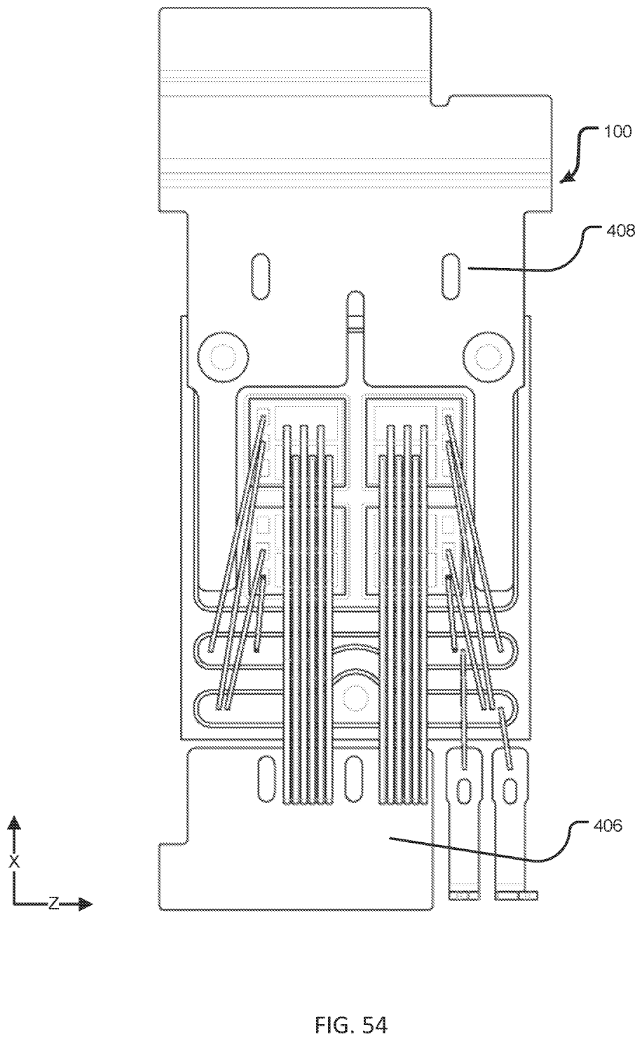

FIG. 54 illustrates aspects of the power package according to aspects of the disclosure.

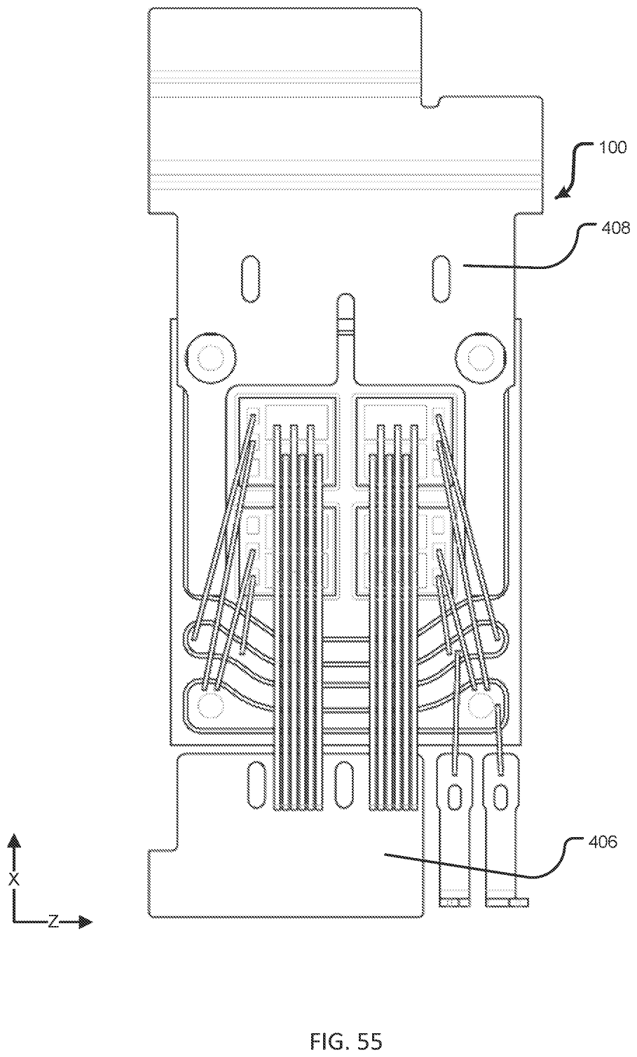

FIG. 55 illustrates aspects of the power package according to aspects of the disclosure.

In particular, FIGS. 44-55 illustrate further aspects of the power package 100. The aspects of the power package 100 illustrated in FIGS. 44-55 may be implemented in any other aspects described herein. Moreover, other aspects described herein may be implemented in the power package 100 of FIGS. 44-55.

In aspects, the power package 100 may be implemented with different configurations. In aspects of the power package 100, there may be multiple viable options for configuring the internal layout based on four driving factors. These options are identified and described below.

Power Interconnection—High current path from device topside to source terminal forming part of the power loop. Depending on attach method, the one or more power devices 200 may have a variety of topside metal stacks and enhancements. These include metals which are aluminum wire bondable, copper wire bondable, and solderable. In some cases, a thick layer of copper is added to the topside of the one or more power devices 200 to enhance bondability and buffer the current distribution. This topside copper or similar highly conductive metal may be plated on the device or formed as a separate sheet which is then attached to the topside of the device through soldering, sintering, or welding.

In aspects illustrated in FIGS. 44-48, the lead frame first portion 406 of the lead frame power interconnection 400 may be configured as a clip. The clip may be a formed metal contact connecting the topside of the one or more power devices 200 to the lead frame first portion 406. This may either be part of the lead frame structure itself or formed as a separate element that is then attached to the lead frame structure.

In aspects of the power package 100 illustrated in FIGS. 48-55, the lead frame first portion 406 may be implemented with a wire/ribbon. In this regard, the wire/ribbon may be implemented as multiple bonded metal elements connecting the topside of the one or more power devices 200 to the lead frame first portion 406. These are most commonly aluminum, copper, or a copper core with an aluminum shell. The metal elements may either be large diameter wire with a circular cross section or a rectangular ribbon.

In aspects of the power package 100, implementation of a source Kelvin may be implemented such that a signal path from device gate pad and source pad of the one or more power devices 200 to the power substrate 300 and the signal contacts 114. The need for a true source kelvin depends on the specific requirements of a system. With a set footprint, adding an independent path for the signal connections is possible but has tradeoffs due to the space those features take up on the layout. Adding a signal trace and accommodations for signal wire bond clearances moves the one or more power devices 200 closer together, increasing heat path overlap, and makes the drain trace smaller, reducing the heat spreading area. Both of these factors reduce overall thermal performance of the power package 100 but deliver maximum switching efficiency and quality.

In aspects illustrated FIGS. 44, 45, 48, 49, 52, and 53 the power package 100 may implement a Pseudo source kelvin connection with some overlap of power and signal loops, with the signal pin joined to the lead frame first portion 406 close to the one or more power devices 200 of the signal and power paths sharing the same conductive element.

In aspects illustrated FIGS. 46, 47, 50, 51, 54, and 55 the power package 100 may implement a true source kelvin connection implementing Wire/Ribbon connection with No overlap of power and signal loops, with dedicated wire bonds and substrate traces separating the signal and power paths.

In aspects of the power package 100, clamping regions on the power substrate 300 during transfer molding may be utilized to limit mold compound flash. The location and pattern of the pins are driven by the need to minimize mold flash, not interfere with other functional elements such as the wire bonds, and to accommodate process clearance tolerances.

As illustrated in FIGS. 45, 46, 48, 50, 52, and 54, aspects of the power package 100 are shown illustrating locations for Four—Hold down pins to press down all four corners of the power substrate 300. This delivers the best pressure distribution and symmetry but complicates the signal wire bonding due to the external terminal locations.

As illustrated in FIGS. 44, 47, 49, 51, and 53, aspects of the power package 100 are shown illustrating locations for Three—Hold down pins to press down on two corners and one edge of the power substrate 300. This arrangement works best with the external terminal locations but adds substrate ceramic damage risks due to the uneven pressure distribution.

In aspects of the power package 100, a physical linkage may be implemented between the lead frame and the power substrate assembly during manufacturing. This regard, during product manufacturing, at some stage the lead frame and power substrate assembly, such as the power substrate 300 and the one or more power devices 200, may be joined together to form the electrical and mechanical connections. This assembly is then transported to various processes before the power package 100 is completed. The power substrate 300 must have a solid and evenly distributed linkage to the lead frame such that it does not sag and deform the lead frame under its own weight.

In aspects of the power package 100 illustrated in FIGS. 44, 45, 46, and 47, the lead frame second portion 408 may be bonded to the power substrate 300, and the lead frame first portion 406 may be bonded to the topside of the one or more power devices 200 through a copper clip. This holds the assembly from both sides.

In aspects of the power package 100 illustrated in FIGS. 48 and 49, the lead frame second portion 408 may be bonded to the power substrate 300, and the lead frame first portion 406 may be bonded to the power substrate 300. This could be any or all of the source side contacts (power source, source kelvin, and gate). This holds the assembly from both sides.

In aspects of the power package 100 illustrated in FIGS. 52, 53, 54, and 55, the lead frame second portion 408 may be bonded to the power substrate 300 at the edge, and then extends around the one or more power devices 200 on the drain trace to hold the power substrate 300 assembly from the middle. This holds the assembly from one side with a large area for mechanical support.

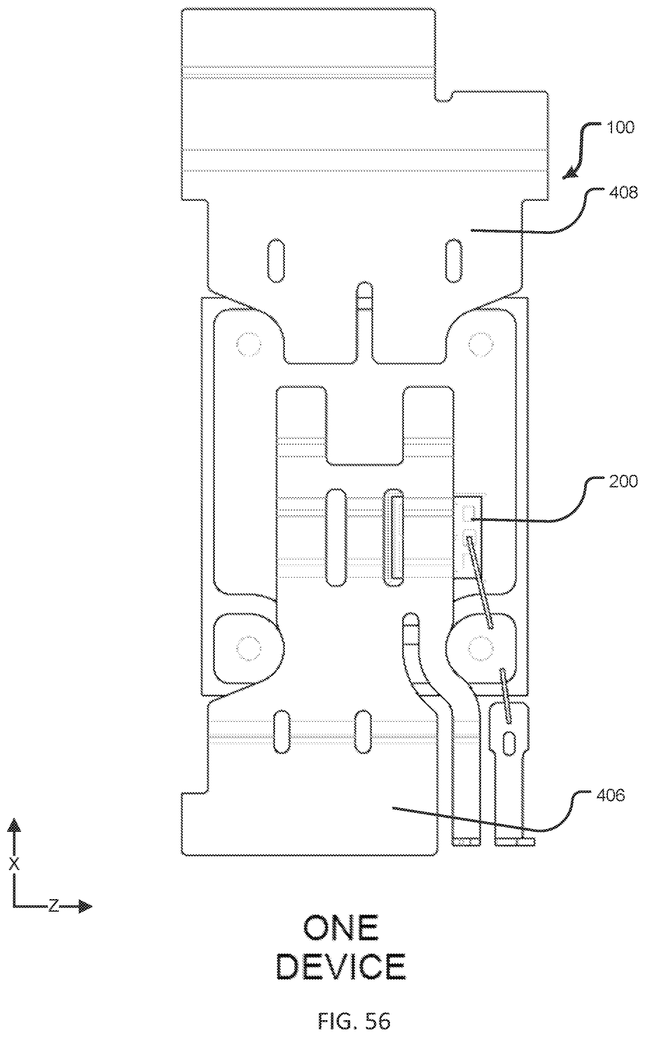

FIG. 56 illustrates aspects of the power package according to aspects of the disclosure.

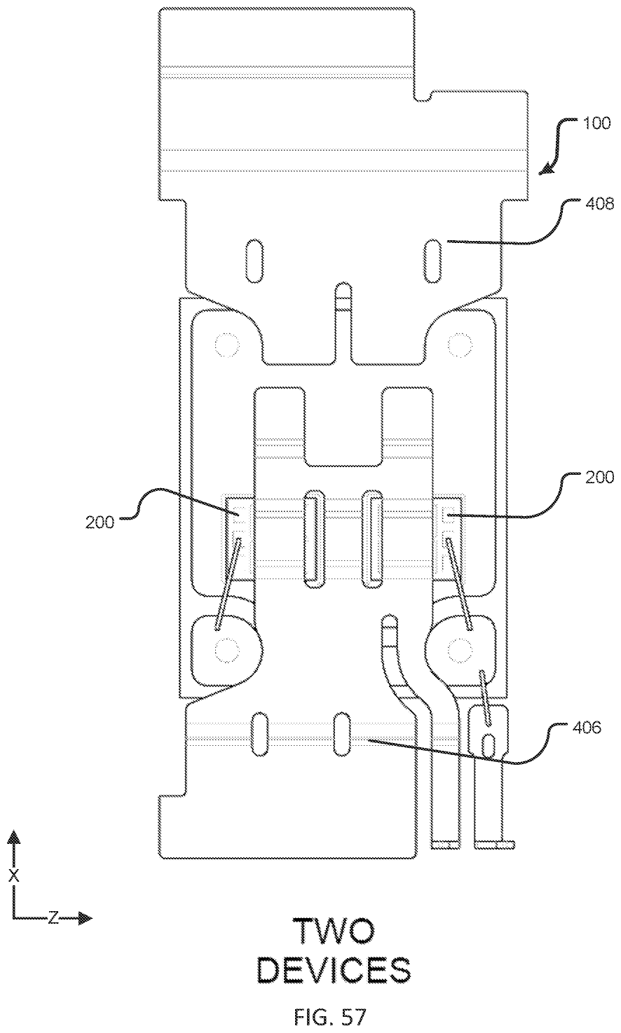

FIG. 57 illustrates aspects of the power package according to aspects of the disclosure.

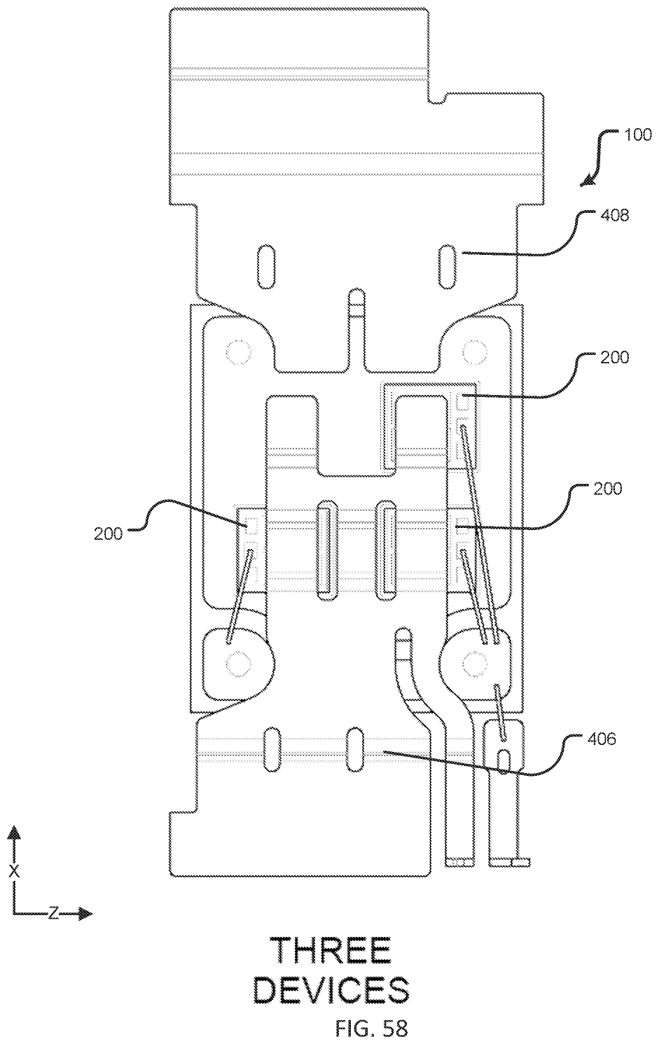

FIG. 58 illustrates aspects of the power package according to aspects of the disclosure.

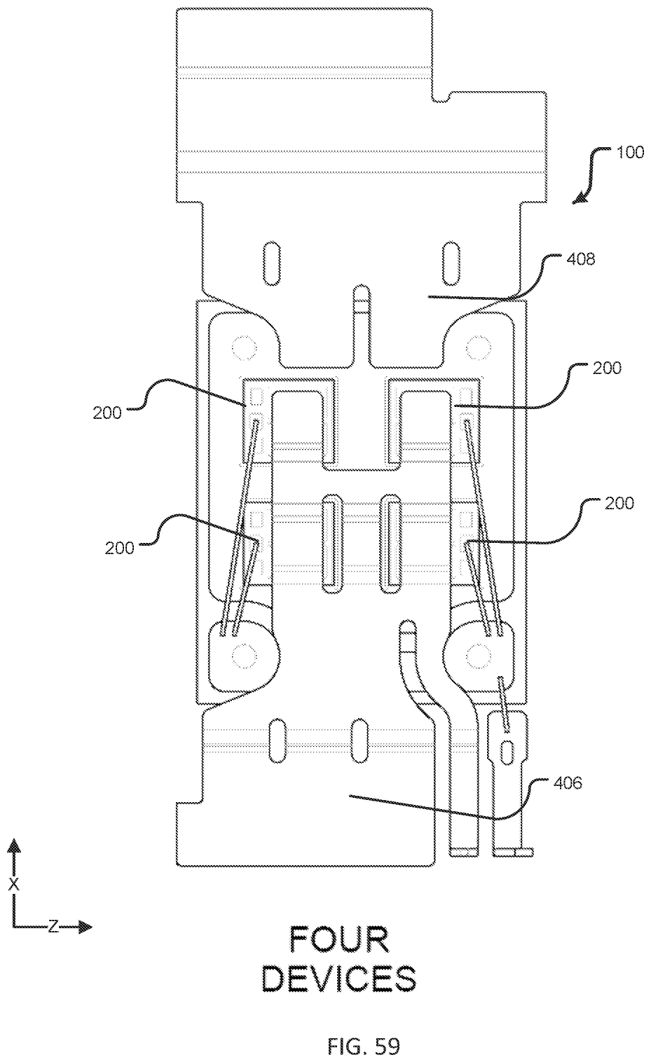

FIG. 59 illustrates aspects of the power package according to aspects of the disclosure.

In particular, FIGS. 56-59 illustrate further aspects of the power package 100. The aspects of the power package 100 illustrated in FIGS. 56-59 may be implemented in any other aspects described herein. Moreover, other aspects described herein may be implemented in the power package 100 of FIGS. 56-59.

In aspects of the power package 100, usage of the different configurations will depend on the specific product and system needs and manufacturing line processes. Note that many ancillary features, such as source return jumper bonds, stitched gate bonds, various strain relief features as described previously may be implemented on any of these layout configurations. Note that while wires are shown, the ribbons may also be used.

Similar to the flexibility in layouts, the modularity of the switch positions allows for many product derivatives to meet many application categories and cost targets. Modularity can be explored in multiple ways. With four potential device positions, the option to fully or partially populate the structure with the one or more power devices 200 is straightforward and effective.

FIGS. 56-59 illustrate exemplary implementations of the power package 100 where one, two, three, or four implementations of the one or more power devices 200 can be populated within the same structure of the power package 100. Unfilled sites may just have the region left by the blank device filled with extra molding compound. While shown for one layout variation, all of the described layout variations would be compatible with this approach for other aspects of the power package 100 as described herein. FIG. 56 illustrates the power package 100 implementing a single implementation of the one or more power devices 200; FIG. 57 illustrates the power package 100 implementing two implementations of the one or more power devices 200;

FIG. 58 illustrates the power package 100 implementing three implementations of the one or more power devices 200; and FIG. 59 illustrates the power package 100 implementing four implementations of the one or more power devices 200.

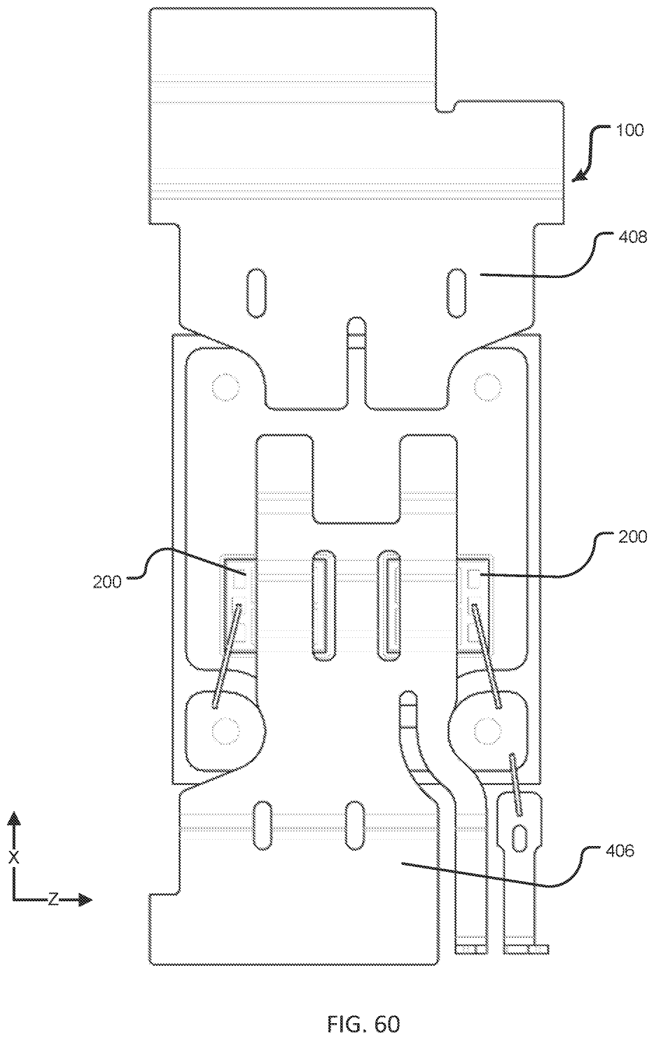

FIG. 60 illustrates aspects of the power package according to aspects of the disclosure.

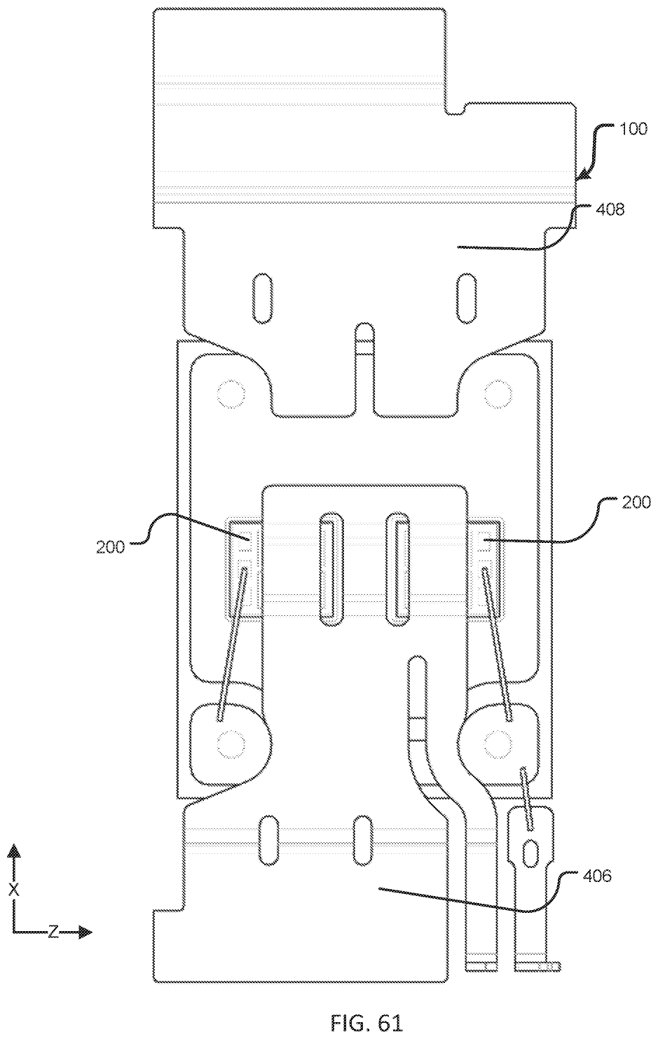

FIG. 61 illustrates aspects of the power package according to aspects of the disclosure.

In particular, FIGS. 60 and 61 illustrate further aspects of the power package 100. The aspects of the power package 100 illustrated in FIGS. 60 and 61 may be implemented in any other aspects described herein. Moreover, other aspects described herein may be implemented in the power package 100 of FIGS. 60 and 61.

In aspects of the power package 100, some partially populated configurations, the one or more power devices 200 may be moved to the center of the footprint to maximize thermal performance. While straightforward for wire and ribbon bonds, for clip attaches the tradeoff is found in using the existing components for a modular approach or sourcing a custom lead frame or clip for a custom approach.

In this regard, FIG. 60 illustrates an implementation of the power package 100 implementing the lead frame first portion 406 utilized in other aspects of the power package 100 as described herein. On the other hand, FIG. 61 illustrates an implementation of the power package 100 implementing a modified and/or customized implementation of the lead frame first portion 406. In particular, the modified and/or customized implementation of the lead frame first portion 406 terminates slightly past the arrangement of the one or more power devices 200.

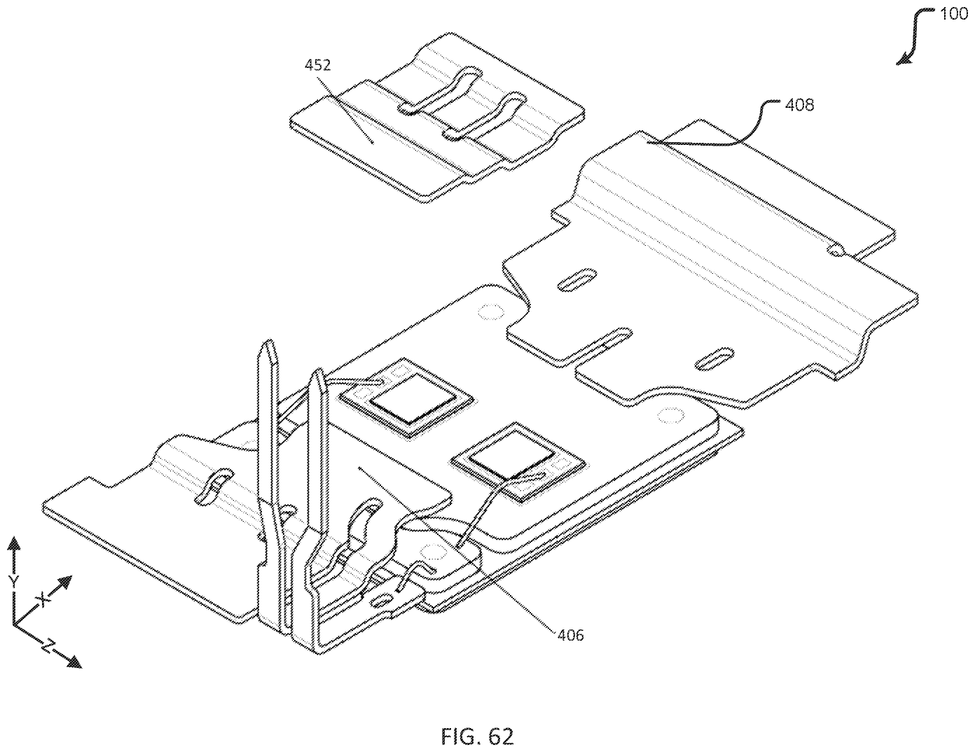

FIG. 62 illustrates aspects of the power package according to aspects of the disclosure.

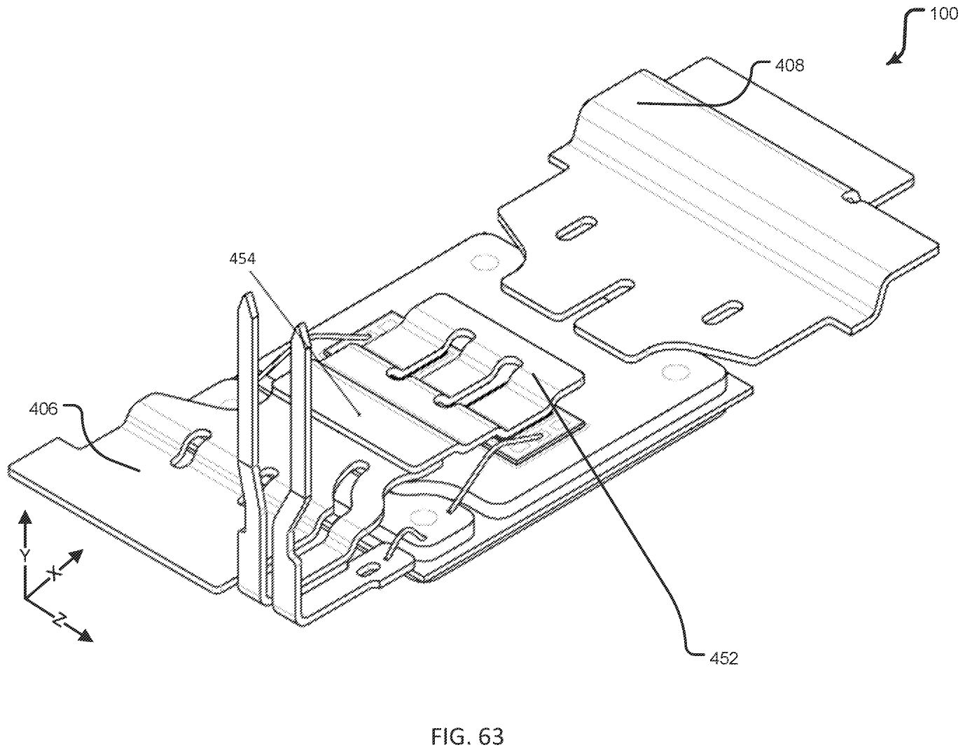

FIG. 63 illustrates aspects of the power package according to aspects of the disclosure.

In particular, FIGS. 62 and 63 illustrate further aspects of the power package 100. The aspects of the power package 100 illustrated in FIGS. 62 and 63 may be implemented in any other aspects described herein. Moreover, other aspects described herein may be implemented in the power package 100 of FIGS. 62 and 63.

In aspects of the power package 100, as an alternative to a custom clip implementation of the lead frame first portion 406, a modular clip 452 may be implemented. Here, the lead frame first portion 406 may be used with the modular clip 452 being a separate element that is directly attached to the lead frame first portion 406 to form a composite and semi-modular structure, as shown in FIG. 62. The attach between the modular clip 452 and the lead frame first portion 406 could be performed as its own process or during the same process as when the modular clip 452 is attached to the one or more power devices 200. As illustrated in FIG. 63, the connection between the modular clip 452 and the lead frame first portion 406 may be implemented by an attach region 454.

This brings considerable flexibility for optimal solutions at the tradeoff of adding interfaces. It may find the most use for research and development activities and smaller lot runs of custom configurations or early customer samples of the power package 100.

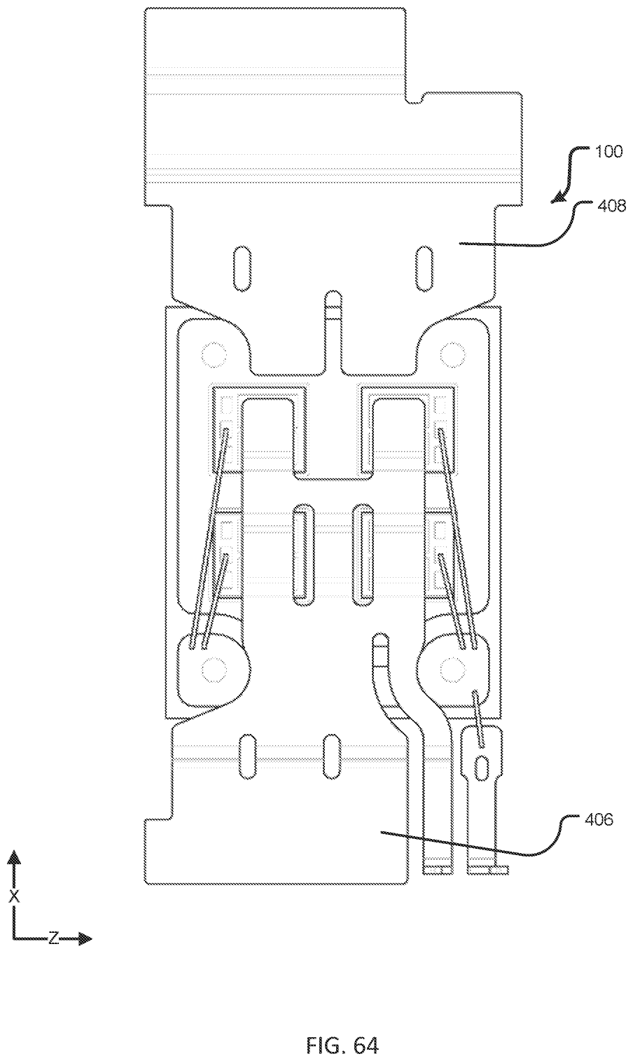

FIG. 64 illustrates aspects of the power package according to aspects of the disclosure.

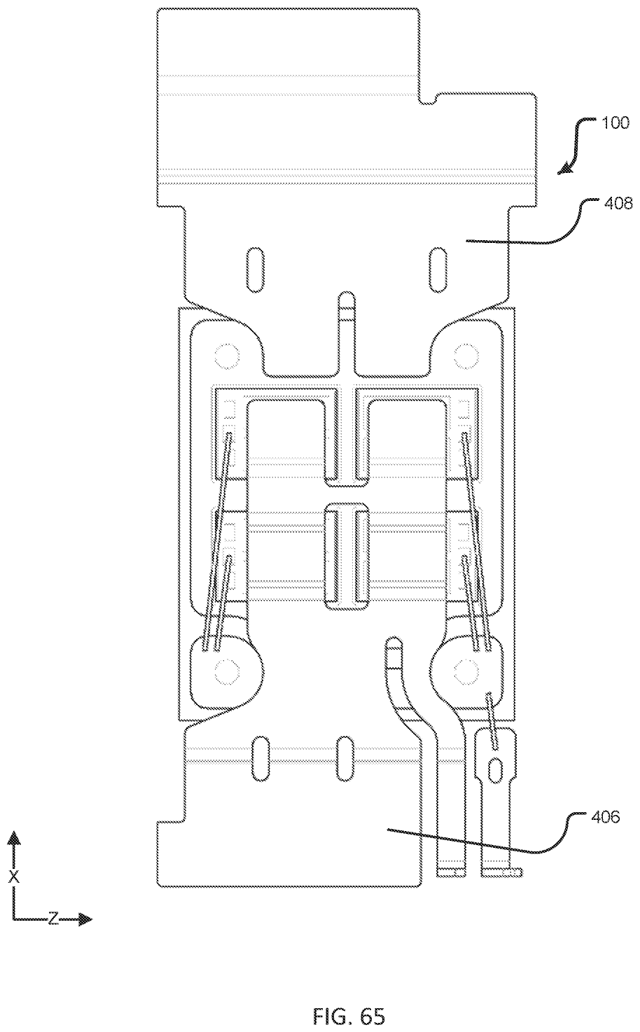

FIG. 65 illustrates aspects of the power package according to aspects of the disclosure.

In particular, FIGS. 64 and 65 illustrate further aspects of the power package 100. The aspects of the power package 100 illustrated in FIGS. 64 and 65 may be implemented in any other aspects described herein. Moreover, other aspects described herein may be implemented in the power package 100 of FIGS. 64 and 65.

In aspects of the power package 100, scalability may be found through the implementation of larger size or smaller size configurations of the one or more power devices 200. In these aspects, the power package 100 may be configured to maximize utilization of the footprint for the lowest conduction losses possible, or to use an existing device or product line without needing to make fundamental design changes. The other modularity aspects, including partial or full position population, apply for devices of any size. In particular, FIG. 64 illustrates implementations of the one or more power devices 200 having a smaller device size; and FIG. 65 illustrates implementations of the one or more power devices 200 having larger device size.

FIG. 66 illustrates aspects of the power package according to aspects of the disclosure.

In particular, FIG. 66 illustrates further aspects of the power package 100. The aspects of the power package 100 illustrated in FIG. 66 may be implemented in any other aspects described herein. Moreover, other aspects described herein may be implemented in the power package 100 of FIG. 66.

In aspects of the power package 100, for applications that have high switching frequencies, switching loss may be a significant portion over the overall power loss. In these cases, an antiparallel diode 260 may be included in the switch position to provide a more efficient path for dynamic current to travel through. The modular switch positions can readily incorporate most power device types such that one or more implementations of the antiparallel diode 260 can be swapped out for the switches, such as the one or more power devices 200, as shown in FIG. 66. This modularity would be shared with any of the previously described layout configurations.

Accordingly, the disclosure has set forth a number of power electronics packages implementing layouts, structures, and/or configurations that can operate commensurate with the high level performance of the power devices implemented by the power electronics packages.

The following are a number of nonlimiting EXAMPLES of aspects of the disclosure.

One EXAMPLE includes: a power package that includes a power substrate. The power package in addition includes one or more power devices arranged on the power substrate. The power package moreover includes a lead frame power interconnection having a lead frame first portion and a lead frame second portion. The power package also includes a connector configured to reduce transconductance mismatches between paralleled implementations of the one or more power devices.

The above-noted EXAMPLE may further include any one or a combination of more than one of the following EXAMPLES: The power package of the above-noted EXAMPLE where the connector is configured as a centralized connecting bar in the lead frame first portion. The power package of the above-noted EXAMPLE where the connector is configured implemented as one or more jumper wire bonds between the one or more power devices. The power package of the above-noted EXAMPLE may include a thermal pad configured as an exposed metal surface configured to thermally and mechanically attach to another component. The power package of the above-noted EXAMPLE where the thermal pad is configured to be attached to the another component via sintering, soldering, conductive epoxy, and/or thermal paste. The power package of the above-noted EXAMPLE where the thermal pad may include hold down configurations arranged thereon. The power package of the above-noted EXAMPLE may include a molded assembly having a dielectric mold compound and configured to provide electrical isolation, voltage safety distances, and/or mechanical support to an internal layout and the one or more power devices. The power package of the above-noted EXAMPLE may include at least one strain relieving feature arranged on one of the lead frame first portion, the lead frame second portion, and/or a signal contact, where the at least one strain relieving feature may include one or more holes or slots. The power package of the above-noted EXAMPLE where the molded assembly may include portions that extend through the at least one strain relieving feature. The power package of the above-noted EXAMPLE where the molded assembly may include creepage extenders, where the creepage extenders are configured as at least one groove, ripple, and/or trench acting as creepage distance extension. The power package of the above-noted EXAMPLE may include a source Kelvin terminal configured as a true source kelvin with limited overlap of a power loop and signal loop. The power package of the above-noted EXAMPLE may include a pseudo Kelvin connection configured to be connected to the lead frame first portion. The power package of the above-noted EXAMPLE where the power substrate may include at least one a fiducial for pattern recognition systems of manufacturing equipment. The power package of the above-noted EXAMPLE where the power substrate may include a first metal having a first contoured portion. The power package of the above-noted EXAMPLE where the first contoured portion is located on the power substrate at a hold down pin location. The power package of the above-noted EXAMPLE where the first contoured portion may include non-rectangular shape. The power package of the above-noted EXAMPLE where the lead frame first portion is implemented as a clip attach and a power interconnection attach is arranged between the one or more power devices and the clip attach. The power package of the above-noted EXAMPLE where the power interconnection attach may include welded portions, soldered portions, sintered portions, and/or preformed portions. The power package of the above-noted EXAMPLE where the power substrate is configured to form a mechanical and electrical connection with the lead frame first portion by attachment to a trace on the power substrate. The power package of the above-noted EXAMPLE where the lead frame second portion may include portions extending over a second metal portion of the power substrate and past one or more implementations of the one or more power devices. The power package of the above-noted EXAMPLE may include a mold assembly feature arranged on the lead frame first portion and configured to provide mold flow enhancement, hold down access, and/or lead strengthening. The power package of the above-noted EXAMPLE where the lead frame first portion may include at least one opening configured for manufacturing tooling access. The power package of the above-noted EXAMPLE may include signal bonds implemented as one of the following: signal bonds formed for each of the one or more power devices having an independent loop or stitched signal bonds extending at least to two of the one or more power devices. The power package of the above-noted EXAMPLE may include power connections extending from the lead frame first portion to the one or more power devices, where the power connections may include ribbon bonds and/or wire bonds. The power package of the above-noted EXAMPLE where the lead frame first portion is configured as a clip, where the clip is configured as a formed metal contact connecting a topside of the one or more power devices to the lead frame first portion. The power package of the above-noted EXAMPLE where the lead frame second portion is bonded to the power substrate. The power package of the above-noted EXAMPLE where the lead frame first portion is bonded to the power substrate. The power package of the above-noted EXAMPLE where components of the power package are configured for one, two, three, or four implementations of the one or more power devices within a same structure of the power package. The power package of the above-noted EXAMPLE may include a modular clip attached to the lead frame first portion and also attached to the one or more power devices.

One EXAMPLE includes: a power package that includes a power substrate. The power package in addition includes one or more power devices arranged on the power substrate. The power package moreover includes a lead frame power interconnection having a lead frame first portion and a lead frame second portion. The power package also includes a molded assembly configured to provide electrical isolation, voltage safety distances, and/or mechanical support to an internal layout and the one or more power devices. The power package further includes where the molded assembly may include creepage extenders.

The above-noted EXAMPLE may further include any one or a combination of more than one of the following EXAMPLES: The power package of the above-noted EXAMPLE may include a connector configured to reduce transconductance mismatches between paralleled implementations of the one or more power devices. The power package of the above-noted EXAMPLE where the connector is configured as a centralized connecting bar in the lead frame first portion. The power package of the above-noted EXAMPLE where the connector is configured implemented as one or more jumper wire bonds between the one or more power devices. The power package of the above-noted EXAMPLE may include at least one strain relieving feature arranged on one of the lead frame first portion, the lead frame second portion, and/or a signal contact, where the at least one strain relieving feature may include one or more holes or slots. The power package of the above-noted EXAMPLE where the dielectric mold compound may include portions that extend through the at least one strain relieving feature. The power package of the above-noted EXAMPLE may include a thermal pad configured as an exposed metal surface configured to thermally and mechanically attach to another component. The power package of the above-noted EXAMPLE where the thermal pad is configured to be attached to the another component via sintering, soldering, conductive epoxy, and/or thermal paste. The power package of the above-noted EXAMPLE where the thermal pad may include hold down configurations arranged thereon. The power package of the above-noted EXAMPLE may include a source Kelvin terminal configured as a true source kelvin with limited overlap of a power loop and signal loop. The power package of the above-noted EXAMPLE may include a pseudo Kelvin connection configured to be connected to the lead frame first portion. The power package of the above-noted EXAMPLE where the power substrate may include at least one a fiducial for pattern recognition systems of manufacturing equipment. The power package of the above-noted EXAMPLE where the power substrate may include a first metal having a first contoured portion. The power package of the above-noted EXAMPLE where the first contoured portion is located on the power substrate at a hold down pin location. The power package of the above-noted EXAMPLE where the first contoured portion may include non-rectangular shape. The power package of the above-noted EXAMPLE where the lead frame first portion is implemented as a clip attach and a power interconnection attach is arranged between the one or more power devices and the clip attach. The power package of the above-noted EXAMPLE where the power interconnection attach may include welded portions, soldered portions, sintered portions, and/or preformed portions. The power package of the above-noted EXAMPLE where the power substrate is configured to form a mechanical and electrical connection with the lead frame first portion by attachment to a trace on the power substrate. The power package of the above-noted EXAMPLE where the lead frame second portion may include portions extending over a second metal portion of the power substrate and past one or more implementations of the one or more power devices. The power package of the above-noted EXAMPLE may include a mold assembly feature arranged on the lead frame first portion and configured to provide mold flow enhancement, hold down access, and/or lead strengthening. The power package of the above-noted EXAMPLE where the lead frame first portion may include at least one opening configured for manufacturing tooling access. The power package of the above-noted EXAMPLE may include signal bonds implemented as one of the following: signal bonds formed for each of the one or more power devices having an independent loop or stitched signal bonds extending at least to two of the one or more power devices. The power package of the above-noted EXAMPLE may include power connections extending from the lead frame first portion to the one or more power devices, where the power connections may include ribbon bonds and/or wire bonds. The power package of the above-noted EXAMPLE where the creepage extenders are configured as at least one groove, ripple, and/or trench acting as creepage distance extension. The power package of the above-noted EXAMPLE where the lead frame first portion is configured as a clip, where the clip is configured as a formed metal contact connecting a topside of the one or more power devices to the lead frame first portion. The power package of the above-noted EXAMPLE where the lead frame second portion is bonded to the power substrate. The power package of the above-noted EXAMPLE where the lead frame first portion is bonded to the power substrate. The power package of the above-noted EXAMPLE where components of the power package are configured for one, two, three, or four implementations of the one or more power devices within a same structure of the power package. The power package of the above-noted EXAMPLE may include a modular clip attached to the lead frame first portion and also attached to the one or more power devices.

One EXAMPLE includes: a power package that includes a power substrate. The power package in addition includes one or more power devices arranged on the power substrate. The power package moreover includes a lead frame power interconnection having a lead frame first portion and a lead frame second portion. The power package also includes a thermal pad configured as an exposed metal surface configured to thermally and mechanically attach to another component. The power package further includes where components of the power package are configured for one, two, three, or four implementations of the one or more power devices within a same structure of the power package.

The above-noted EXAMPLE may further include any one or a combination of more than one of the following EXAMPLES: The power package of the above-noted EXAMPLE may include a connector configured to reduce transconductance mismatches between paralleled implementations of the one or more power devices, where the connector is configured as a centralized connecting bar in the lead frame first portion and/or as one or more jumper wire bonds between the one or more power devices. The power package of the above-noted EXAMPLE where the thermal pad is configured to be attached to the another component via sintering, soldering, conductive epoxy, and/or thermal paste. The power package of the above-noted EXAMPLE may include a molded assembly having a dielectric mold compound and configured to provide electrical isolation, voltage safety distances, and/or mechanical support to an internal layout and the one or more power devices. The power package of the above-noted EXAMPLE may include at least one strain relieving feature arranged on one of the lead frame first portion, the lead frame second portion, and/or a signal contact, where the at least one strain relieving feature may include one or more holes or slots. The power package of the above-noted EXAMPLE where the dielectric mold compound may include portions that extend through the at least one strain relieving feature. The power package of the above-noted EXAMPLE where the molded assembly may include creepage extenders, where the creepage extenders are configured as at least one groove, ripple, and/or trench acting as creepage distance extension. The power package of the above-noted EXAMPLE may include a source Kelvin terminal configured as a true source kelvin with limited overlap of a power loop and signal loop. The power package of the above-noted EXAMPLE may include a pseudo Kelvin connection configured to be connected to the lead frame first portion. The power package of the above-noted EXAMPLE where the thermal pad may include hold down configurations arranged thereon. The power package of the above-noted EXAMPLE where the power substrate may include at least one a fiducial for pattern recognition systems of manufacturing equipment. The power package of the above-noted EXAMPLE where the power substrate may include a first metal having a first contoured portion. The power package of the above-noted EXAMPLE where the first contoured portion is located on the power substrate at a hold down pin location. The power package of the above-noted EXAMPLE where the first contoured portion may include non-rectangular shape. The power package of the above-noted EXAMPLE where the lead frame first portion is implemented as a clip attach and a power interconnection attach is arranged between the one or more power devices and the clip attach. The power package of the above-noted EXAMPLE where the power interconnection attach may include welded portions, soldered portions, sintered portions, and/or preformed portions. The power package of the above-noted EXAMPLE where the power substrate is configured to form a mechanical and electrical connection with the lead frame first portion by attachment to a trace on the power substrate. The power package of the above-noted EXAMPLE where the lead frame second portion may include portions extending over a second metal portion of the power substrate and past one or more implementations of the one or more power devices. The power package of the above-noted EXAMPLE may include a mold assembly feature arranged on the lead frame first portion and configured to provide mold flow enhancement, hold down access, and/or lead strengthening. The power package of the above-noted EXAMPLE where the lead frame first portion may include at least one opening configured for manufacturing tooling access. The power package of the above-noted EXAMPLE may include signal bonds implemented as one of the following: signal bonds formed for each of the one or more power devices having an independent loop or stitched signal bonds extending at least to two of the one or more power devices. The power package of the above-noted EXAMPLE may include power connections extending from the lead frame first portion to the one or more power devices, where the power connections may include ribbon bonds and/or wire bonds. The power package of the above-noted EXAMPLE where the lead frame first portion is configured as a clip, where the clip is configured as a formed metal contact connecting a topside of the one or more power devices to the lead frame first portion. The power package of the above-noted EXAMPLE where the lead frame second portion is bonded to the power substrate. The power package of the above-noted EXAMPLE where the lead frame first portion is bonded to the power substrate. The power package of the above-noted EXAMPLE may include a modular clip attached to the lead frame first portion and also attached to the one or more power devices.

Moreover, the power package 100 may be implemented in numerous circuit topologies including a single switch configuration, half bridge configuration, full bridge configuration, three phase bridge configuration (also called a six pack), buck configuration, boost configuration, buck-boost configuration, ćuk configuration, a common source configuration, a common drain configuration, a neutral point clamp configuration, and/or the like. Applications of the power package 100 may include a power system, a motor system, an automotive motor system, a charging system, an automotive charging system, a vehicle system, an industrial motor drive, an embedded motor drive, an uninterruptible power supply, an AC-DC power supply, a welder power supply, military systems, an inverter, an inverter for wind turbines, solar power panels, tidal power plants, and electric vehicles (EVs), a converter, motor drives, solar inverters, circuit breakers, protection circuits, DC-DC converters, and/or the like.

Aspects of the disclosure have been described above with reference to the accompanying drawings, in which aspects of the disclosure are shown. It will be appreciated, however, that this disclosure may, however, be embodied in many different forms and should not be construed as limited to the aspects set forth above. Rather, these aspects are provided so that this disclosure will be thorough and complete, and will fully convey the scope of the disclosure to those skilled in the art. Additionally, the various aspects described may be implemented separately. Moreover, one or more the various aspects described may be combined. Like numbers refer to like elements throughout.

It will be understood that, although the terms first, second, etc. are used throughout this specification to describe various elements, these elements should not be limited by these terms. These terms are only used to distinguish one element from another. For example, a first element could be termed a second element, and, similarly, a second element could be termed a first element, without departing from the scope of the disclosure. The term “and/or” includes any and all combinations of one or more of the associated listed items.

The terminology used herein is for the purpose of describing particular aspects only and is not intended to be limiting of the disclosure. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “top” or “bottom” may be used herein to describe a relationship of one element, layer or region to another element, layer or region as illustrated in the figures. It will be understood that these terms are intended to encompass different orientations of the device in addition to the orientation depicted in the figures.

Aspects of the disclosure are described herein with reference to cross-section illustrations that are schematic illustrations of idealized embodiments (and intermediate structures) of the disclosure. The thickness of layers and regions in the drawings may be exaggerated for clarity. Additionally, variations from the shapes of the illustrations as a result, for example, of manufacturing techniques and/or tolerances, are to be expected.

In the drawings and specification, there have been disclosed typical aspects of the disclosure and, although specific terms are employed, they are used in a generic and descriptive sense only and not for purposes of limitation, the scope of the disclosure being set forth in the following claims.

While the disclosure has been described in terms of exemplary aspects, those skilled in the art will recognize that the disclosure can be practiced with modifications in the spirit and scope of the appended claims. These examples given above are merely illustrative and are not meant to be an exhaustive list of all possible designs, aspects, applications or modifications of the disclosure. In this regard, the various aspects, features, components, elements, modules, arrangements, circuits, and the like are contemplated to be interchangeable, mixed, matched, combined, and the like. In this regard, the different features of the disclosure are modular and can be mixed and matched with each other.

1. A power package comprising:
a power substrate;
one or more power devices arranged on the power substrate;
a lead frame power interconnection comprising a lead frame first portion and a lead frame second portion; and
a connector configured to reduce transconductance mismatches between paralleled implementations of the one or more power devices.

2. The power package according to claim 1 wherein the connector is configured as a centralized connecting bar in the lead frame first portion.

3. The power package according to claim 1 wherein the connector is configured implemented as one or more jumper wire bonds between the one or more power devices.

4. The power package according to claim 1 further comprising a thermal pad configured as an exposed metal surface configured to thermally and mechanically attach to another component.

5. The power package according to claim 4 wherein the thermal pad is configured to be attached to the another component via sintering, soldering, conductive epoxy, and/or thermal paste.

6. The power package according to claim 1 further comprising a molded assembly comprising a dielectric mold compound and configured to provide electrical isolation, voltage safety distances, and/or mechanical support to an internal layout and the one or more power devices.

7. The power package according to claim 1 further comprising a source Kelvin terminal configured as a true source kelvin with limited overlap of a power loop and signal loop.

8. The power package according to claim 1 further comprising a pseudo Kelvin connection configured to be connected to the lead frame first portion.

9. The power package according to claim 4 wherein the thermal pad comprises hold down configurations arranged thereon.

10. The power package according to claim 1 wherein the power substrate comprises at least one a fiducial for pattern recognition systems of manufacturing equipment.

11. The power package according to claim 1 wherein the power substrate comprises a first metal having a first contoured portion.

12. The power package according to claim 11 wherein the first contoured portion is located on the power substrate at a hold down pin location.

13. The power package according to claim 11 wherein the first contoured portion comprises non-rectangular shape.

14. The power package according to claim 1 wherein the lead frame first portion is implemented as a clip attach and a power interconnection attach is arranged between the one or more power devices and the clip attach.

15. The power package according to claim 14 wherein the power interconnection attach comprises welded portions, soldered portions, sintered portions, and/or preformed portions.

16. The power package according to claim 1 wherein the power substrate is configured to form a mechanical and electrical connection with the lead frame first portion by attachment to a trace on the power substrate.

17. The power package according to claim 1 wherein the lead frame second portion comprises portions extending over a second metal portion of the power substrate and past one or more implementations of the one or more power devices.

18. The power package according to claim 6 further comprising at least one strain relieving feature arranged on one of the lead frame first portion, the lead frame second portion, and/or a signal contact, wherein the at least one strain relieving feature comprises one or more holes or slots.

19. The power package according to claim 18 wherein the dielectric mold compound comprises portions that extend through the at least one strain relieving feature.

20. The power package according to claim 1 further comprising a mold assembly feature arranged on the lead frame first portion and configured to provide mold flow enhancement, hold down access, and/or lead strengthening.

21. The power package according to claim 1 wherein the lead frame first portion comprises at least one opening configured for manufacturing tooling access.

22. The power package according to claim 1 further comprising signal bonds implemented as one of the following: signal bonds formed for each of the one or more power devices having an independent loop or stitched signal bonds extending at least to two of the one or more power devices.

23. The power package according to claim 1 further comprising power connections extending from the lead frame first portion to the one or more power devices,
wherein the power connections comprise ribbon bonds and/or wire bonds.

24. The power package according to claim 6 wherein the molded assembly comprises creepage extenders,
wherein the creepage extenders are configured as at least one groove, ripple, and/or trench acting as creepage distance extension.

25. The power package according to claim 1 wherein the lead frame first portion is configured as a clip, wherein the clip is configured as a formed metal contact connecting a topside of the one or more power devices to the lead frame first portion.

26. The power package according to claim 1 wherein the lead frame second portion is bonded to the power substrate.

27. The power package according to claim 1 wherein the lead frame first portion is bonded to the power substrate.

28. The power package according to claim 1 wherein components of the power package are configured for one, two, three, or four implementations of the one or more power devices within a same structure of the power package.

29. The power package according to claim 1 further comprising a modular clip attached to the lead frame first portion and also attached to the one or more power devices.

30. A power package comprising:
a power substrate;
one or more power devices arranged on the power substrate;
a lead frame power interconnection comprising a lead frame first portion and a lead frame second portion; and
a molded assembly configured to provide electrical isolation, voltage safety distances, and/or mechanical support to an internal layout and the one or more power devices,
wherein the a molded assembly comprises creepage extenders.

31.-58. (canceled)

59. A power package comprising:
a power substrate;
one or more power devices arranged on the power substrate;
a lead frame power interconnection comprising a lead frame first portion and a lead frame second portion; and
a thermal pad configured as an exposed metal surface configured to thermally and mechanically attach to another component,
wherein components of the power package are configured for one, two, three, or four implementations of the one or more power devices within a same structure of the power package.

60.-84. (canceled)
